(19) United States
(12) Patent Application Publication
(10) Pub. No.: US 2025/0107180 A1
(43) Pub. Date: Mar. 27, 2025

(54) STACKED INTEGRATED CIRCUIT DEVICE

(71) Applicant: Samsung Electronics Co., Ltd., Suwon-si (KR)

(72) Inventors: Kyunghee CHO, Suwon-si (KR); Byungho MOON, Suwon-si (KR); Donghoon HWANG, Suwon-si (KR)

(73) Assignee: Samsung Electronics Co., Ltd., Suwon-si (KR)

(21) Appl. No.: 18/755,008

(22) Filed: Jun. 26, 2024

(30) Foreign Application Priority Data
Sep. 25, 2023 (KR) 10-2023-0128486

(51) Int. Cl. H01L 29/06; H01L 21/822; H01L 21/8238; H01L 27/06; H01L 27/092; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 84/0167; H10D 84/017; H10D 84/0177; H10D 84/038; H10D 84/856; H10D 88/00; H10D 88/01

(57) ABSTRACT

Provided is an integrated circuit device including a base substrate layer, a sheet separation wall extending on the base substrate layer in a first horizontal direction, a pair of nanosheet stacked structures including the sheet separation wall therebetween and apart from each other in a second horizontal direction, the second horizontal direction different from the first horizontal direction, the pair of nanosheet stacked structures each including a plurality of nanosheets, a plurality of cladding patterns between a first end of each of the plurality of nanosheets included in each of the pair of nanosheet stacked structures and the sheet separation wall, and a pair of gate electrodes extending on the pair of nanosheet stacked structures in the second horizontal direction.

### CROSS-REFERENCE TO RELATED APPLICATION

This application is based on and claims ranking under 35 U.S.C. § 119 to Korean Patent Application No. 10-2023-0128486, filed on Sep. 25, 2023 in the Korean Intellectual Property office, the disclosure of which are incorporated by reference herein in their entirety.

### BACKGROUND

The inventive concepts relate to integrated circuit devices including a multi-gate metal-oxide-semiconductor field effect transistor (MOSFET).

As the degree of integration of an integrated circuit device is increased, the size thereof is reduced to the extreme state and the scaling thereof has reached the limit. Accordingly, a new method by using a structure change of the integrated circuit device is required to improve the performance of the integrated circuit device, and an integrated circuit device equipped with a transistor having a new structure such as a multi-gate MOSFET is proposed.

### SUMMARY

The inventive concepts provide integrated circuit devices equipped with a transistor including a multi-gate metal-oxide-semiconductor field effect transistor (MOSFET) having improved operation characteristics.

The inventive concepts provide integrated circuit devices as described below.

According to some aspects of the inventive concepts, there is provided an integrated circuit device including a base substrate layer, a sheet separation wall extending on the base substrate layer in a first horizontal direction, a pair of nanosheet stacked structures including the sheet separation wall therebetween and apart from each other in a second horizontal direction, the second horizontal direction different from the first horizontal direction, the pair of nanosheet stacked structures each including a plurality of nanosheets, a plurality of cladding patterns between a first end of each of the plurality of nanosheets included in each of the pair of nanosheet stacked structures and the sheet separation wall, and a pair of gate electrodes extending on the pair of nanosheet stacked structures in the second horizontal direction.

According to some aspects of the inventive concepts, there is provided an integrated circuit device including a base insulating layer on a base substrate layer, a sheet separation wall extending on the base insulating layer in a first horizontal direction, a pair of nanosheet stacked structures including the sheet separation wall therebetween and apart from each other in a second horizontal direction, the second horizontal direction different from the first horizontal direction, the pair of nanosheet stacked structures each including a plurality of nanosheets, a plurality of cladding patterns between a first end of each of the plurality of nanosheets included in each of the pair of nanosheet stacked structures and the sheet separation wall, a pair of gate electrodes extending on the pair of nanosheet stacked structures in the second horizontal direction, a pair of gate insulating layers between the plurality of nanosheets included in each of the pair of nanosheet stacked structures and the pair of gate electrodes, the pair of gate insulating layers each having a thickness less than a thickness of each of the plurality of cladding patterns, and a pair of source/drain regions connected to a second end opposite to the first end of each of the plurality of nanosheets included in each of the pair of nanosheet stacked structures.

According to some aspects of the inventive concepts, there is provided an integrated circuit device including a base insulating layer on a base substrate layer, a sheet separation wall extending on the base insulating layer in a first horizontal direction, a pair of nanosheet stacked structures including the sheet separation wall therebetween and apart from each other in a second horizontal direction different from the first horizontal direction, the pair of nanosheet stacked structures each including a plurality of nanosheets, a plurality of cladding patterns between a first end of each of the plurality of nanosheets included in each of the pair of nanosheet stacked structures and the sheet separation wall, a plurality of gate electrodes between a nanosheet at an uppermost end among the plurality of nanosheets included in the pair of nanosheet stacked structures and each of the plurality of nanosheets, the plurality of gate electrodes extending in the second horizontal direction, a pair of gate insulating layers between the plurality of nanosheets included in each of the pair of nanosheet stacked structures and the plurality of gate electrodes, the pair of gate insulating layers each having a thickness less than a thickness of each of the plurality of cladding patterns, a gate capping layer covering the plurality of gate electrodes, a pair of source/drain regions connected to a second end opposite to the first end of each of the plurality of nanosheets included in each of the pair of nanosheet stacked structures, a gate contact configured to penetrate the gate capping layer and connected to each of the plurality of gate electrodes, and a source/drain contact configured to penetrate the base substrate layer and connected to each of the pair of source/drain regions, wherein the sheet separation wall has a horizontal cross-section having a pair of concave portions between the pair of nanosheet stacked structures, wherein the plurality of cladding patterns are arranged in the pair of concave portions, and wherein the plurality of gate electrodes extend into the pair of concave portions.

### BRIEF DESCRIPTION OF THE DRAWINGS

Embodiments will be more clearly understood from the following detailed description taken in conjunction with the accompanying drawings in which:

FIG. 1 is a layout of an integrated circuit device, according to some example embodiments;

FIGS. 2A, 2B, 3A, 3B, 4A though 4C, 5A through 5D, 6A through 6D, 7A through 7D, 8A through 8D, 9A through 9E, 10A through 10E, 11A through 11E, 12A through 12E, 13A through 13E, 14A through 14E, 15A through 15E, 16A through 16E, 17A through 17E, 18A through 18E, 19A through 19F, and 20A through 20F are vertical cross-sectional views for describing a manufacturing method of a semiconductor device, according to some example embodiments;

FIGS. 21A through 21F are vertical cross-sectional views according to some example embodiments, FIG. 22 is an enlarged cross-sectional view, and FIGS. 23A and 23B are horizontal cross-sectional views; and

FIG. 24 is a vertical cross-sectional view of an integrated circuit device according to some example embodiments.

### DETAILED DESCRIPTION

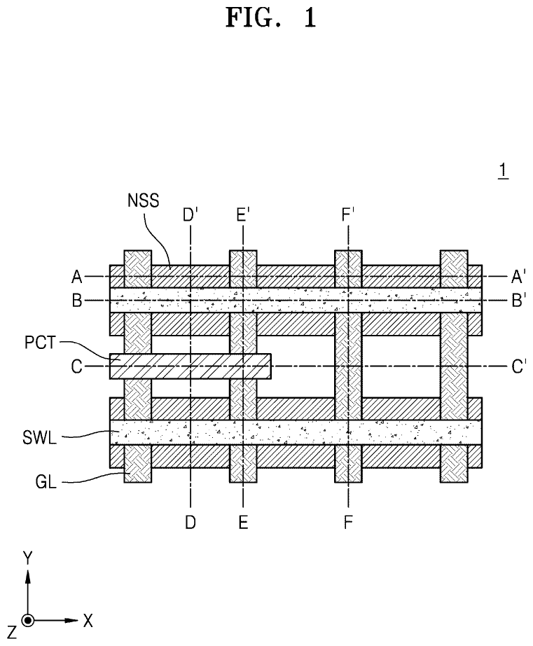

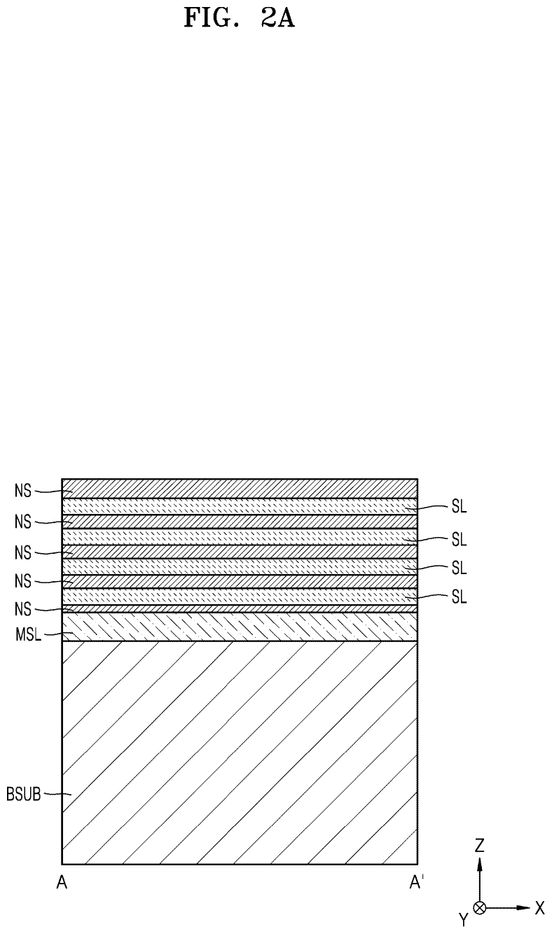

FIG. 1 is a layout of an integrated circuit device 1, according to some example embodiments.

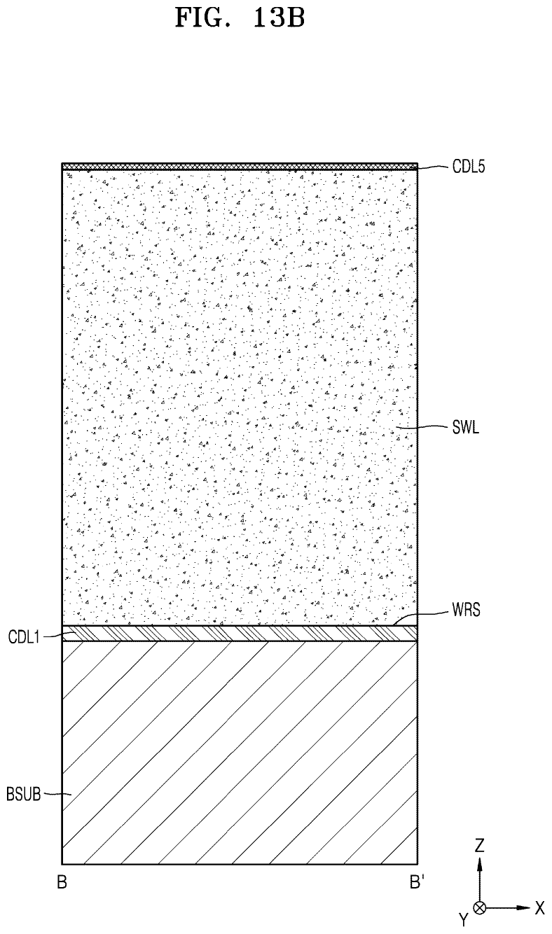

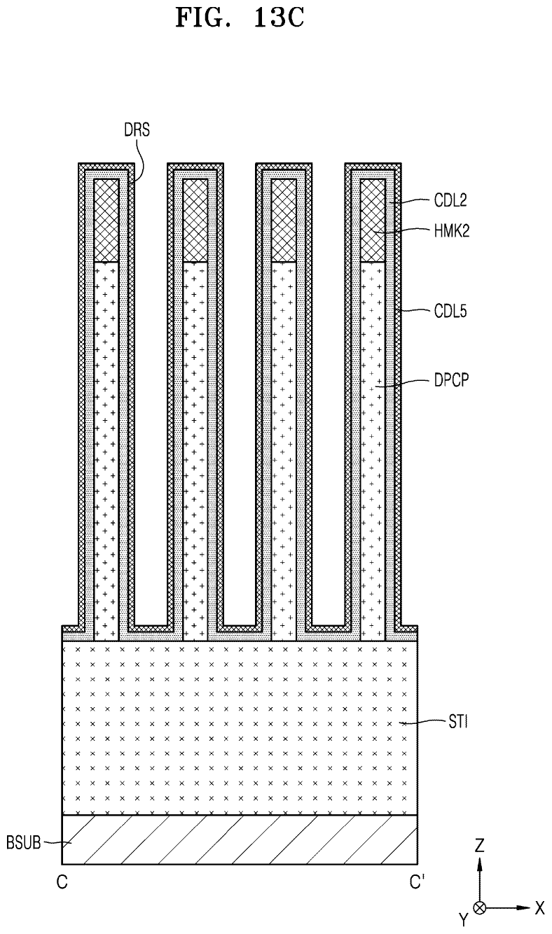

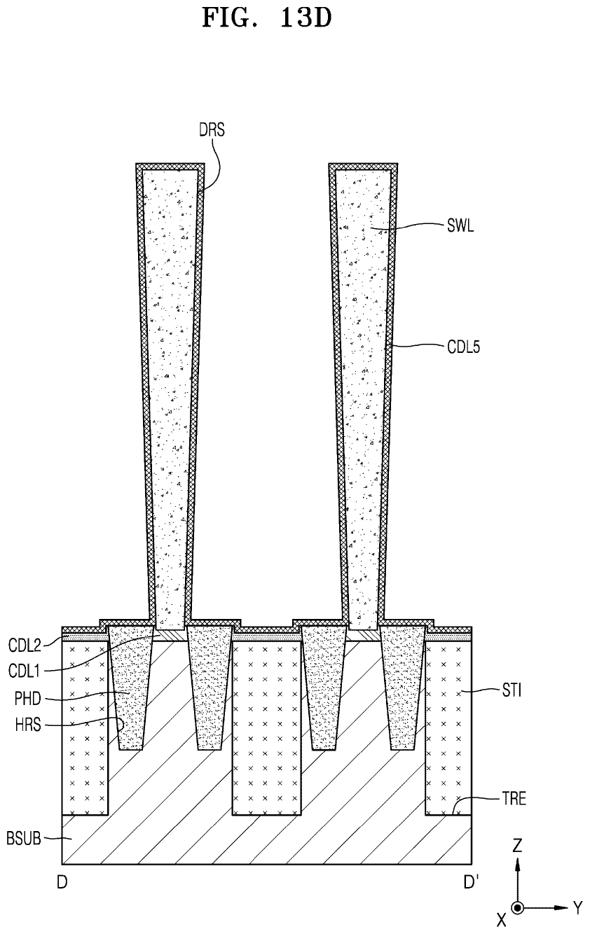

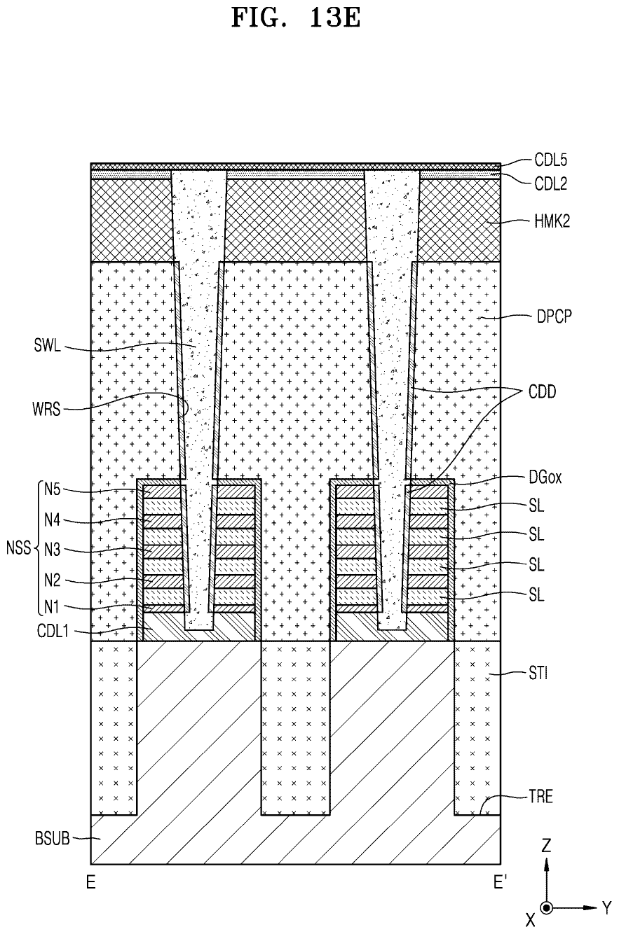

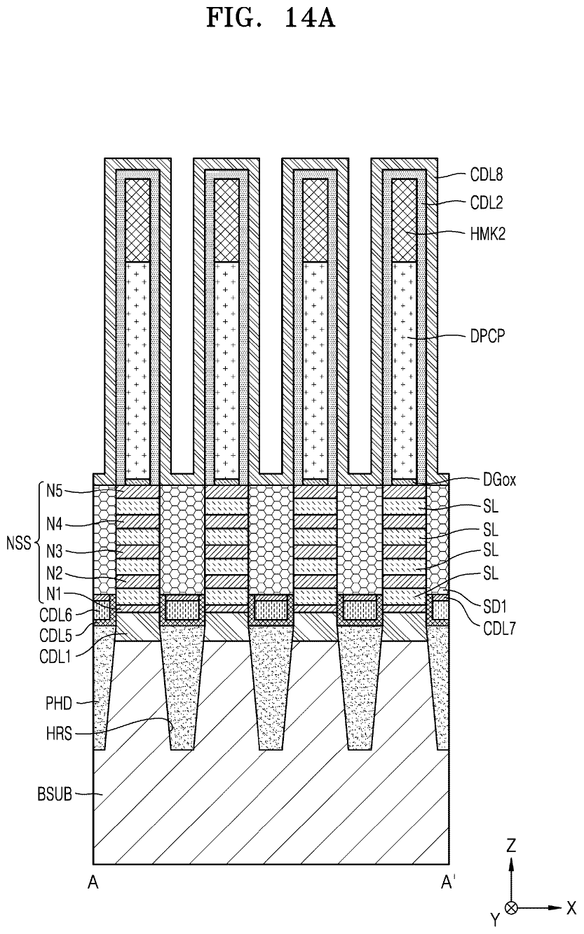

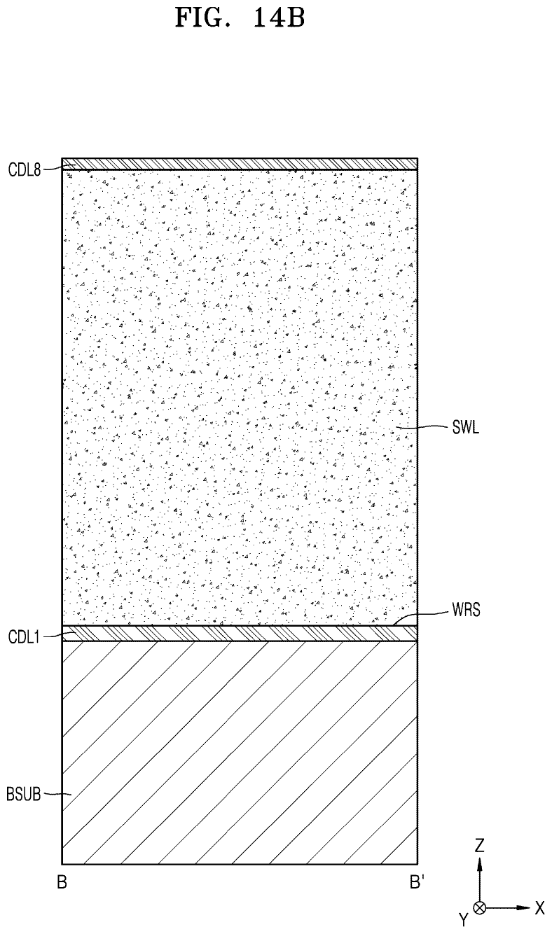

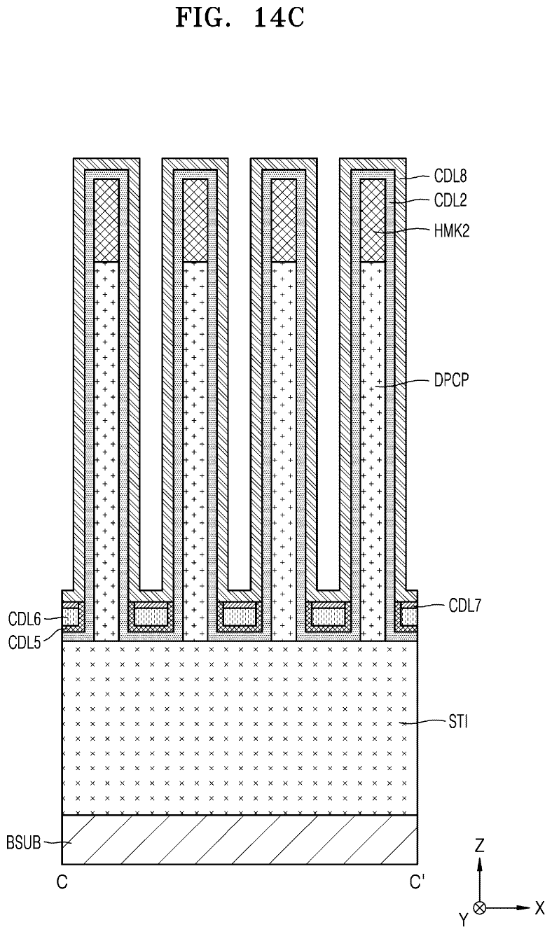

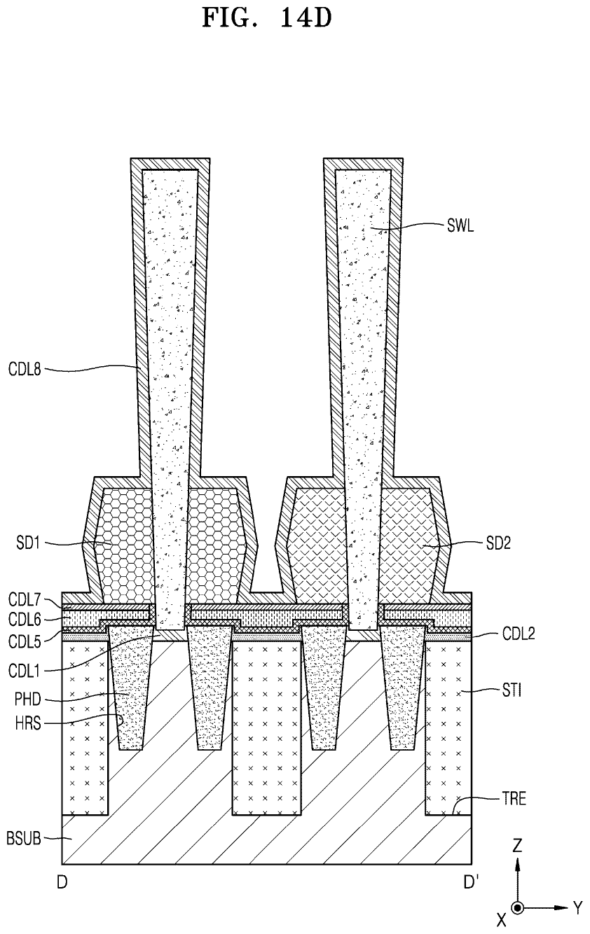

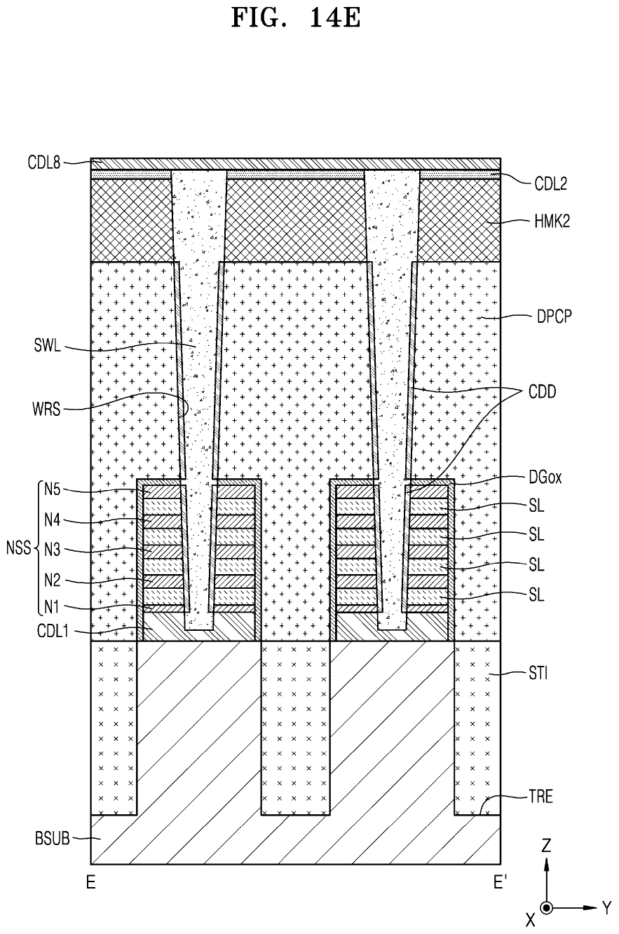

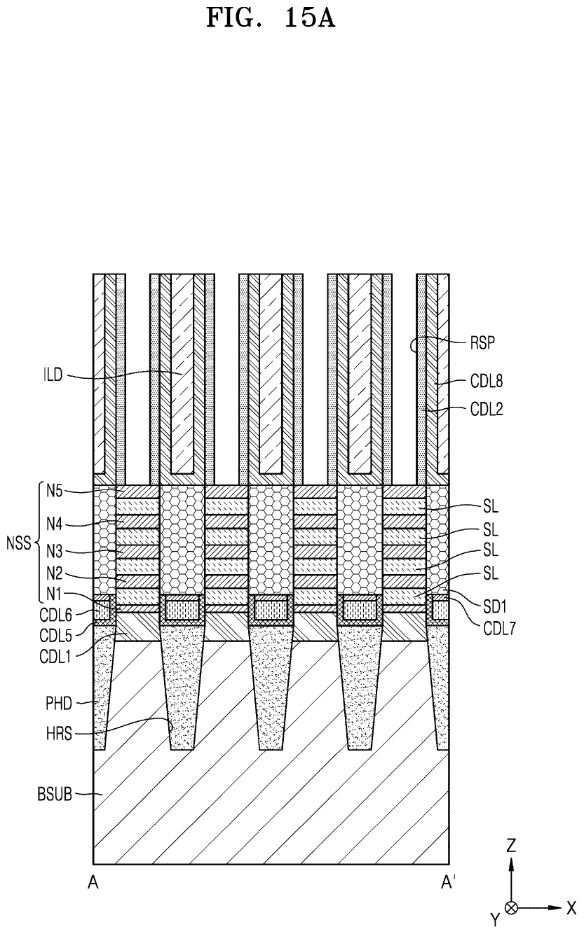

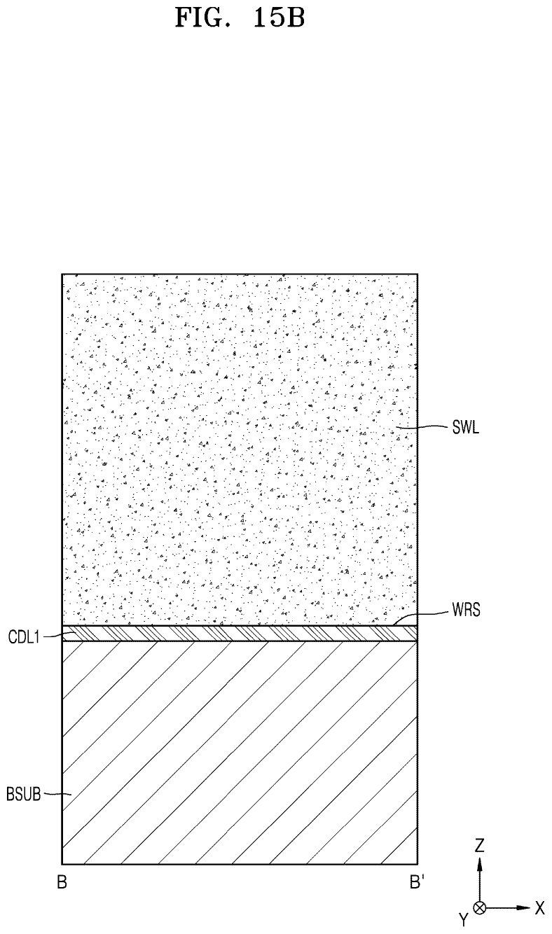

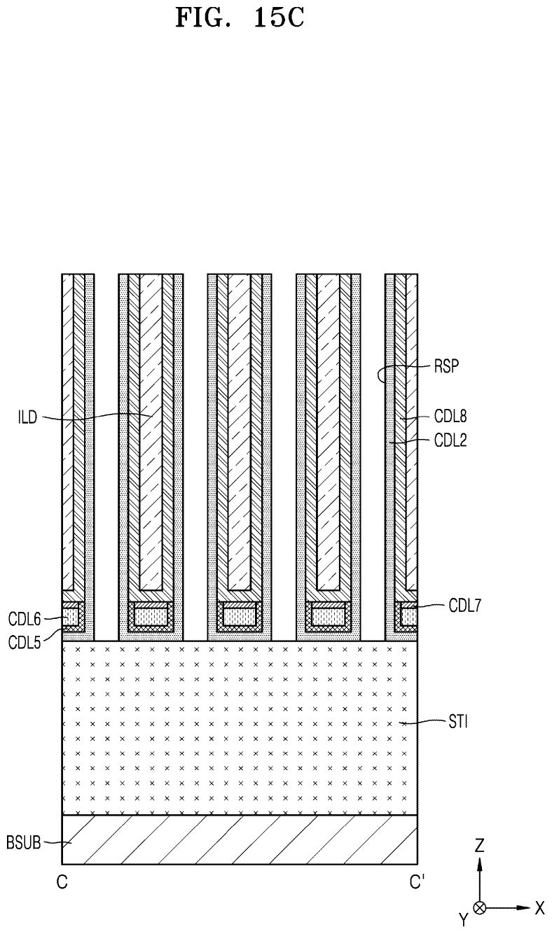

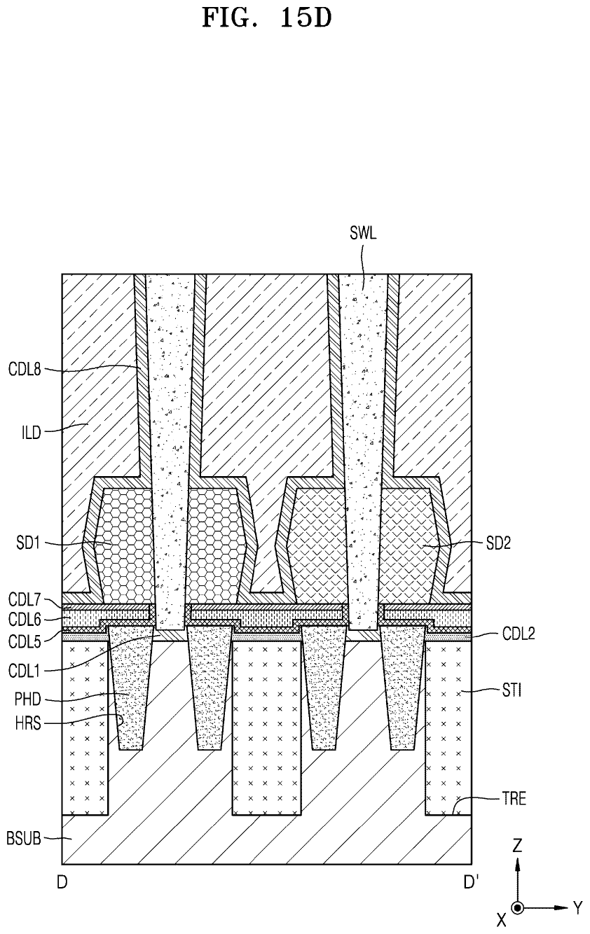

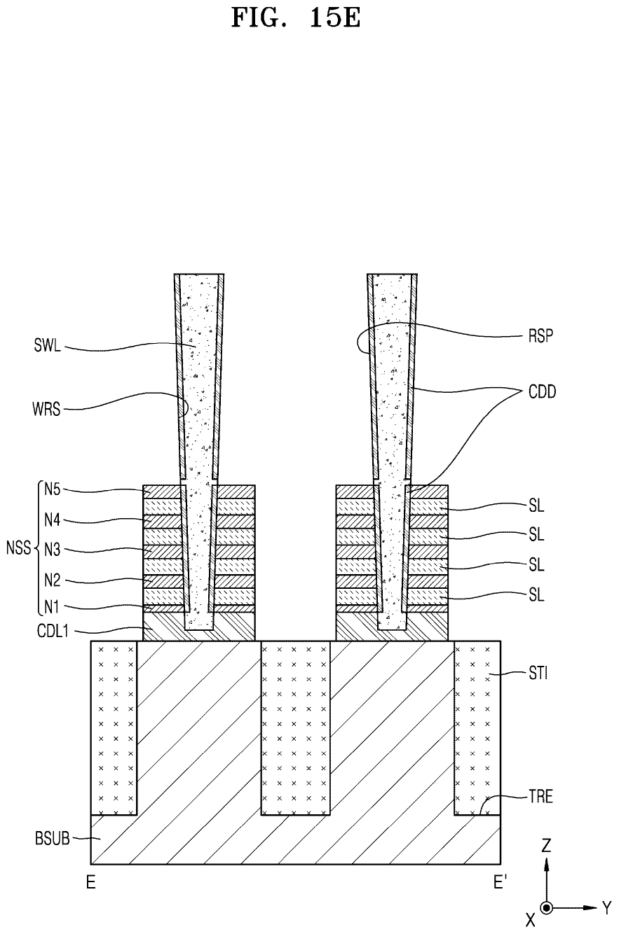

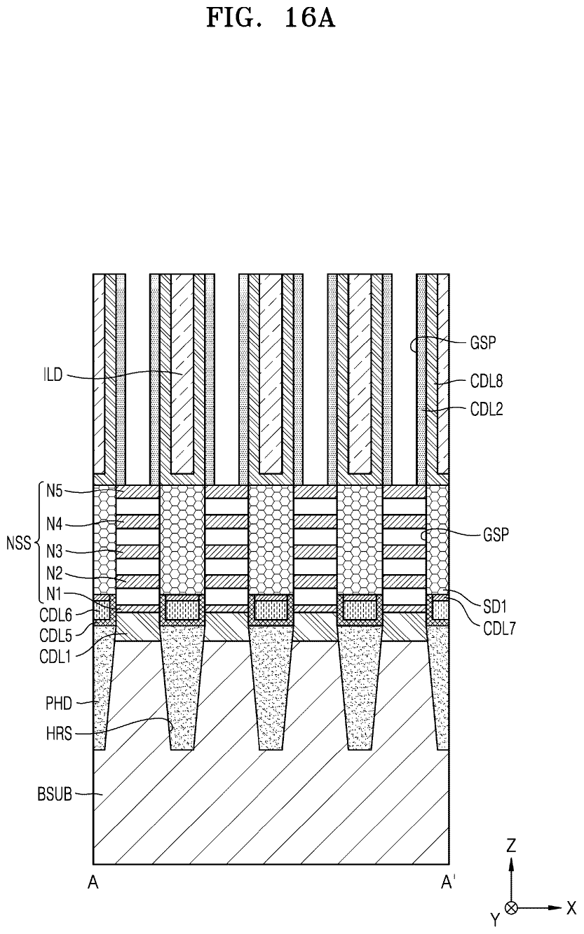

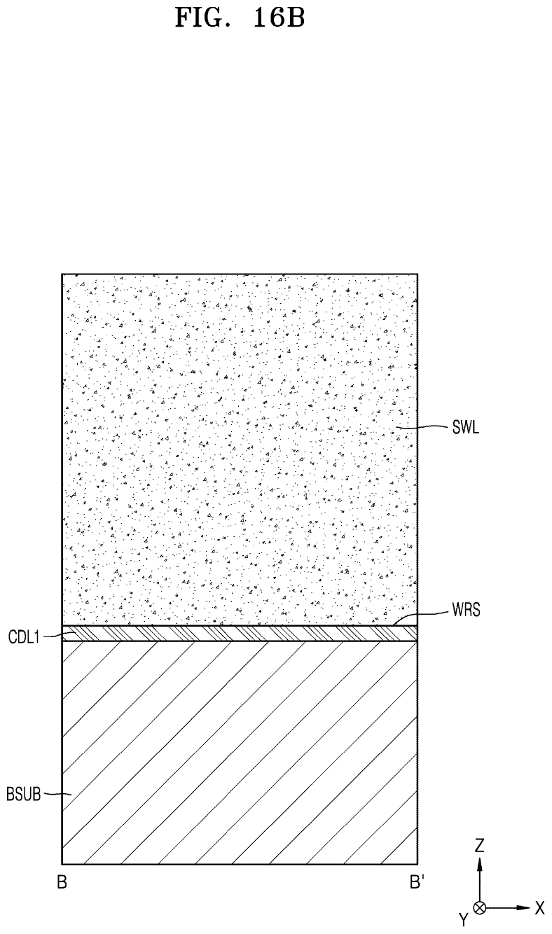

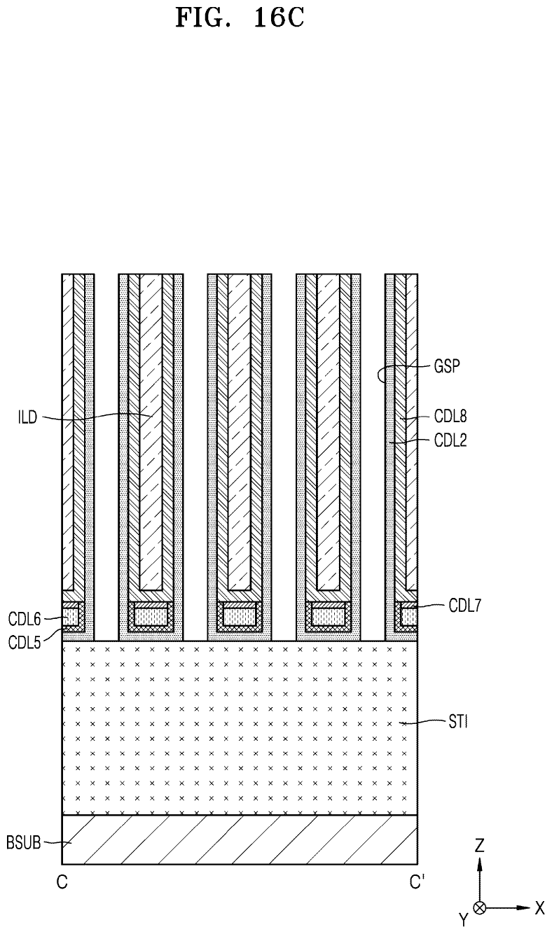

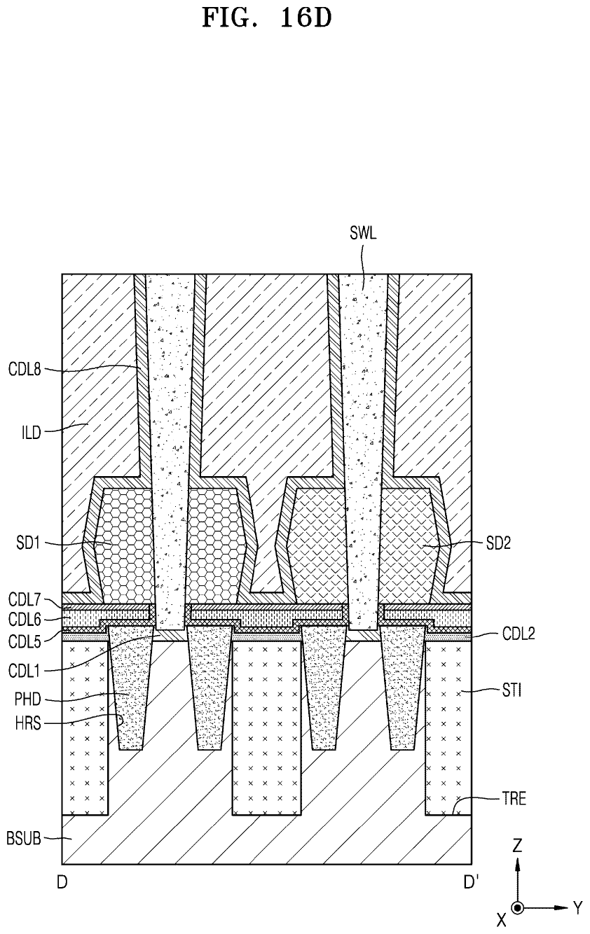

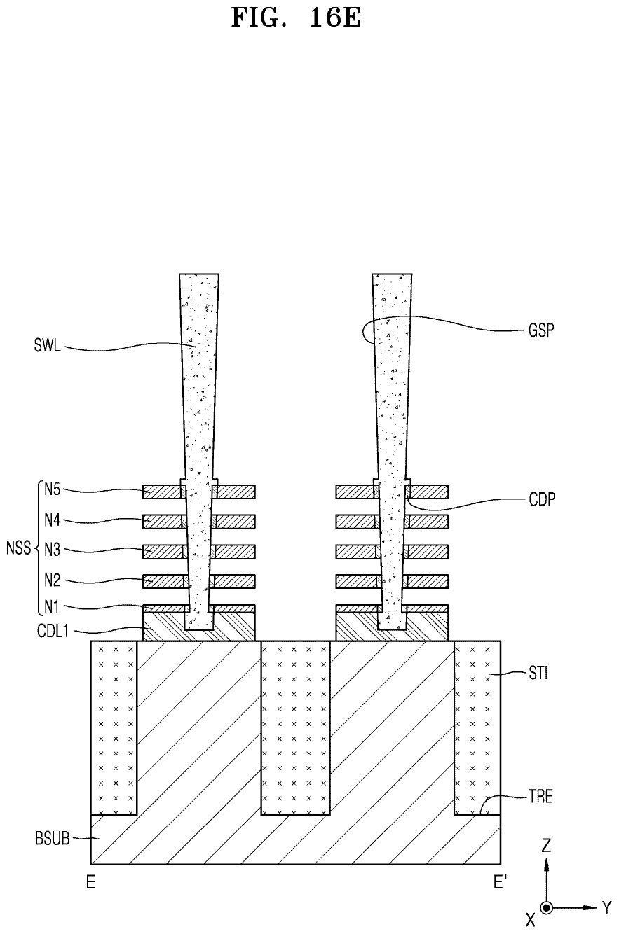

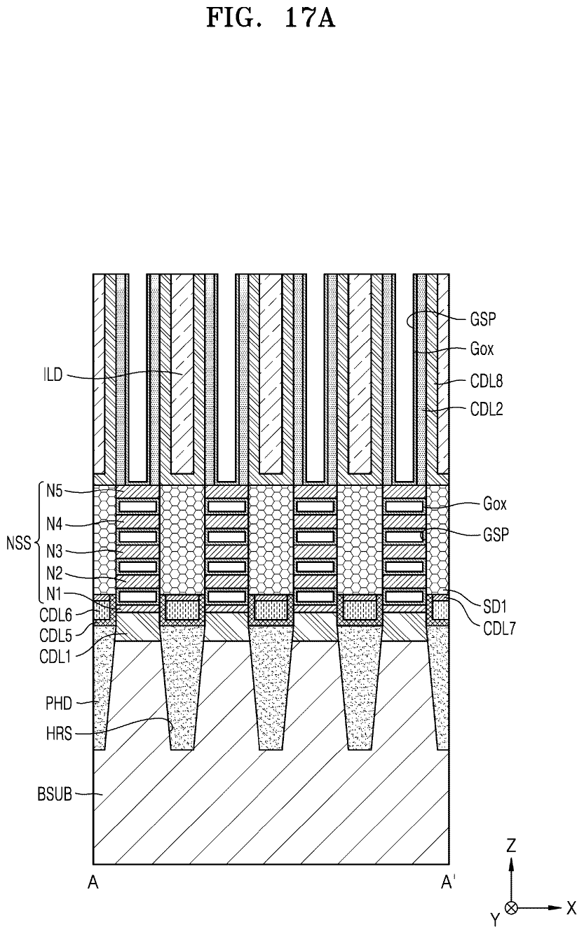

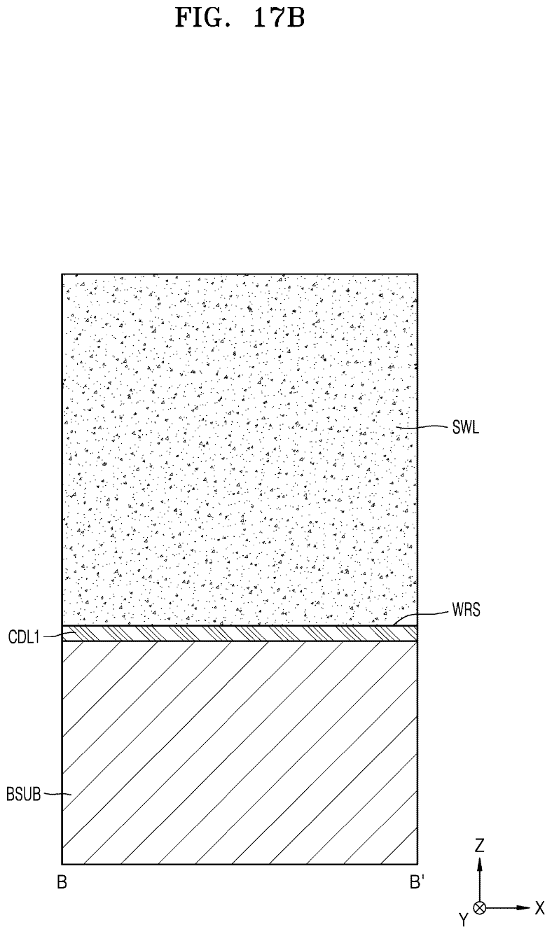

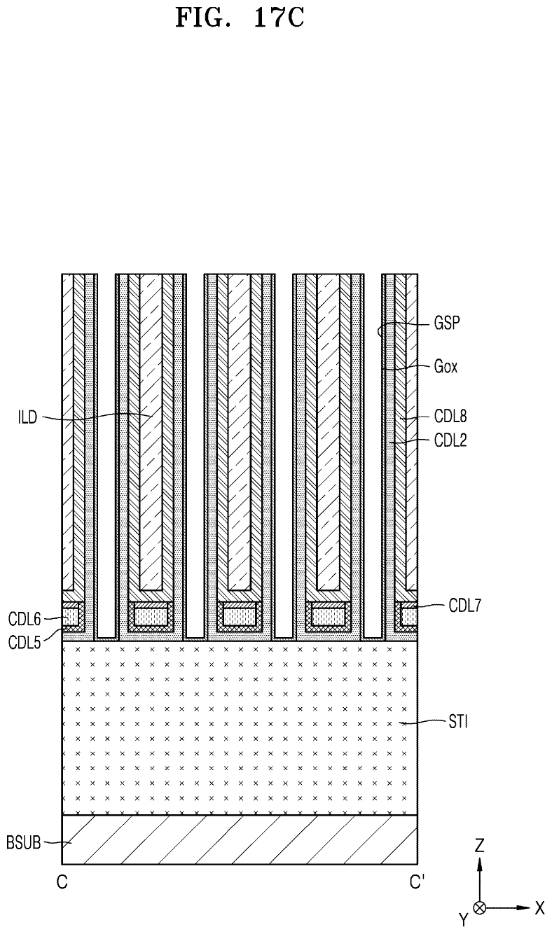

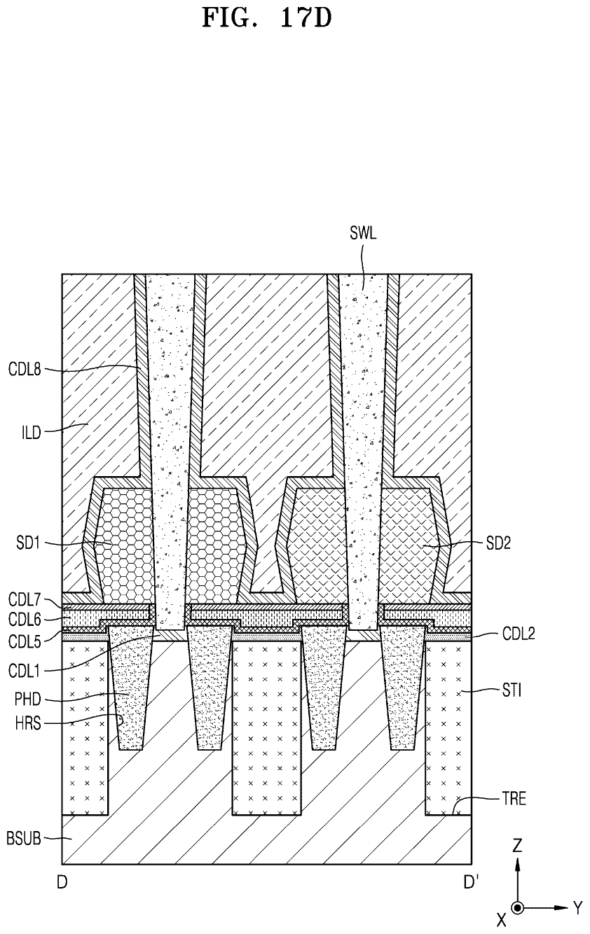

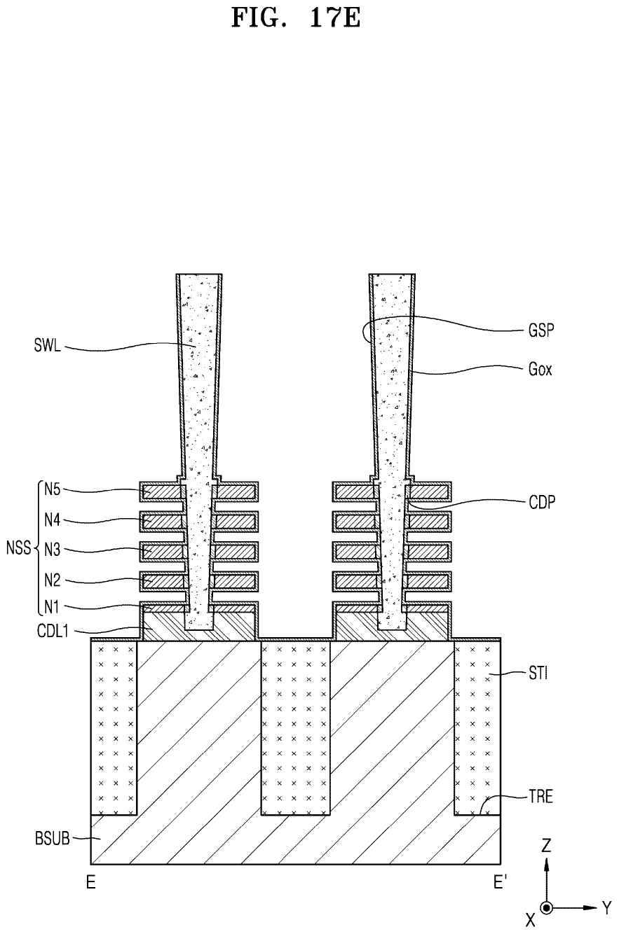

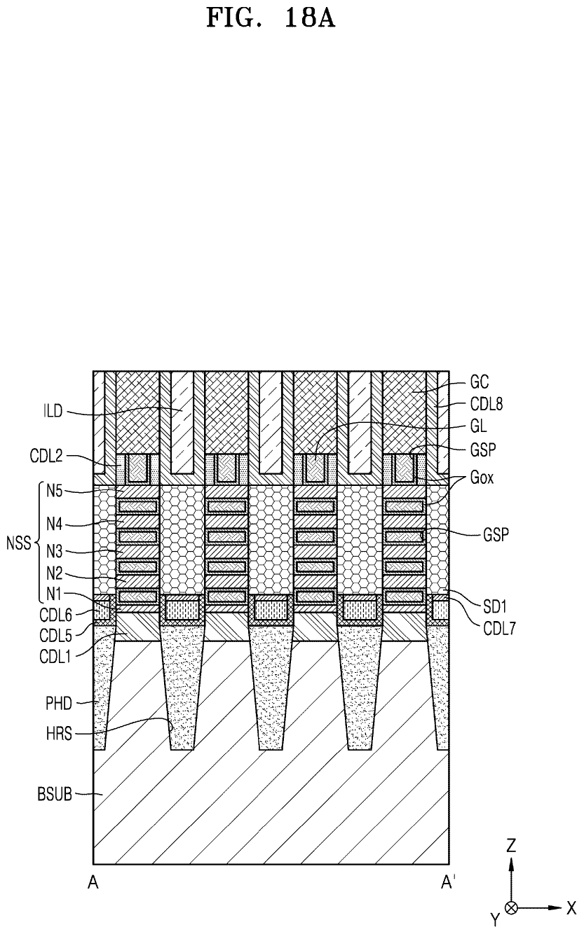

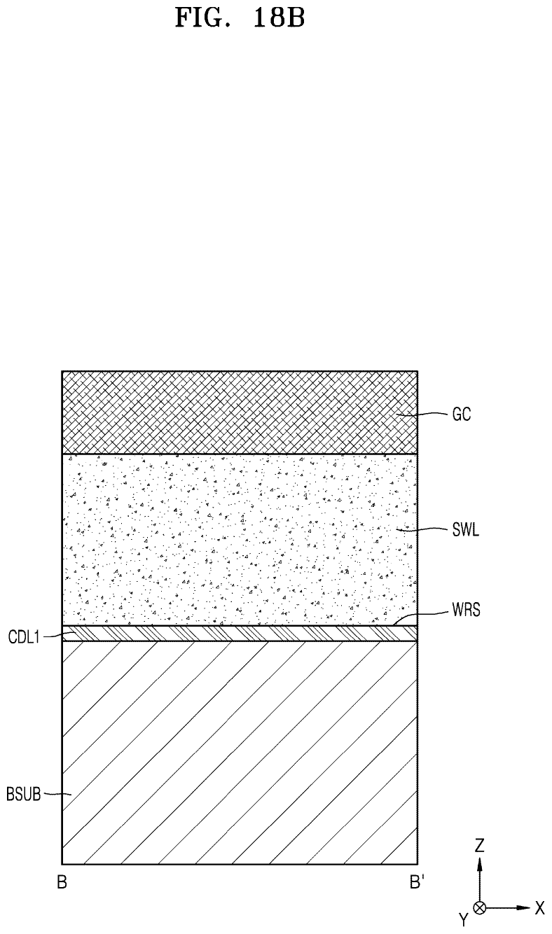

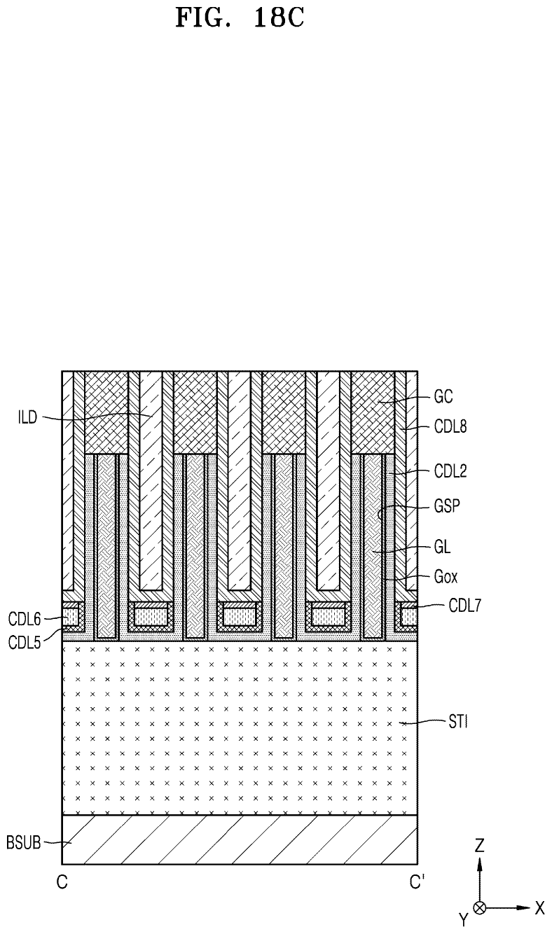

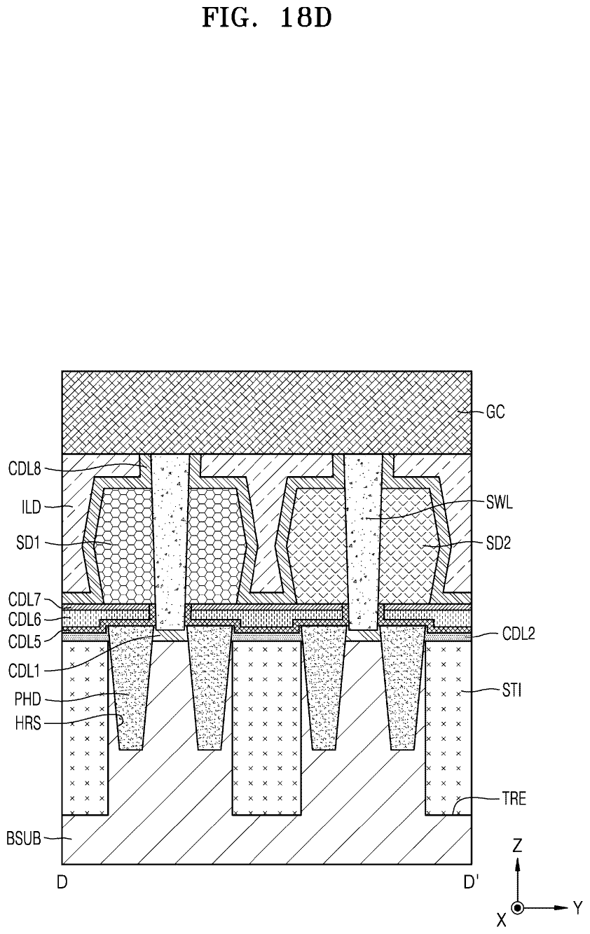

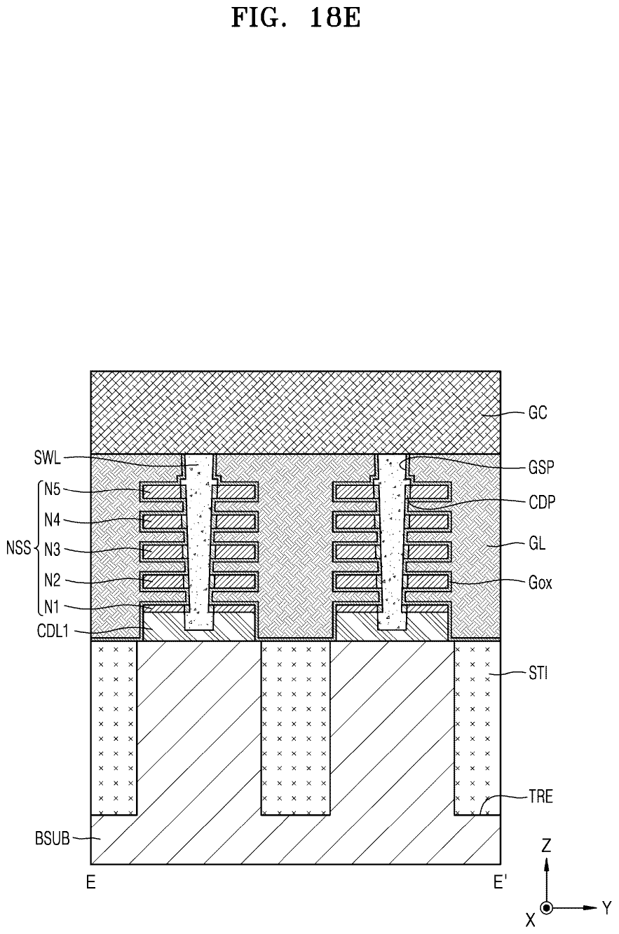

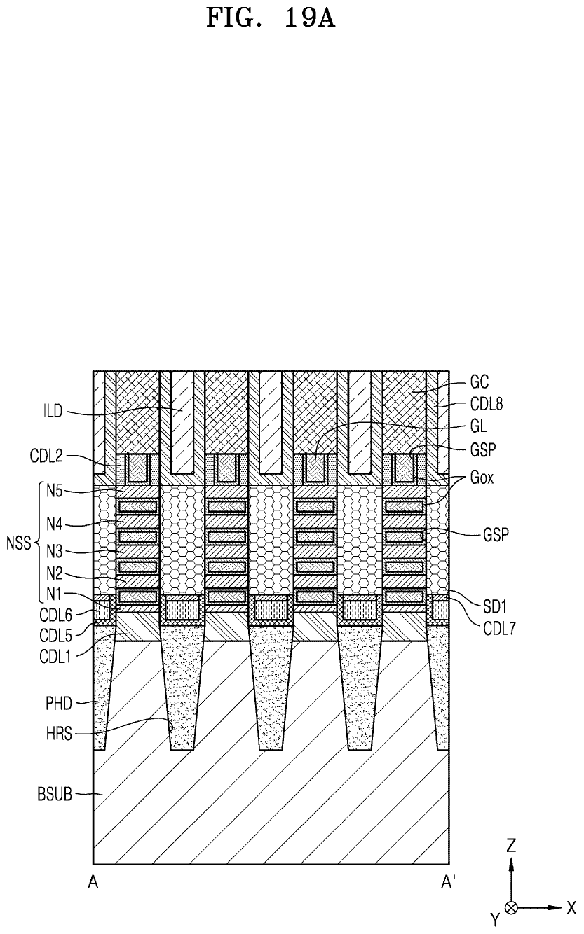

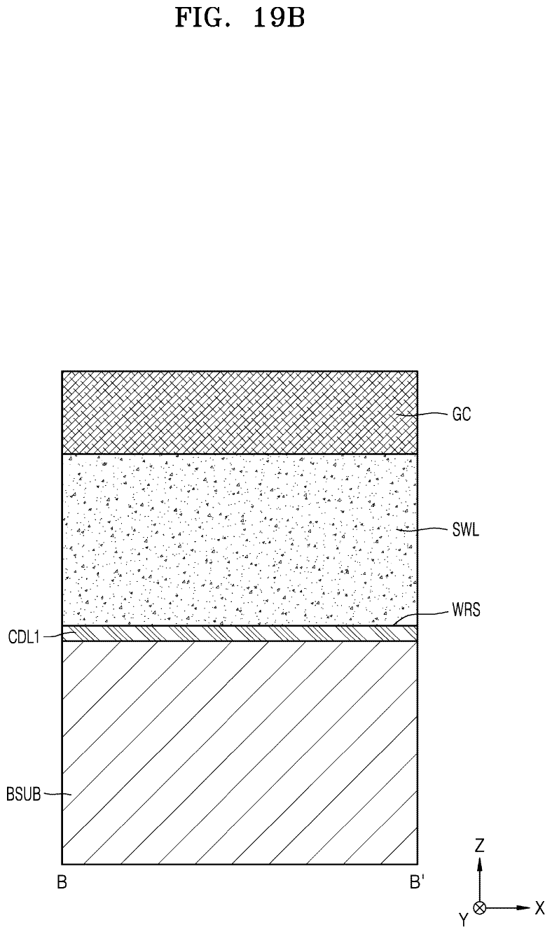

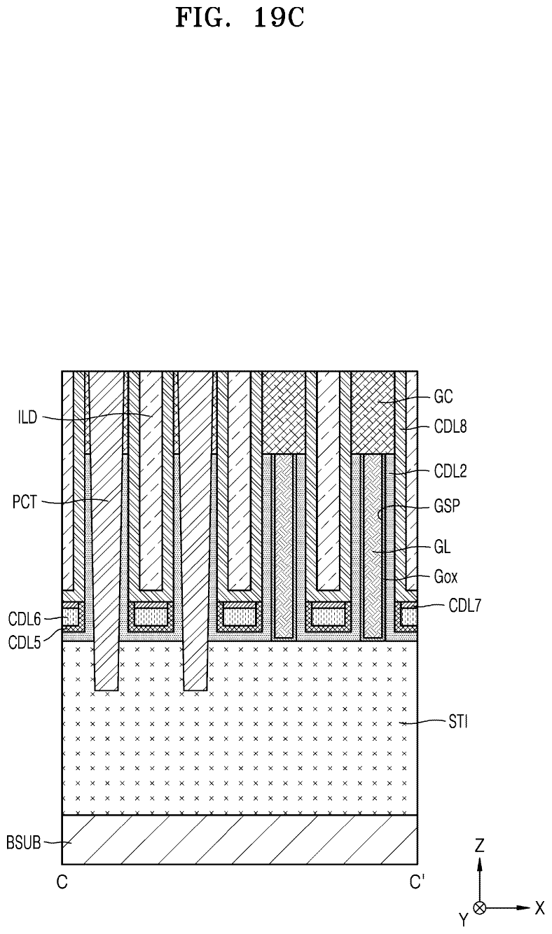

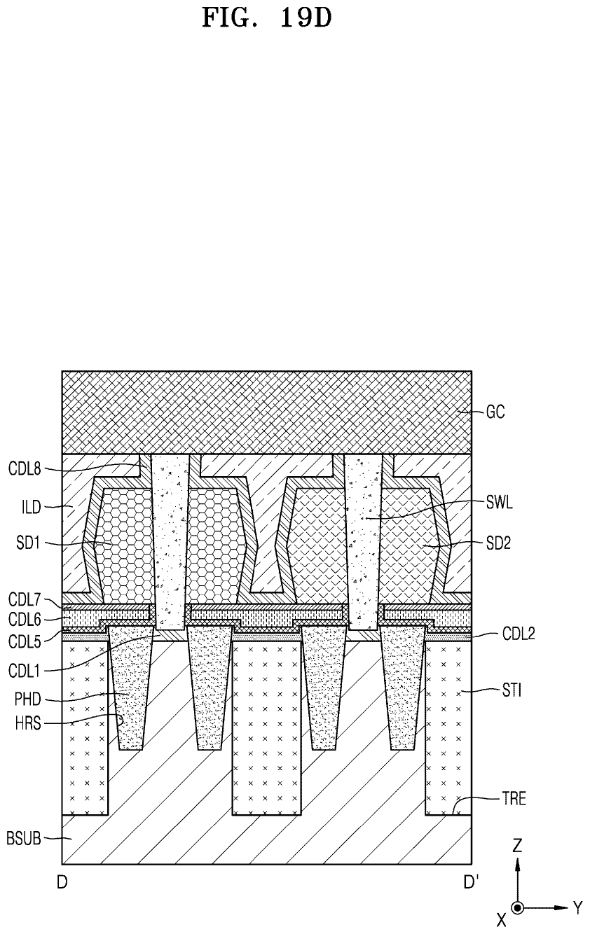

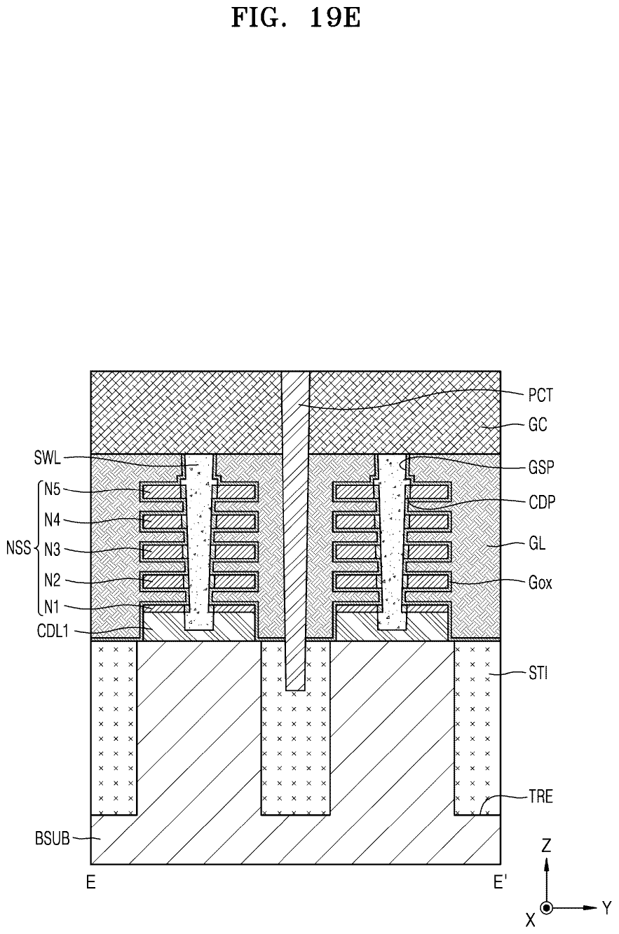

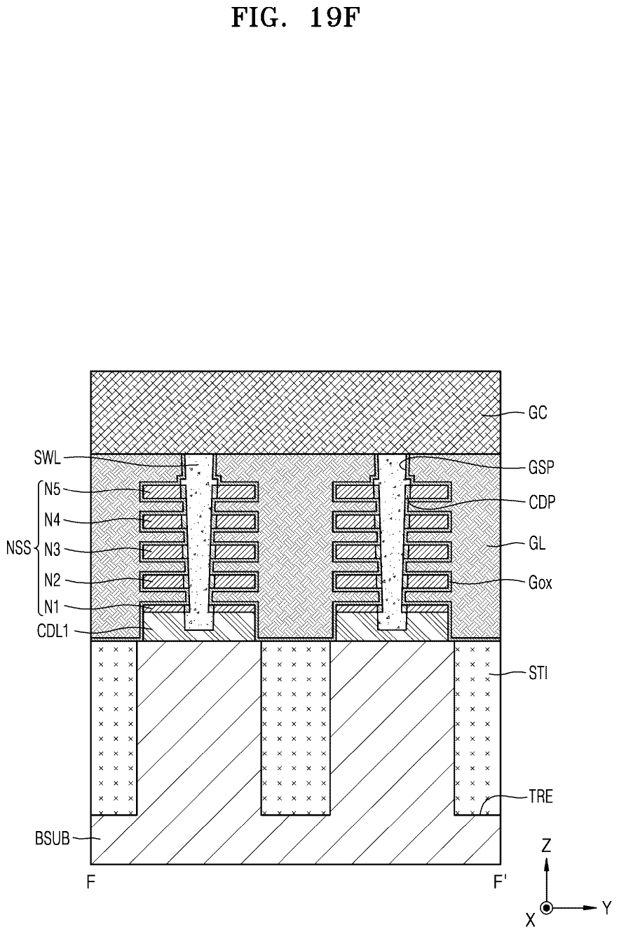

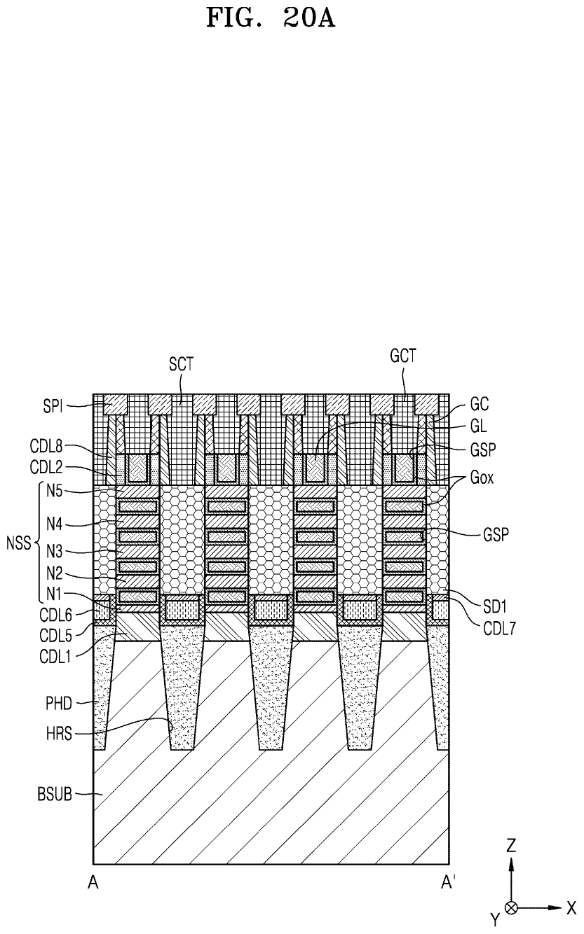

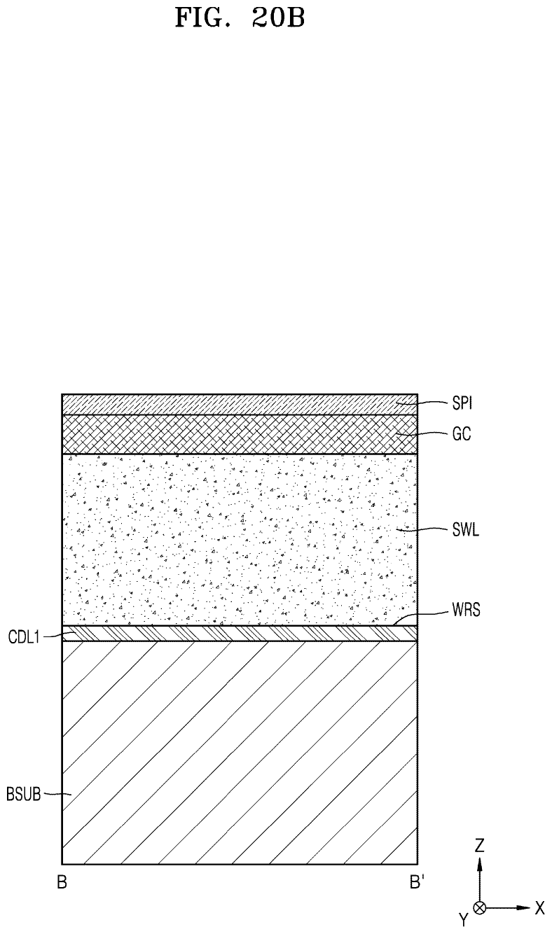

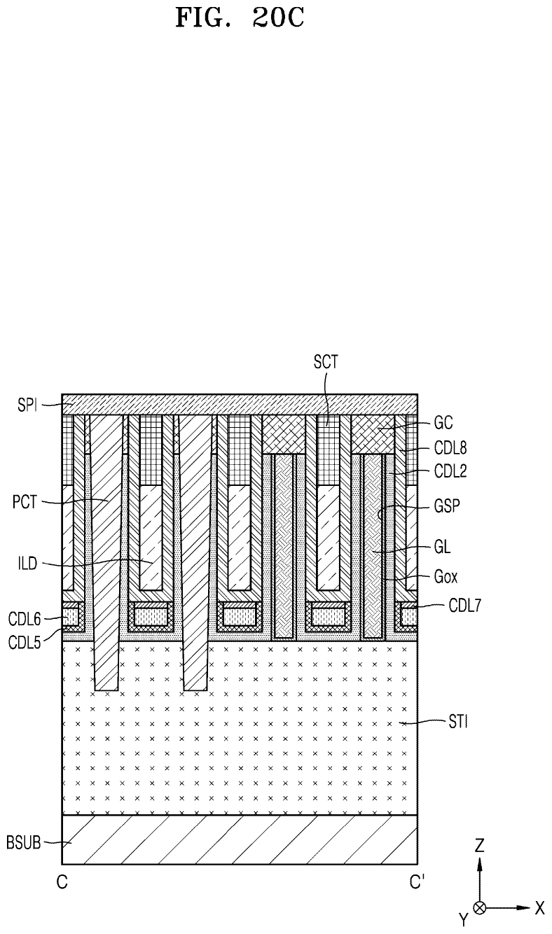

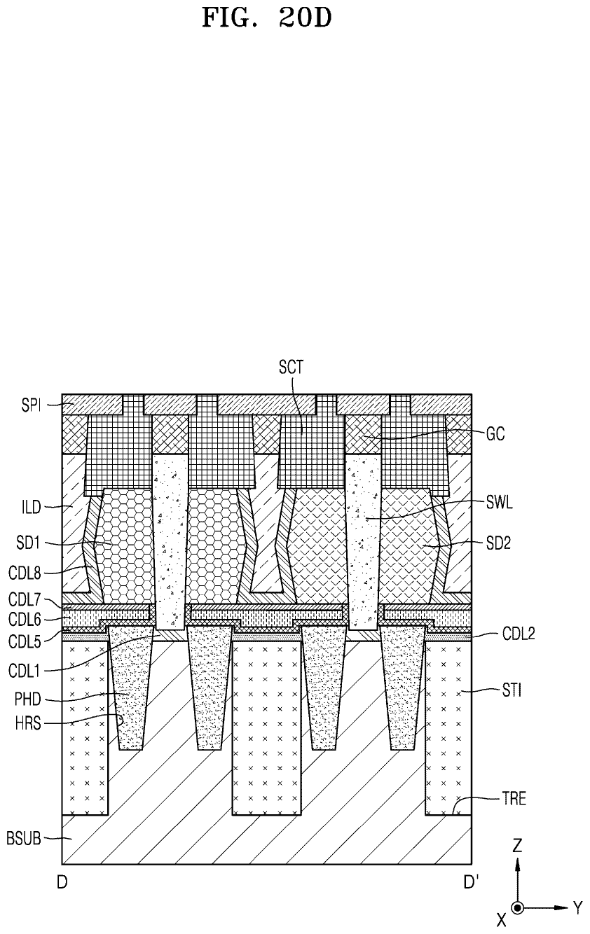

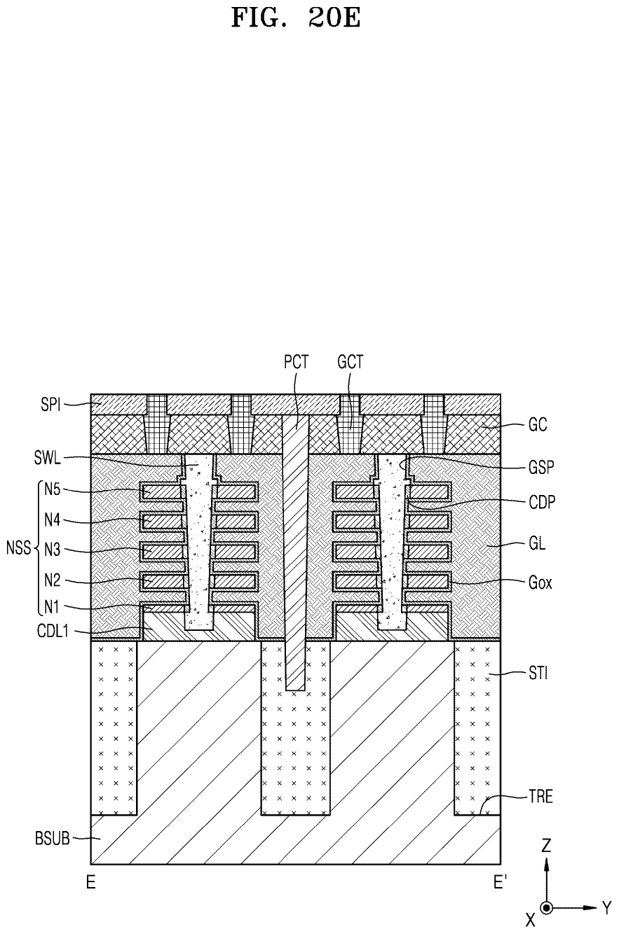

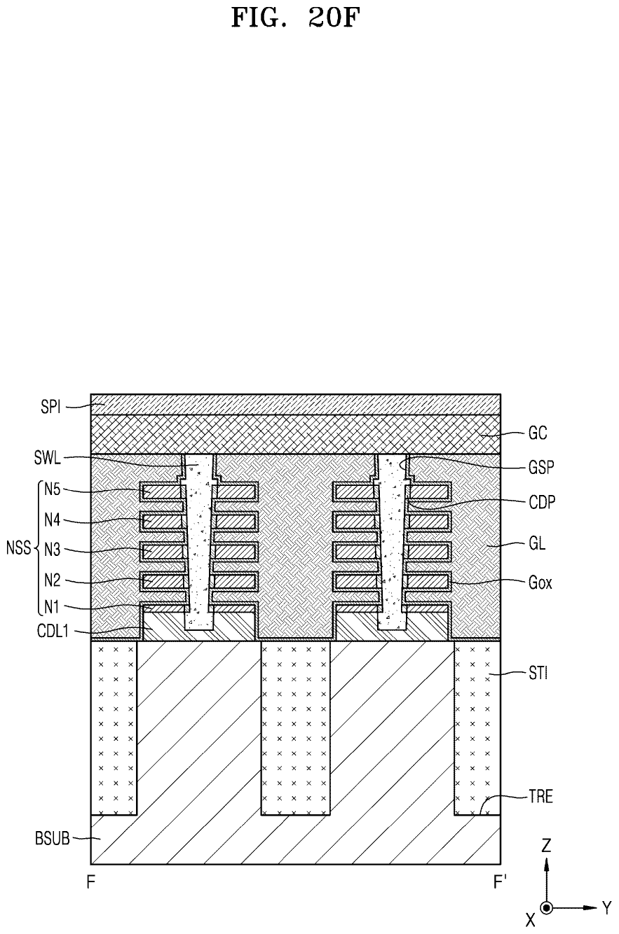

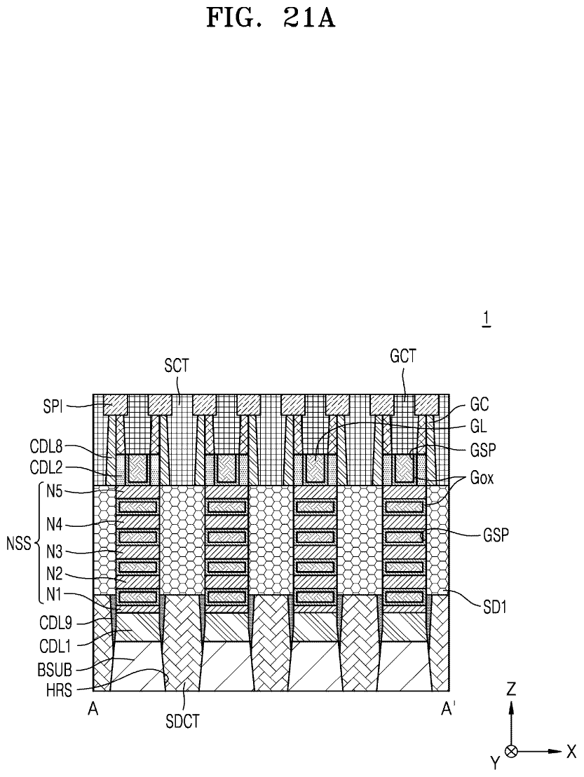

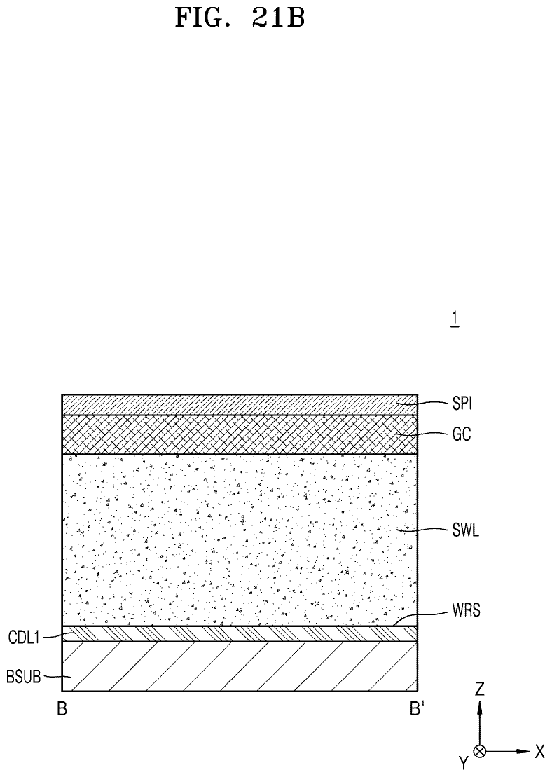

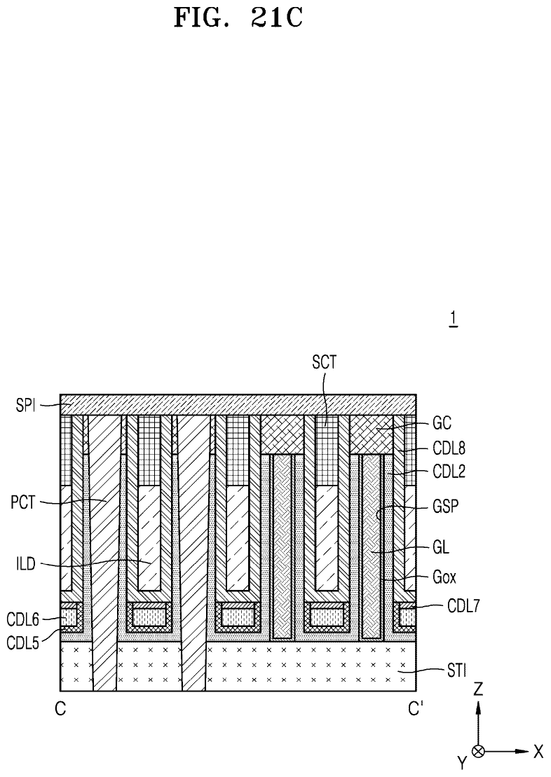

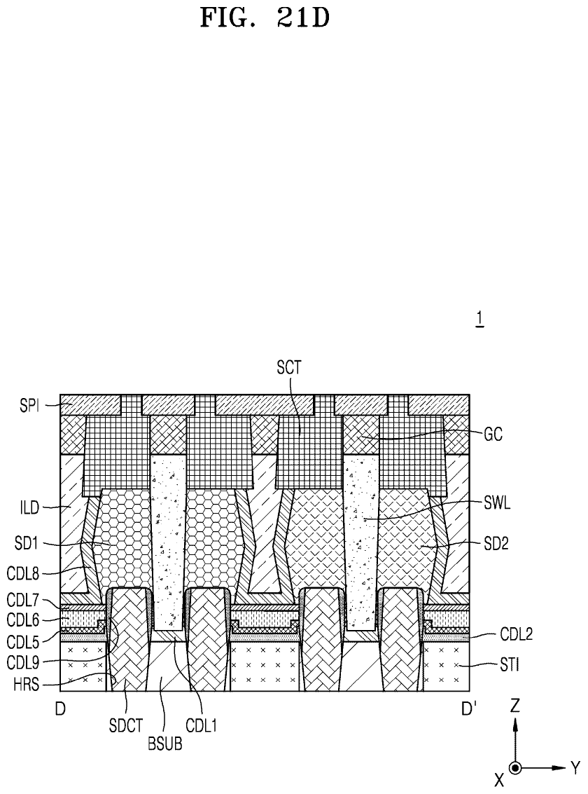

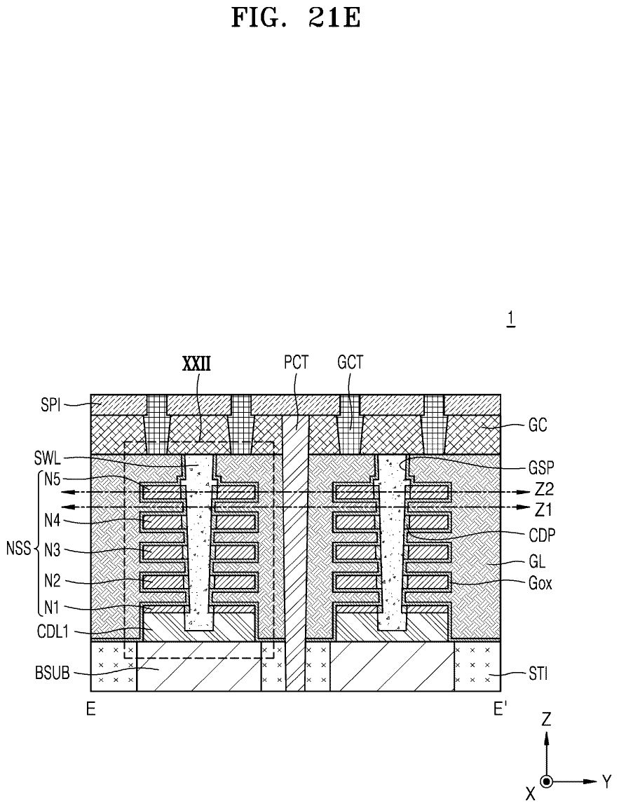

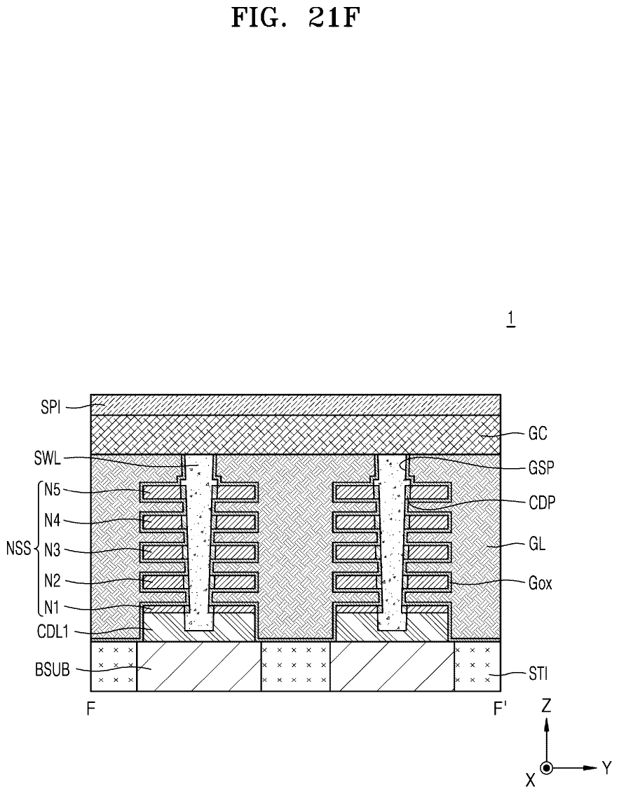

Referring to FIG. 1, the integrated circuit device 1 may include a plurality of sheet separation walls SWL extending in a first horizontal direction (X direction), a plurality of nanosheet stacked structures NSS, a plurality of gate electrodes GL extending in a second horizontal direction (Y direction), and at least one gate cut structure PCT extending in the first horizontal direction (X direction) and cutting across at least some of the plurality of gate electrodes GL. The first horizontal direction (X direction) may be orthogonal to the second horizontal direction (Y direction). Each of the plurality of nanosheet stacked structures NSS may include a plurality of nanosheets (N1, N2, N3, N4, and N5 in FIGS. 21A and 21E), which are apart from each other and stacked in a vertical direction (Z direction).

The integrated circuit device 1 may include a plurality of logic cells. The logic cell may include a plurality of circuit elements, such as a transistor and a resistor, and may be variously configured. The logic cell may constitute, for example, an AND gate, a NAND gate, an OR gate, a NOR gate, an exclusive OR (XOR) gate, an exclusive NOR (XNOR) gate, an inverter (INV), an adder (ADD), a buffer (BUF), a delay (DLY), a filter (FIL), a multiplexer (MXT/MXIT), an OR/AND INV (OAI), an AND/OR (AO) INV (AOI), a D flip-flop, a reset flip-flop, a master-slave flip-flop, a latch, or the like, and may constitute a standard cell performing a logic function.

The plurality of nanosheet stacked structures NSS may be arranged in rows and columns in the first horizontal direction (X direction) and the second horizontal direction (Y direction), respectively. The plurality of nanosheet stacked structures NSS may be adjacent to the plurality of sheet separation walls SWL, and may be arranged in rows in the first horizontal direction (X direction). A corresponding pair of nanosheet stacked structures NSS among the plurality of nanosheet stacked structures NSS may include the sheet separation wall SWL therebetween, and may be arranged apart from each other in the second horizontal direction (Y direction).

The gate electrodes GL separated into two by the gate cut structure PCT may include the gate cut structure PCT therebetween, and may be apart from each other in the second horizontal direction (Y direction).

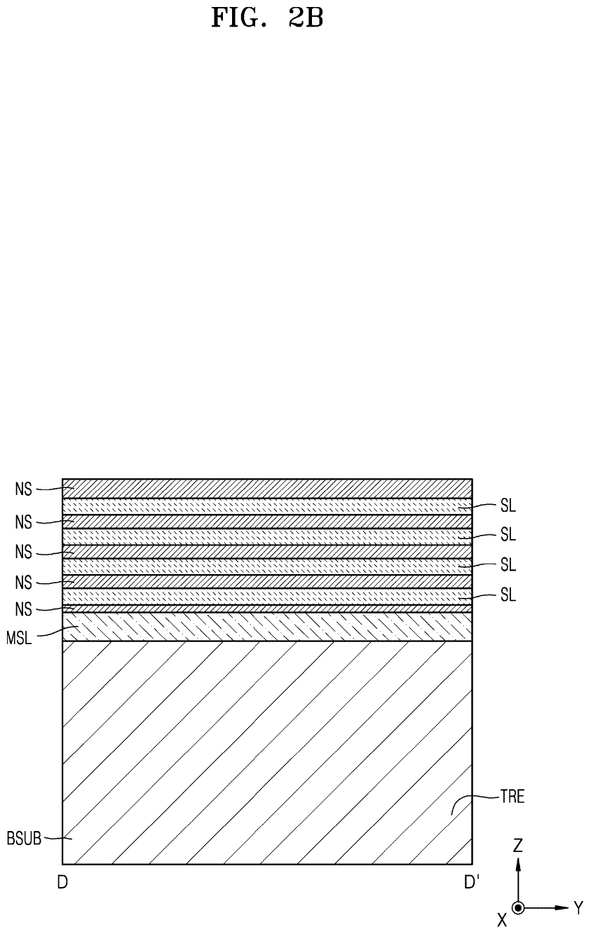

FIGS. 2A, 2B, 3A, 3B, 4A though 4C, 5A through 5D, 6A through 6D, 7A through 7D, 8A through 8D, 9A through 9E, 10A through 10E, 11A through 11E, 12A through 12E, 13A through 13E, 14A through 14E, 15A through 15E, 16A through 16E, 17A through 17E, 18A through 18E, 19A through 19F, and 20A through 20F are vertical cross-sectional views for describing a manufacturing method of the semiconductor device 1, according to some example embodiments. The FIGS. show cross-sectional views taken along a portion corresponding to one of lines A-A′, B-B′, C-C′, D-D′, E-E′, and F-F′ of the semiconductor device 1 in FIG. 1 describing a manufacturing method as may be shown and discussed herein.

Referring to FIGS. 2A and 2B together, after a base sacrificial layer MSL is formed on a base substrate layer BSUB, a plurality of nanosheet semiconductor layers NS and a plurality of sacrificial layers SL may be alternately stacked on the base sacrificial layer MSL one-by-one. Each of the plurality of nanosheet semiconductor layers NS and the plurality of sacrificial layers SL may extend in parallel with an upper surface of the base substrate layer BSUB. In some example embodiments, the nanosheet semiconductor layer NS at the lowest end (for example, corresponding to a lowest layer, or lowest position in the Z direction, etc.) among the plurality of nanosheet semiconductor layers NS may be formed thinner than the other nanosheet semiconductor layers NS. The base substrate layer BSUB may include a semiconductor material, such as silicon (Si) and germanium (Ge), or a compound semiconductor material, such as silicon germanium (SiGe), silicon carbide (SiC), gallium arsenide (GaAs), indium arsenide (InAs), and indium phosphide (InP). In some example embodiments, the base substrate layer BSUB may include at least one of a Group III-V material and a Group IV material. The Group III-V material may include a binary, ternary, or quaternary compound semiconductor material including at least one Group III element and at least one Group V element. The base substrate layer BSUB may include a conductive region, for example, a well doped with impurities, or a structure doped with impurities.

In some example embodiments, the plurality of nanosheet semiconductor layers NS may include a material having etching characteristics that are the same as or similar to a constituting material of the base substrate layer BSUB. The base sacrificial layer MSL may include a material having an etching selectivity of the plurality of nanosheet semiconductor layers NS. The base sacrificial layer MSL may include a material having an etching selectivity of the plurality of sacrificial layers SL. In some example embodiments, each of the plurality of nanosheet semiconductor layers NS and the base substrate layer BSUB may include a semiconductor material, such as Si and Ge. In some example embodiments, the base sacrificial layer MSL and the plurality of sacrificial layers SL may include a chemical semiconductor such as SiGe. For example, the density of the Ge atom of the Si atom and the Ge atom included in the base sacrificial layer MSL may be higher than that included in each of the plurality of sacrificial layers SL.

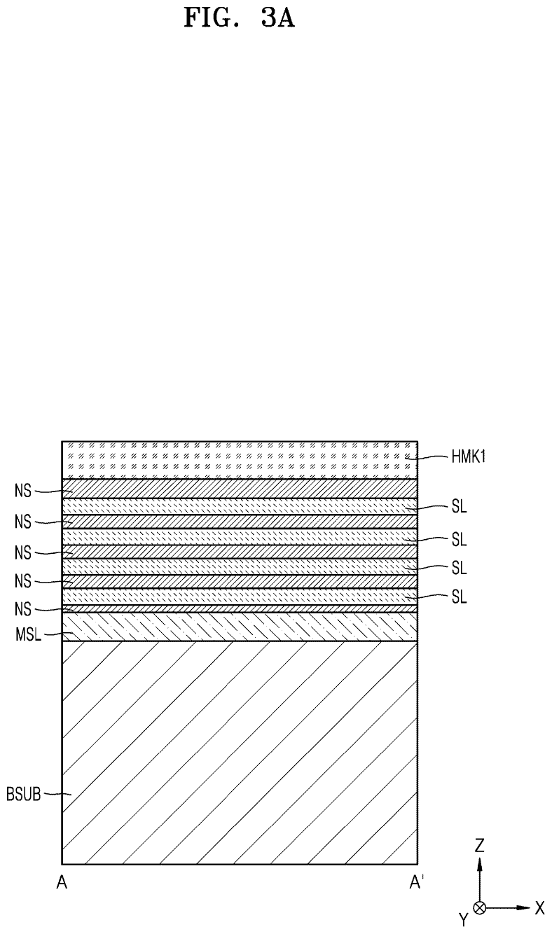

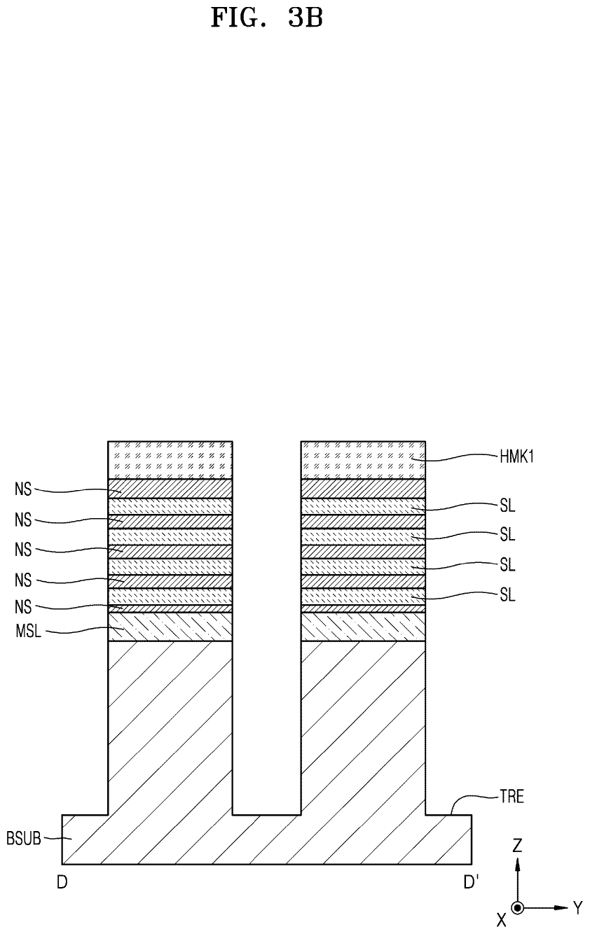

Referring to FIGS. 3A and 3B, after a plurality of first hard mask patterns HMK1 are formed on the plurality of nanosheet semiconductor layers NS, the plurality of nanosheet semiconductor layers NS, the plurality of sacrificial layers SL, and the base sacrificial layer MSL may be patterned with the plurality of first hard mask patterns HMK1 as etching masks, and by removing a portion of the base substrate layer BSUB exposed between the patterned resultant product together, a plurality of trenches TRE may be formed. The plurality of first hard mask patterns HMK1 may extend in the first horizontal direction (X direction), and may be formed apart from each other in the second horizontal direction (Y direction). Each of the plurality of first hard mask patterns HMK1 may include nitride. For example, each of the plurality of first hard mask patterns HMK1 may include silicon nitride. Thereafter, the plurality of first hard mask patterns HMK1 may be removed.

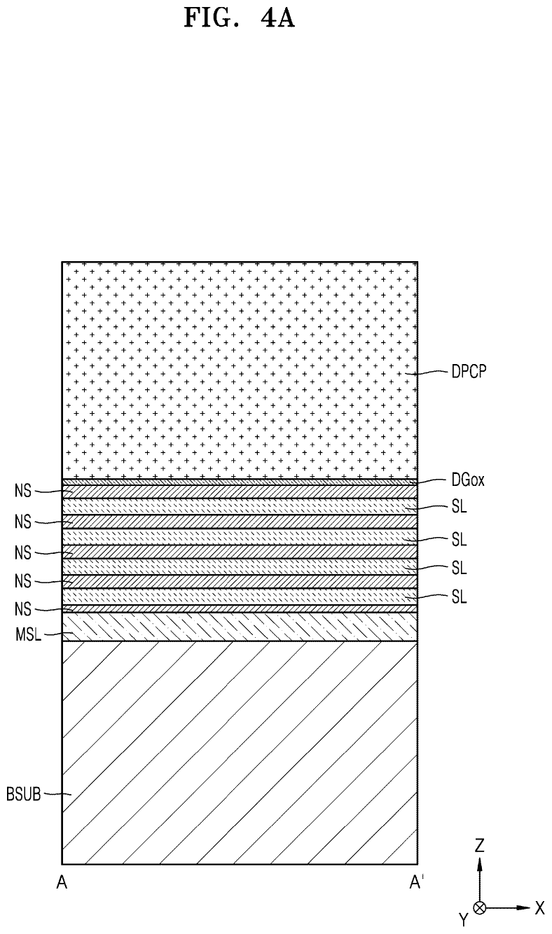

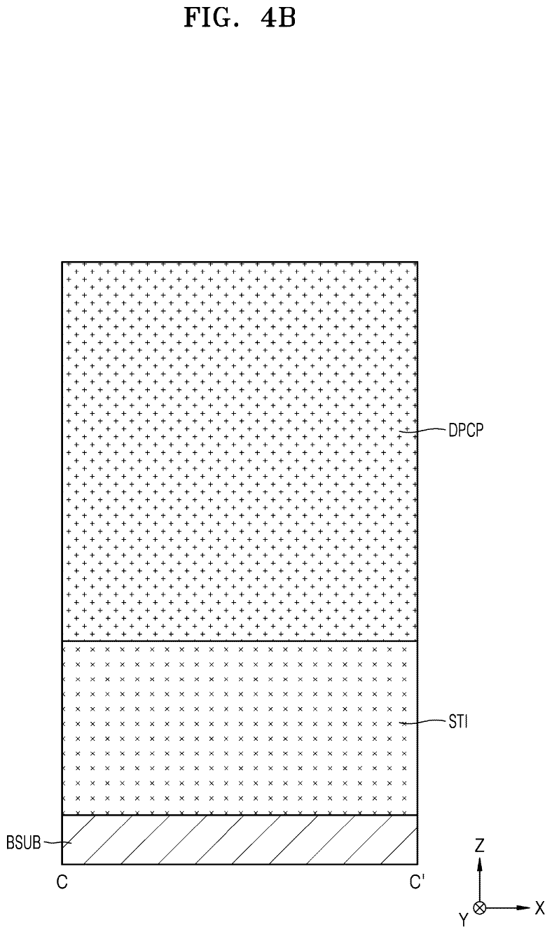

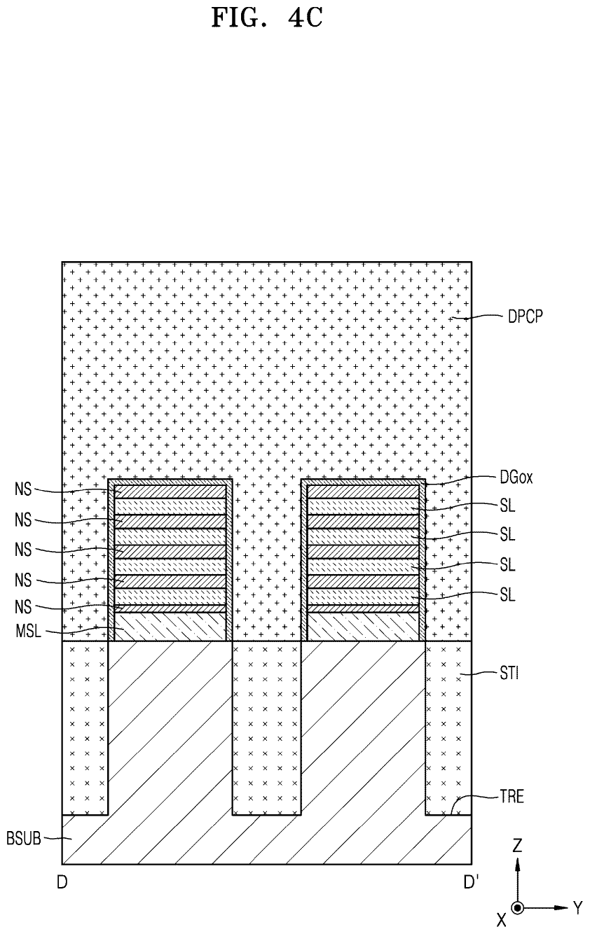

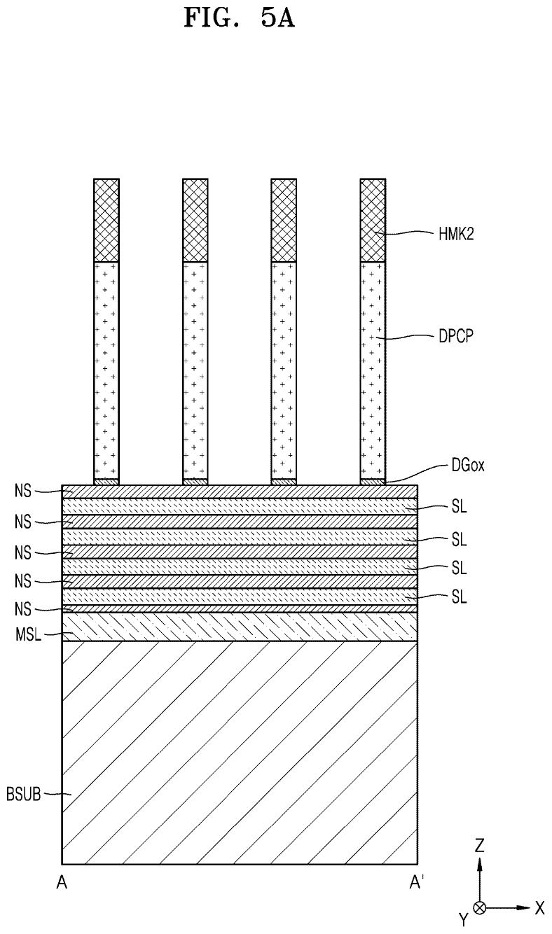

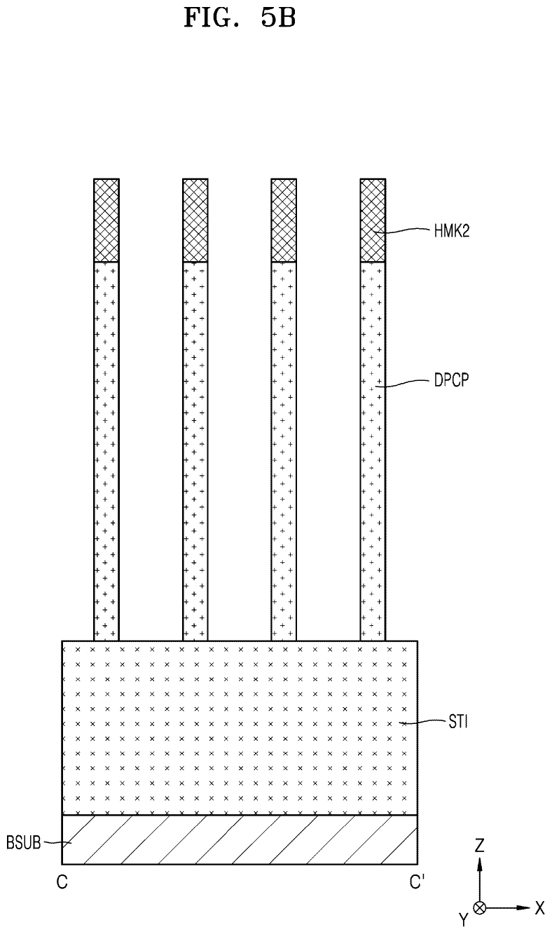

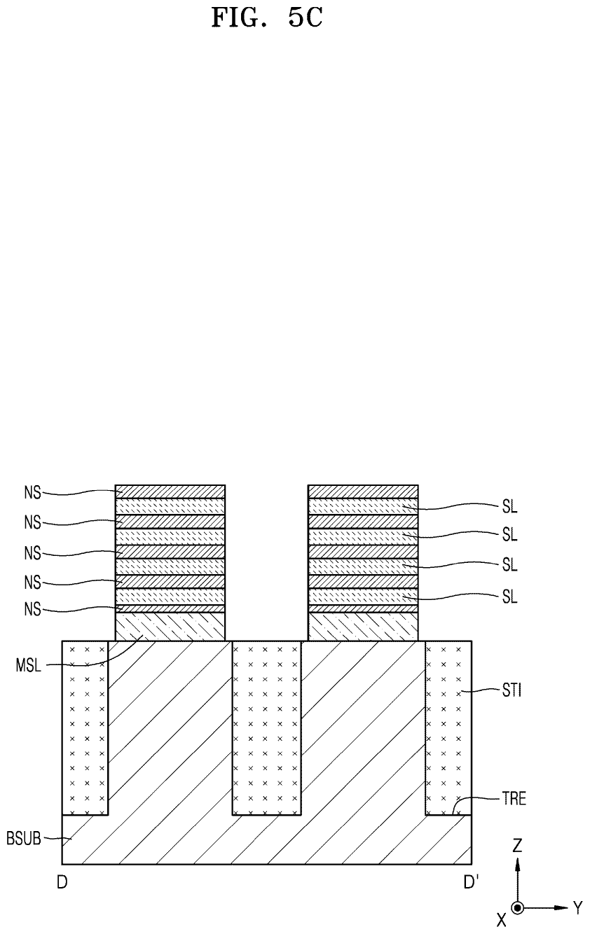

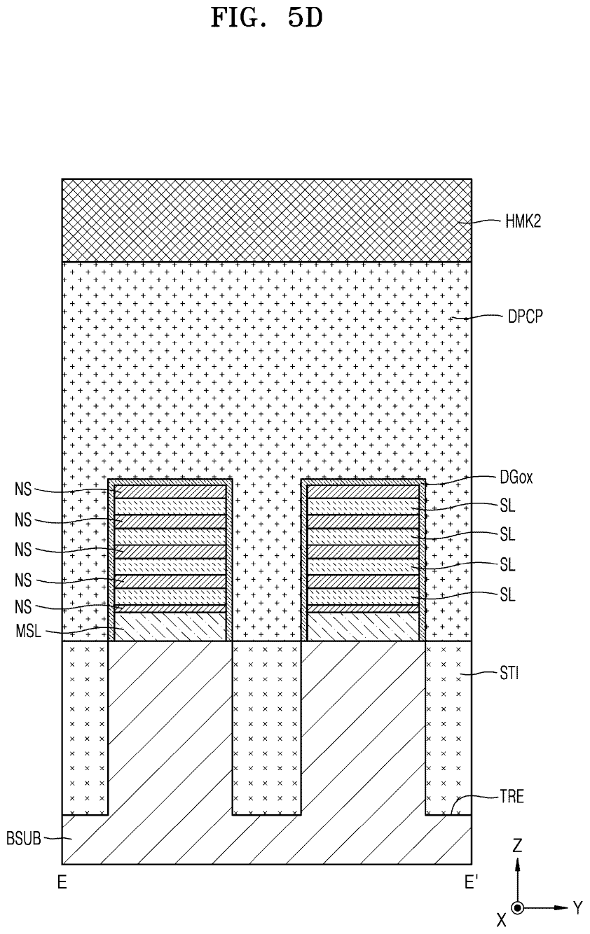

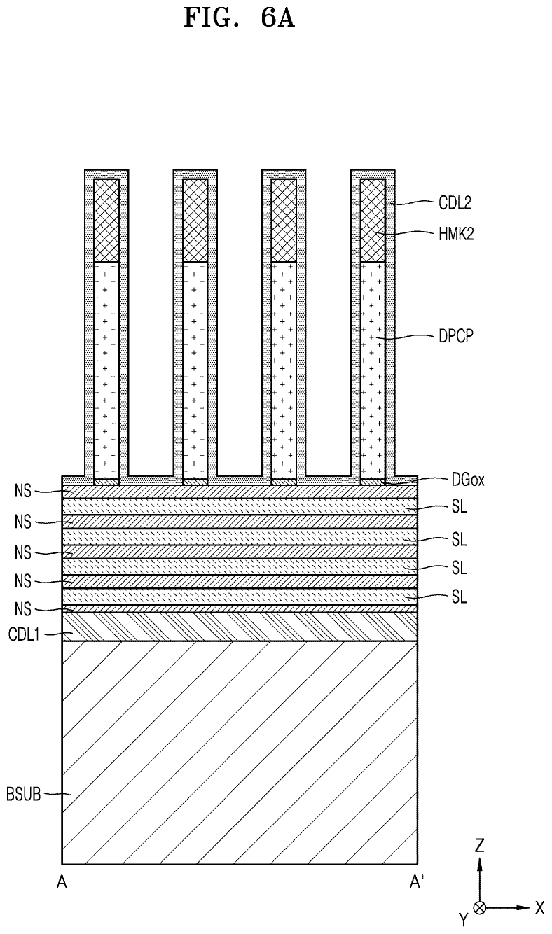

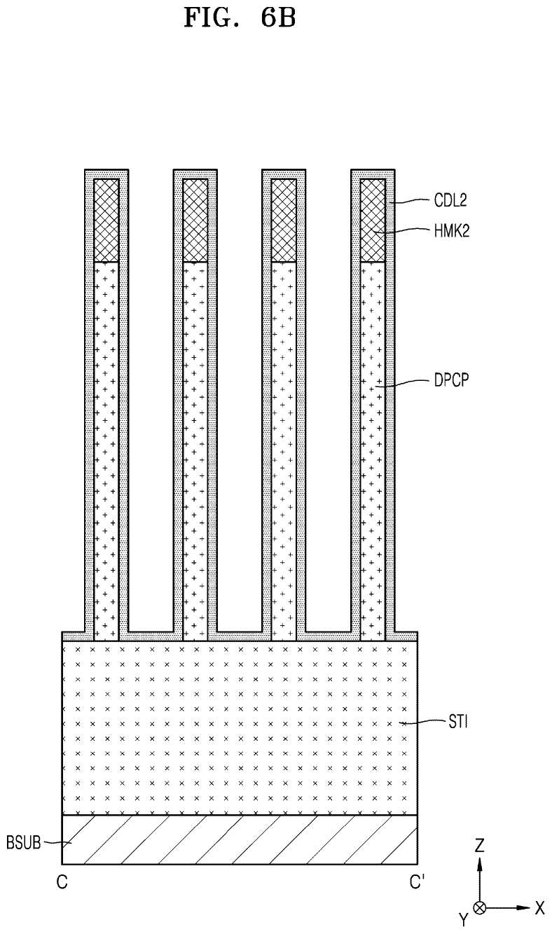

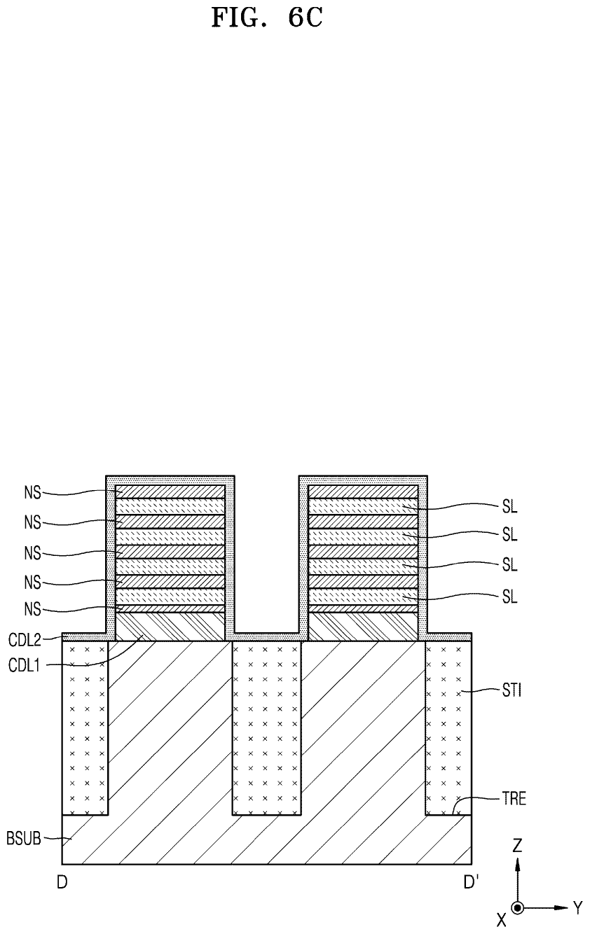

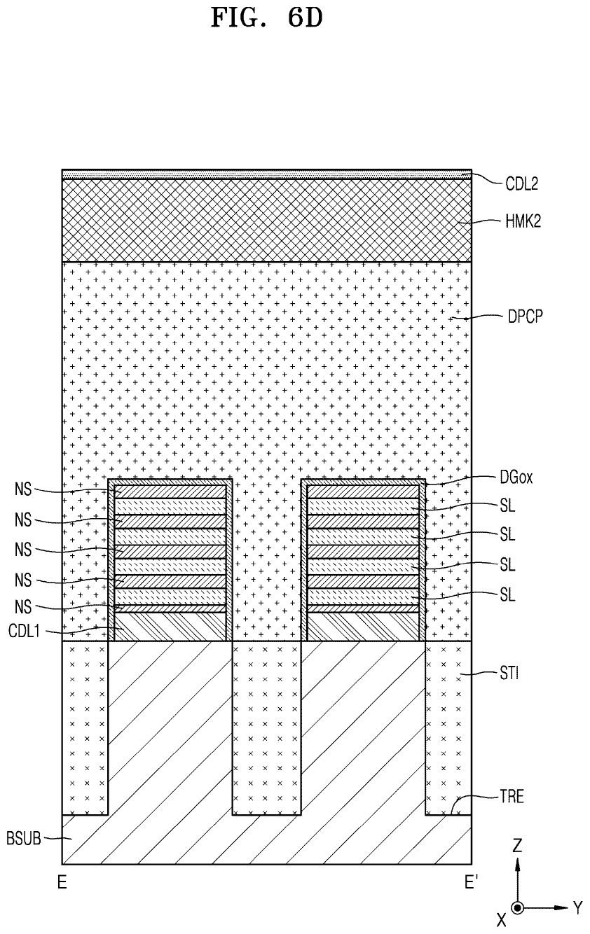

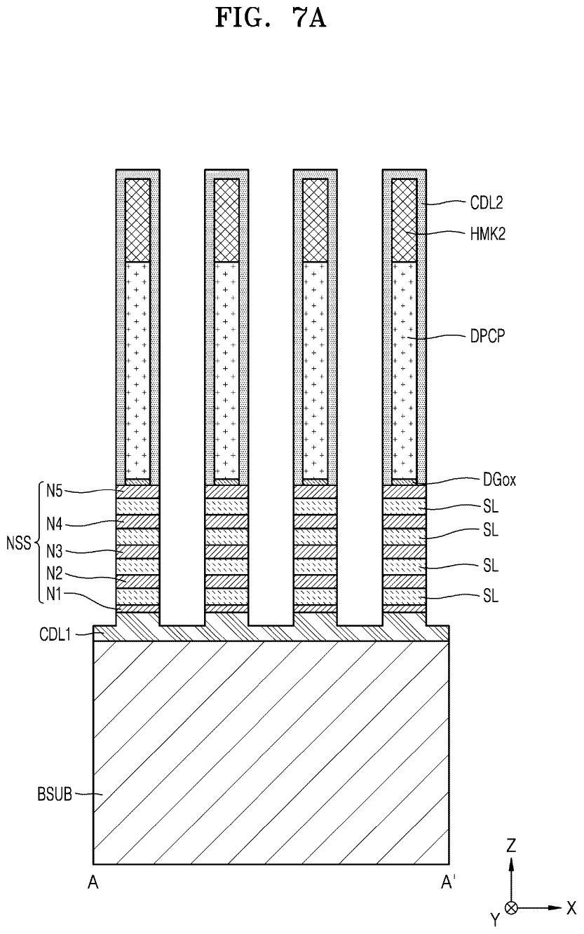

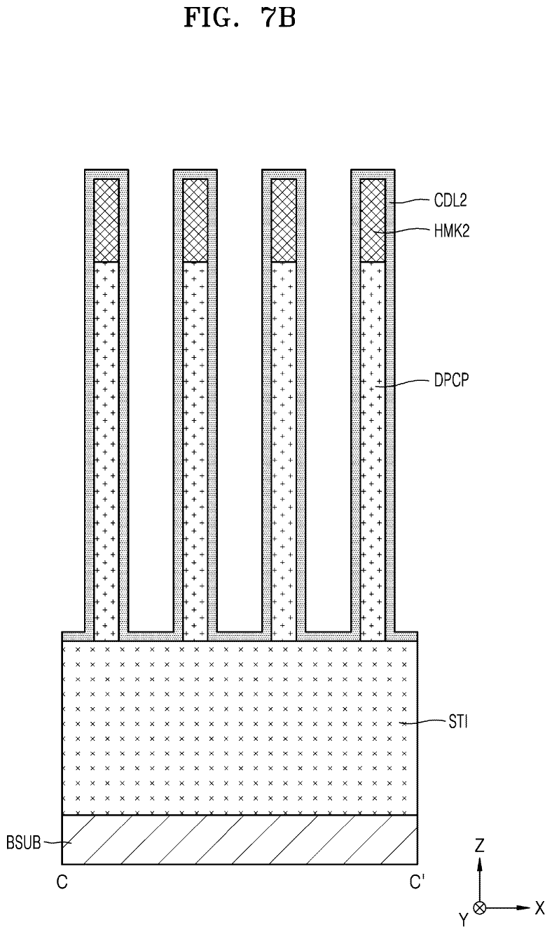

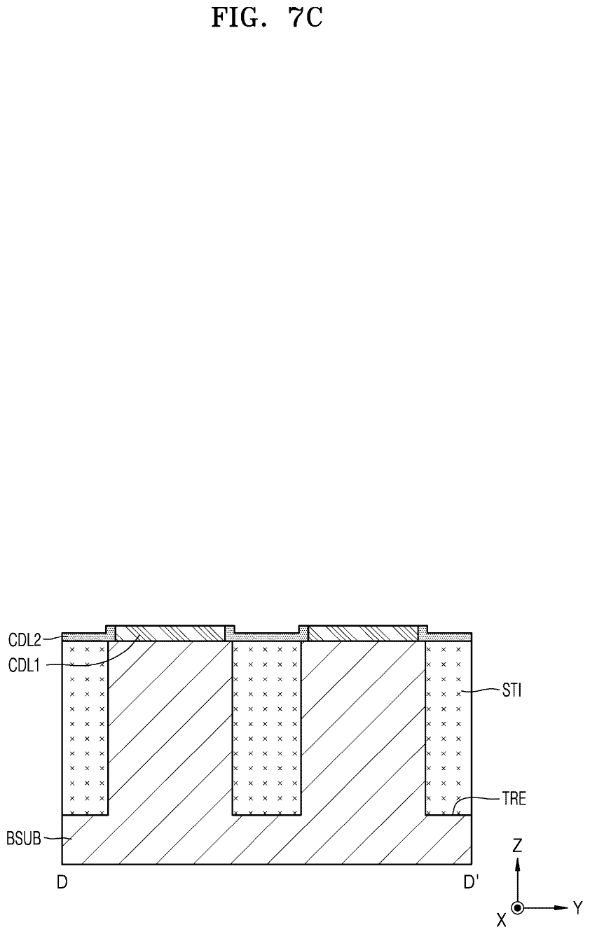

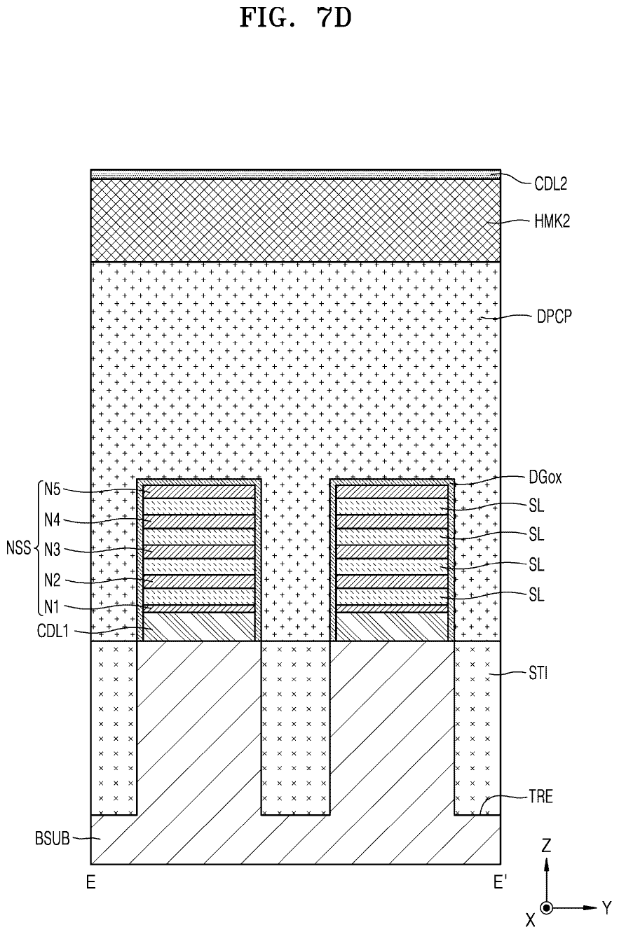

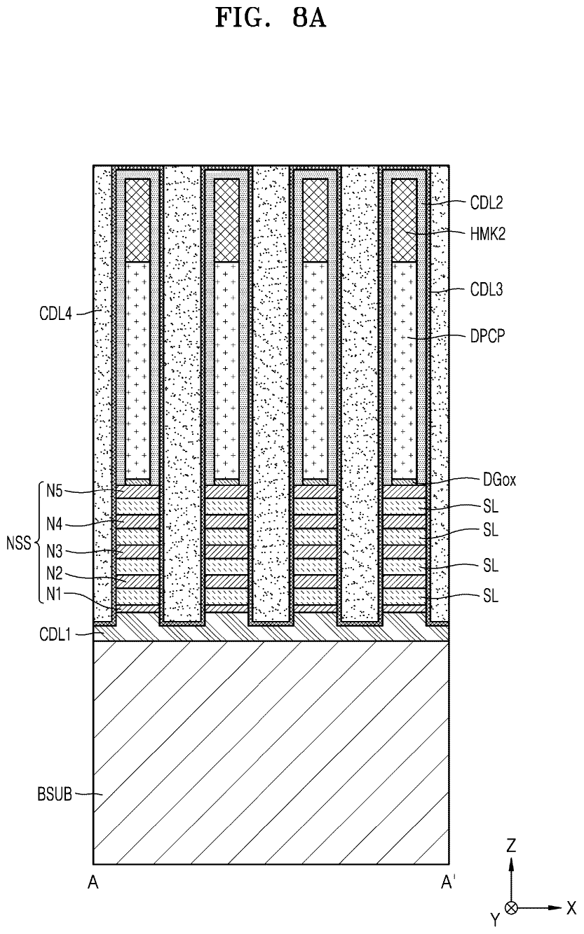

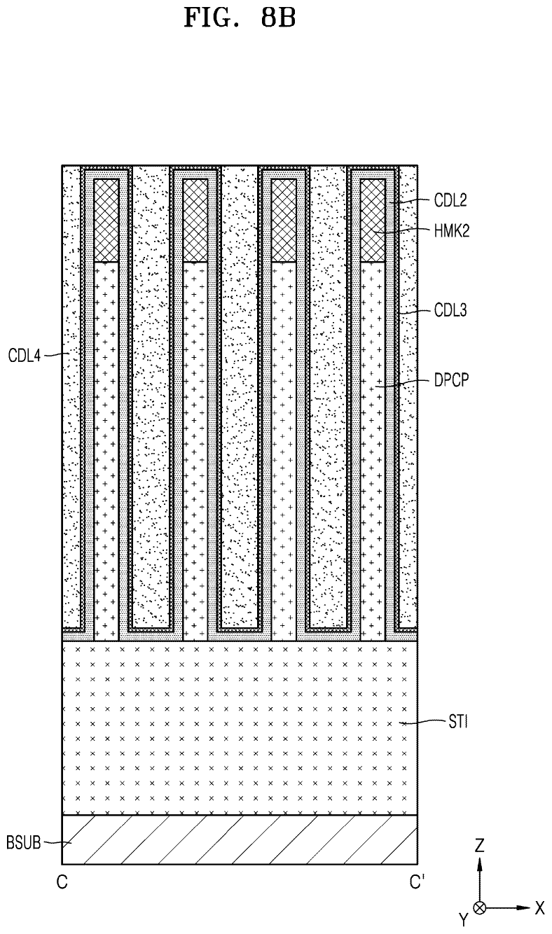

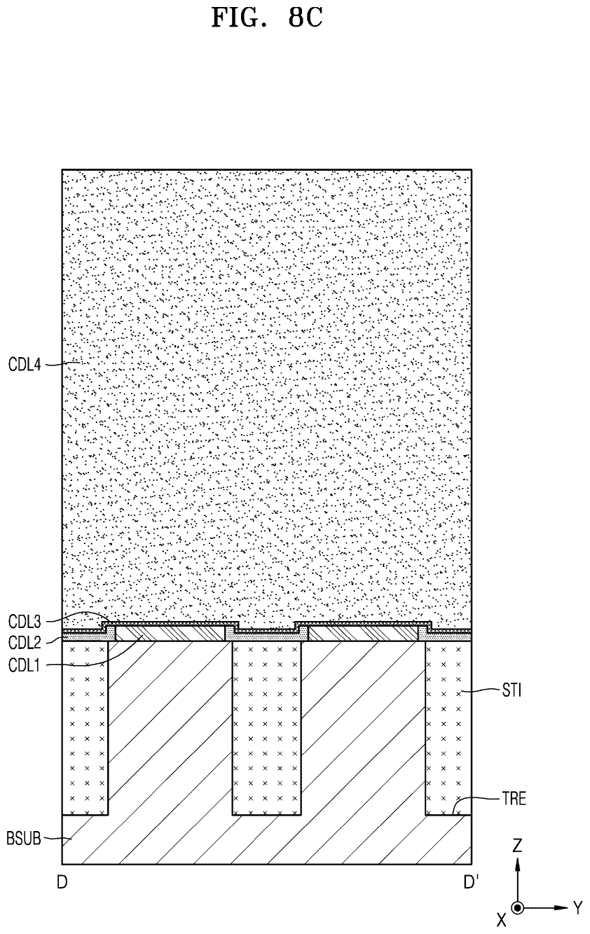

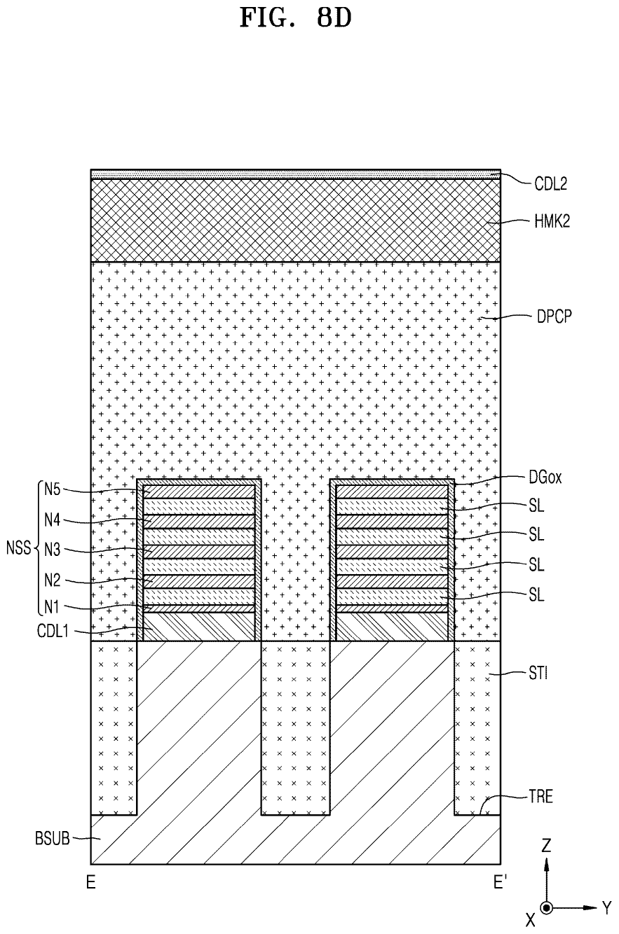

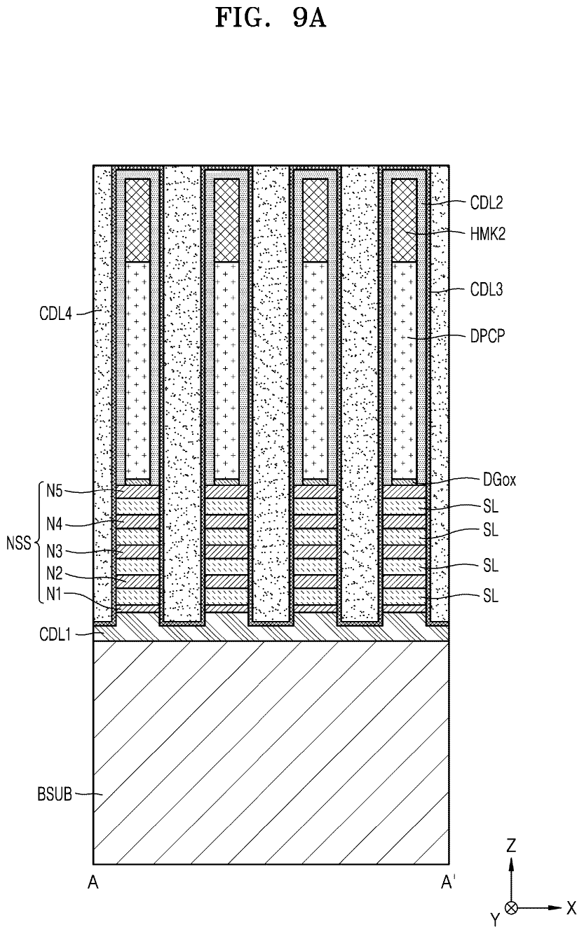

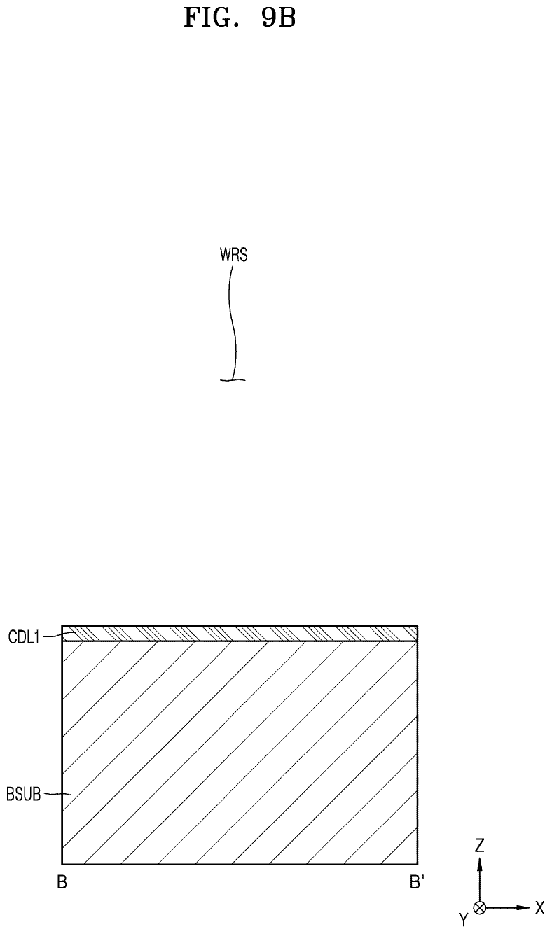

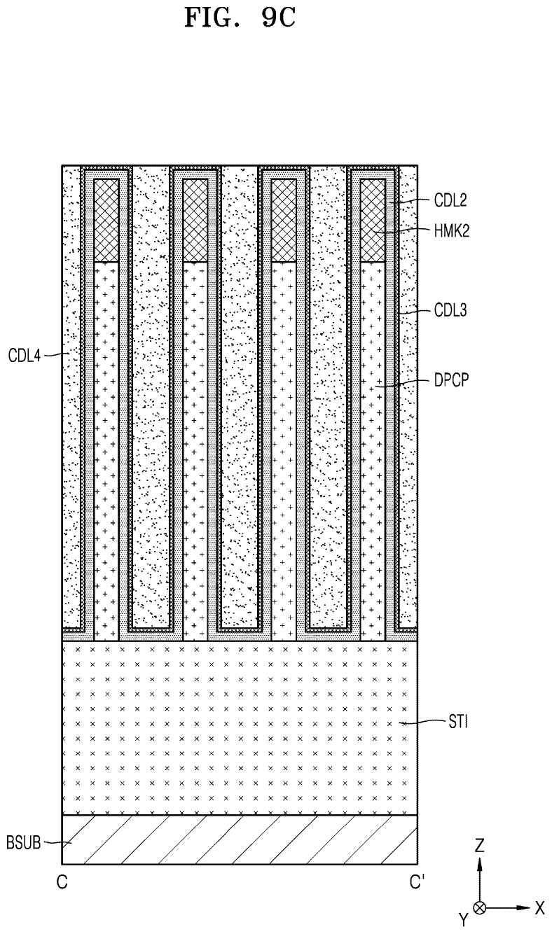

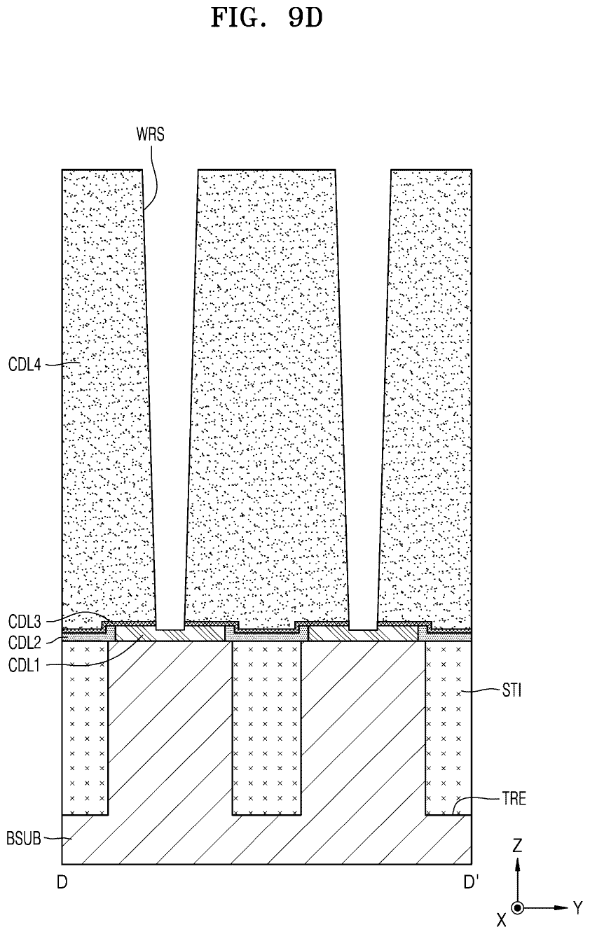

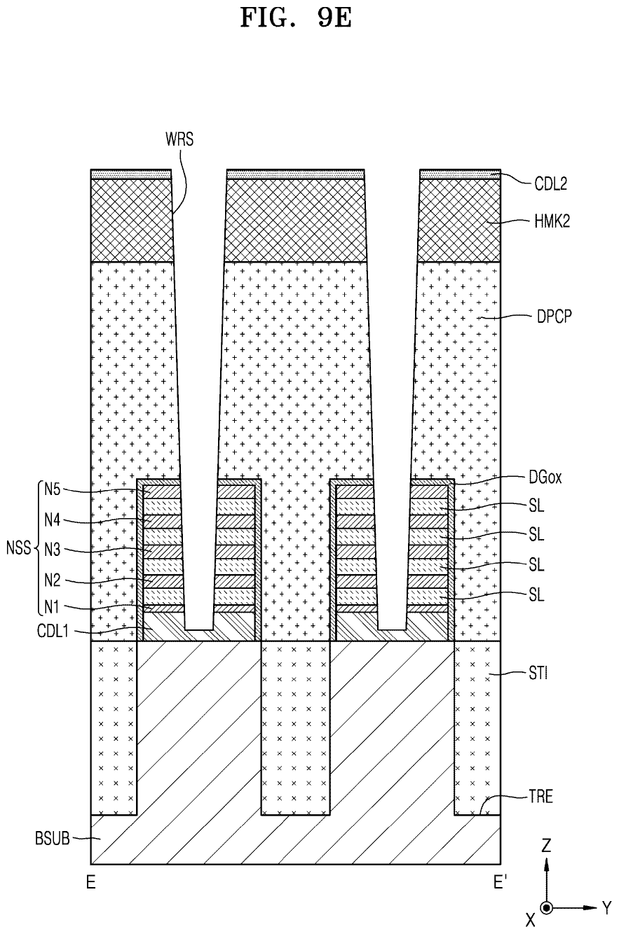

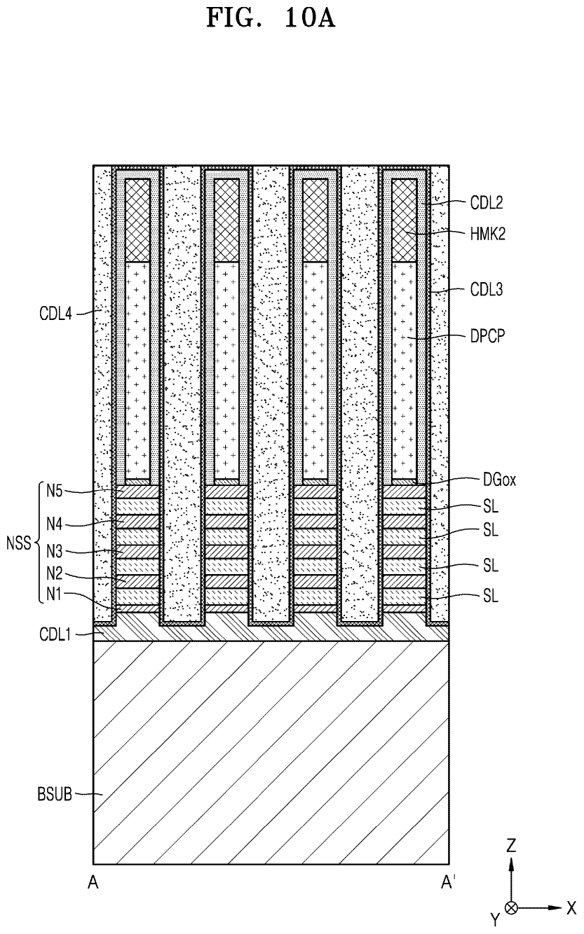

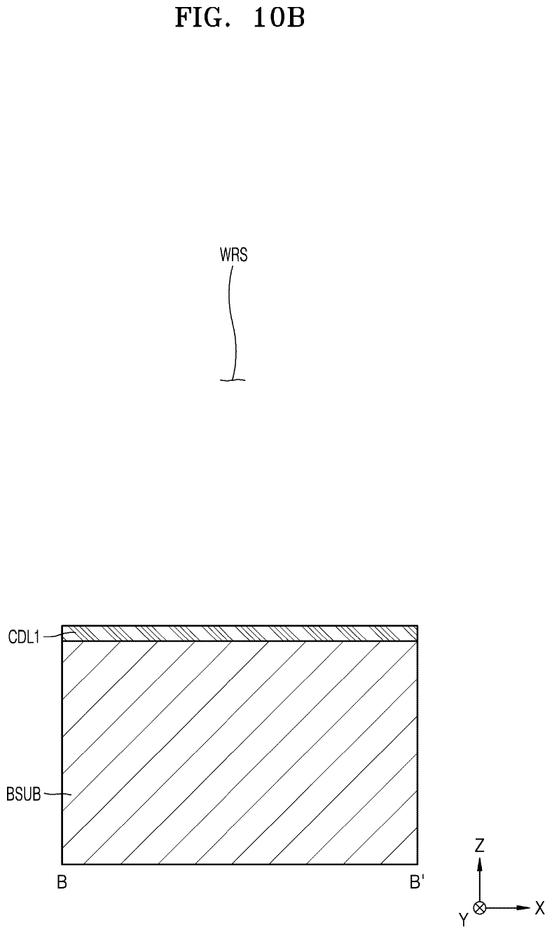

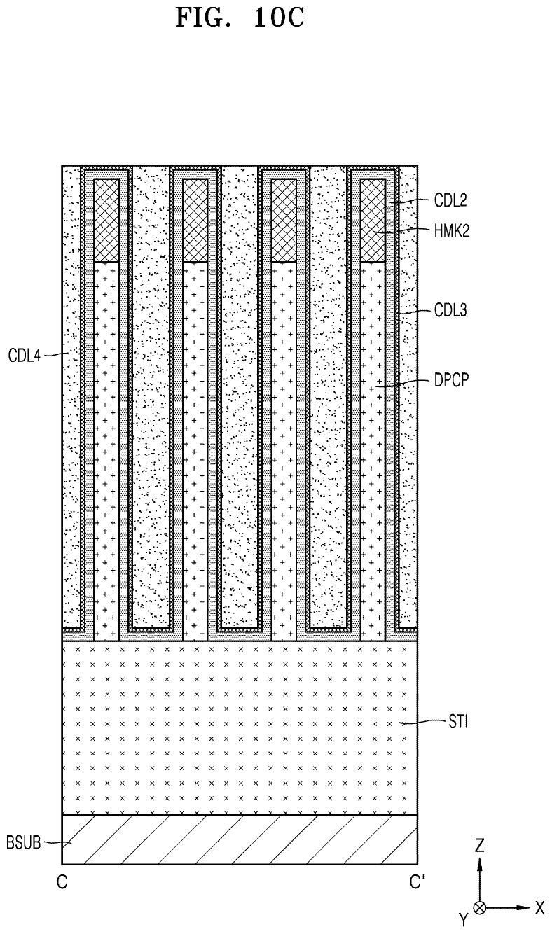

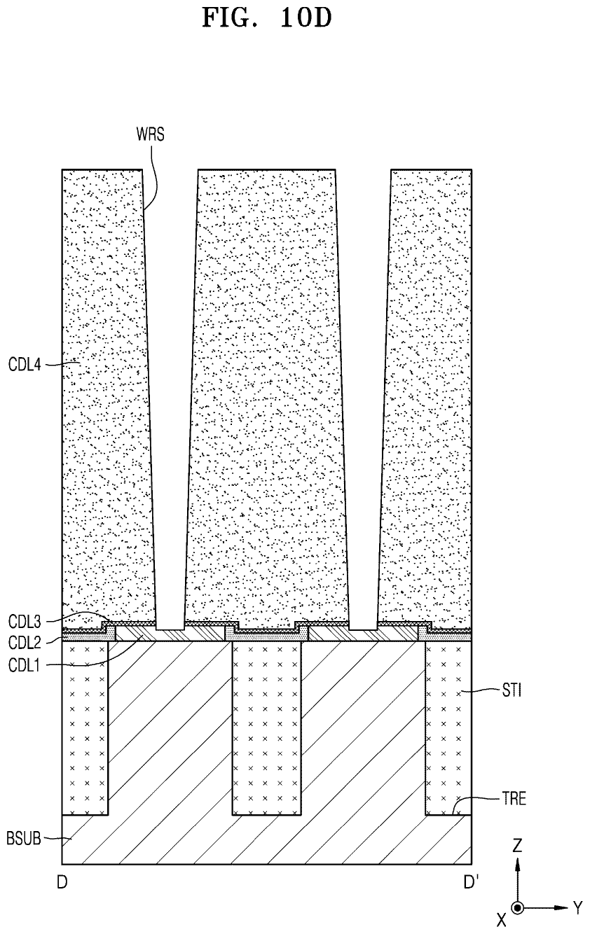

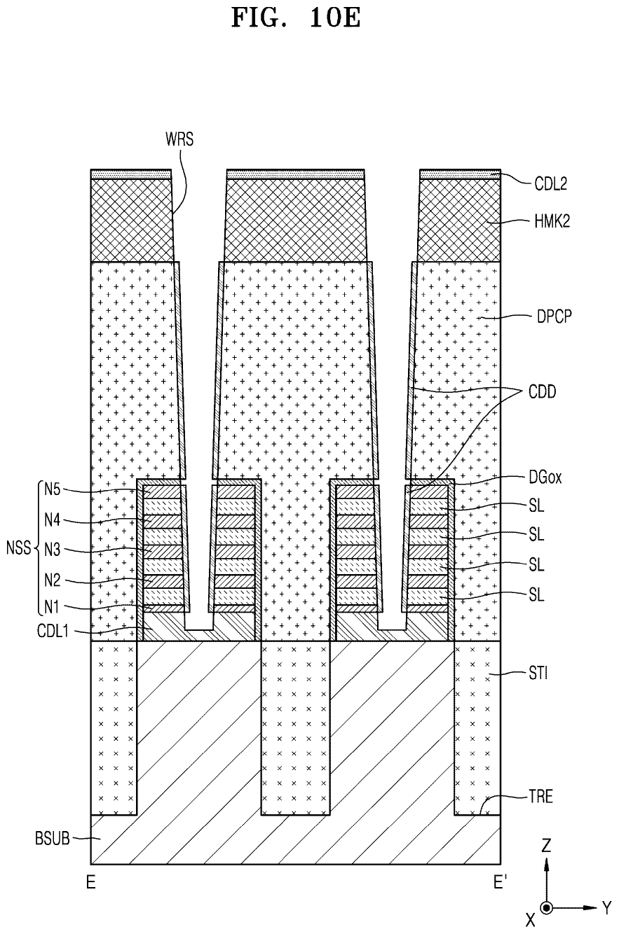

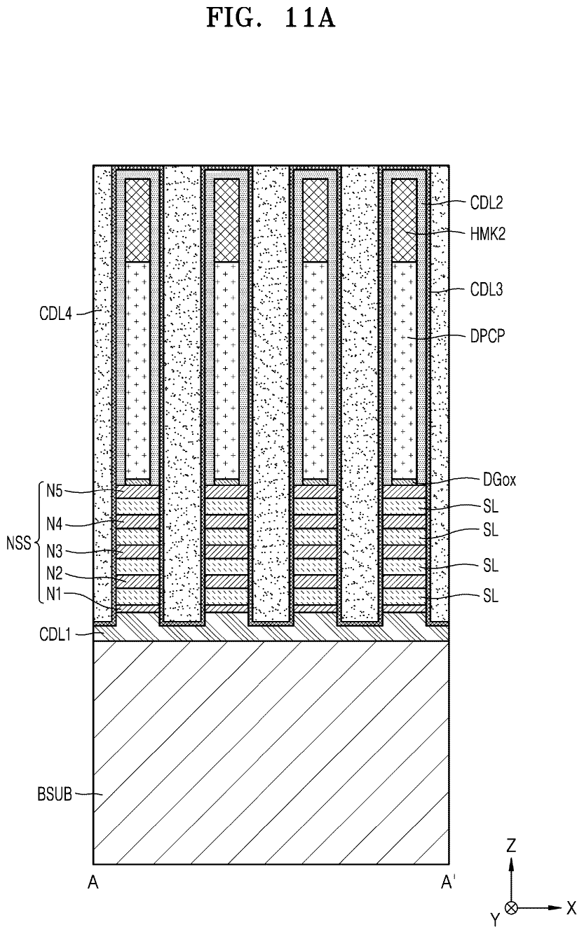

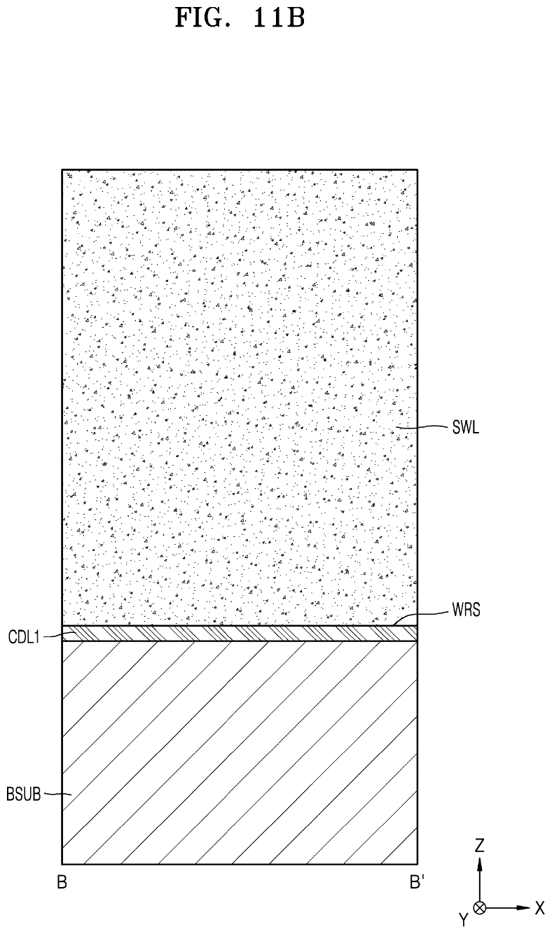

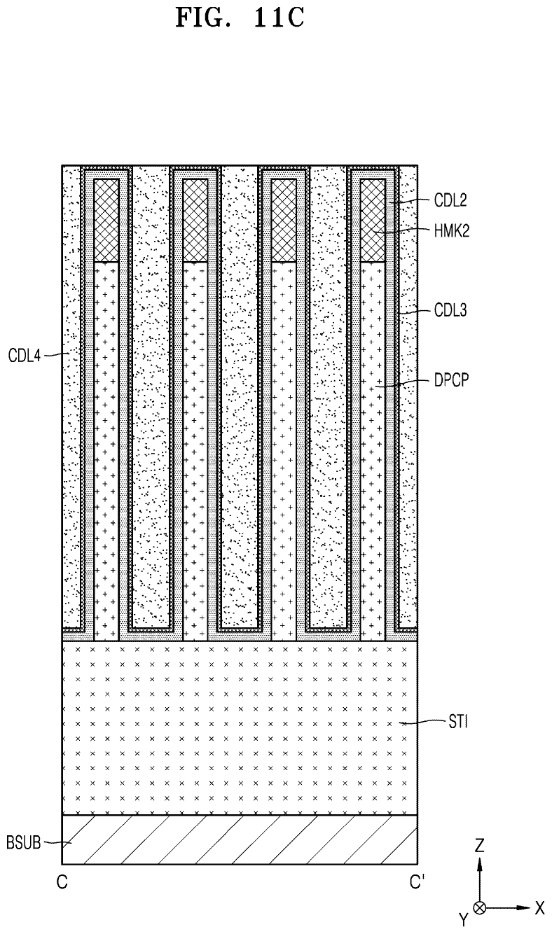

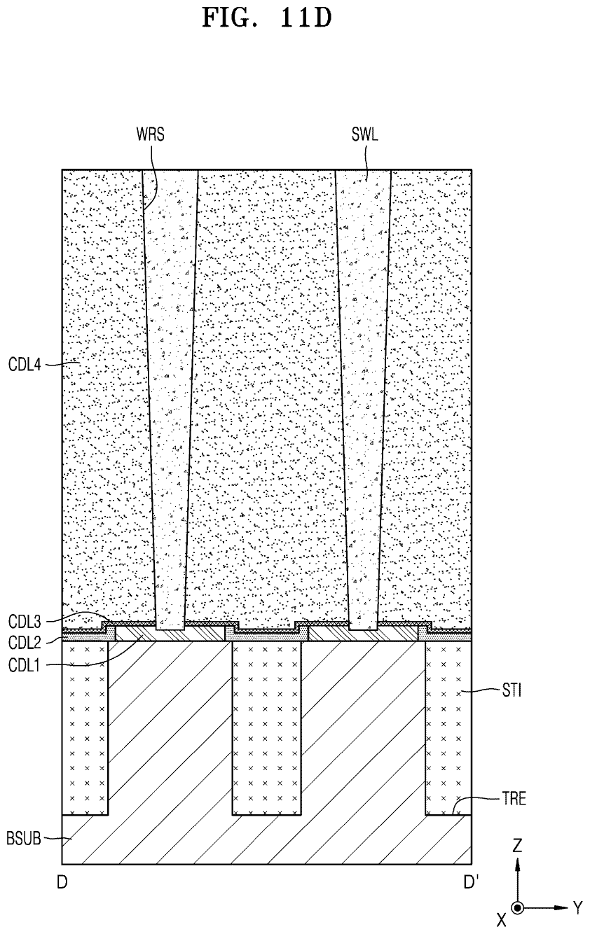

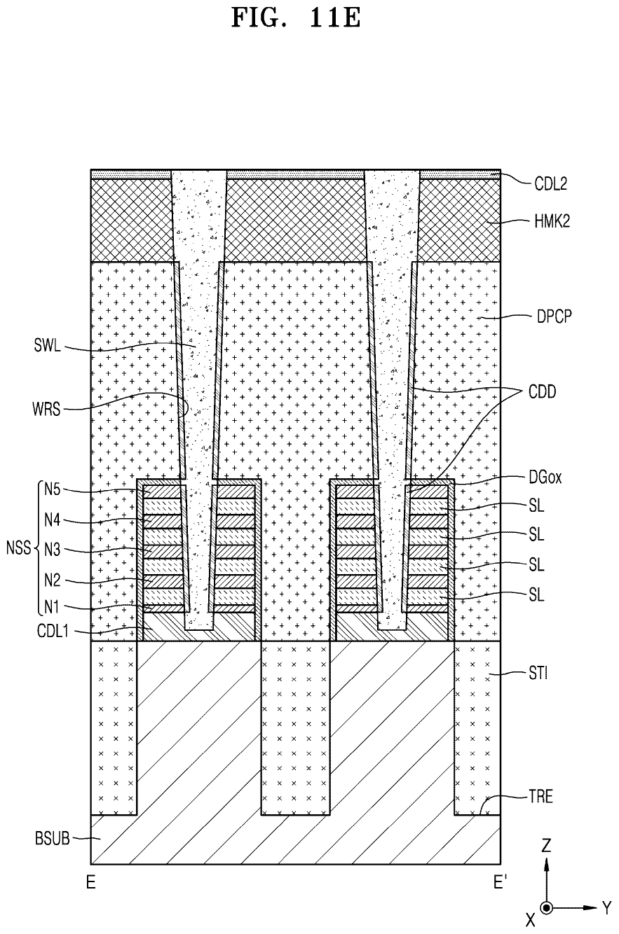

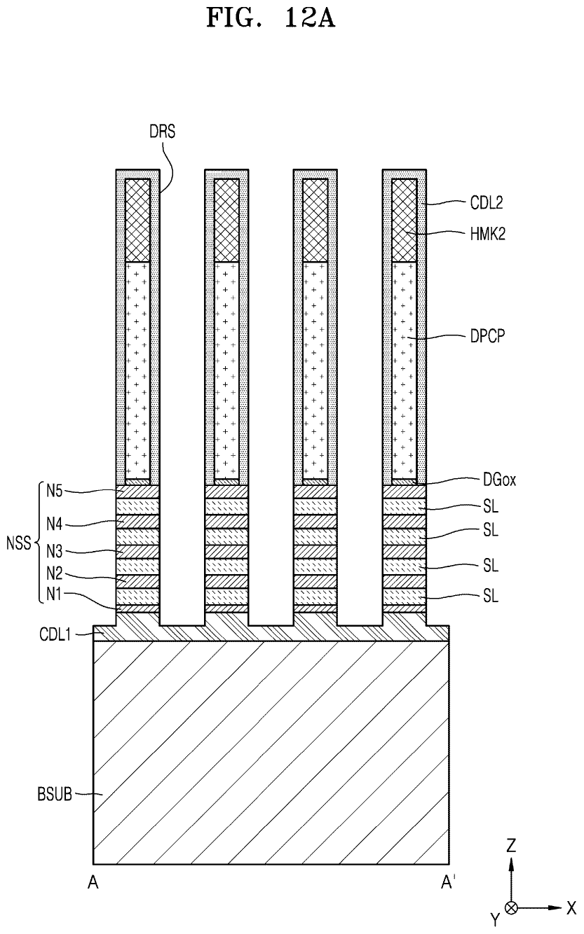

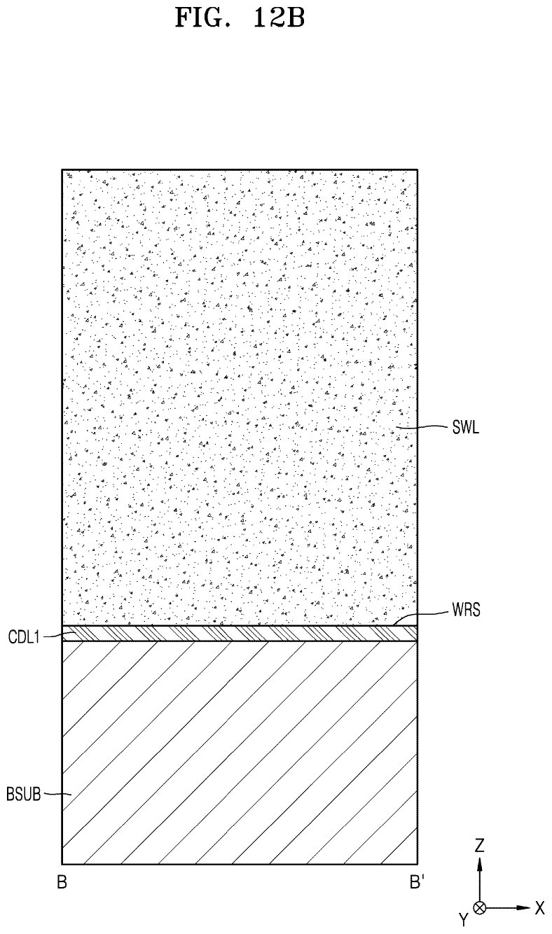

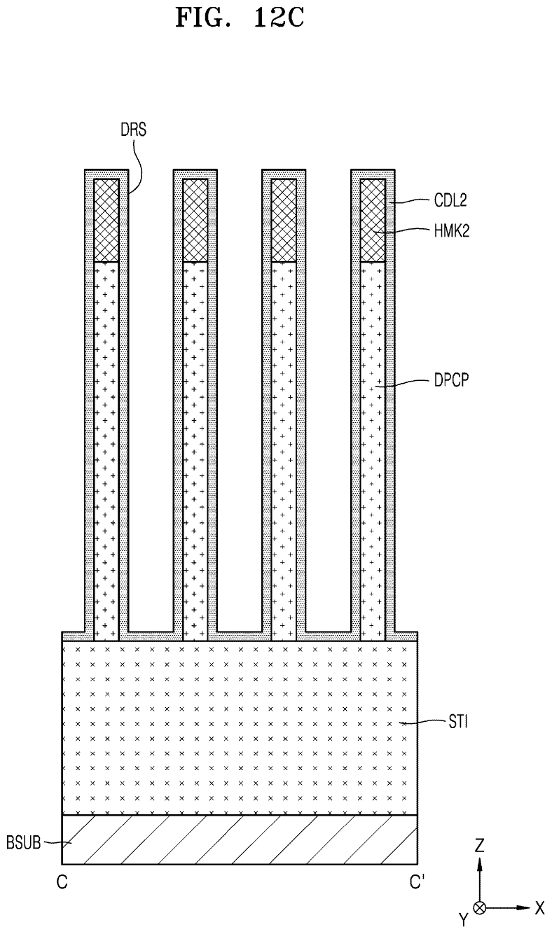

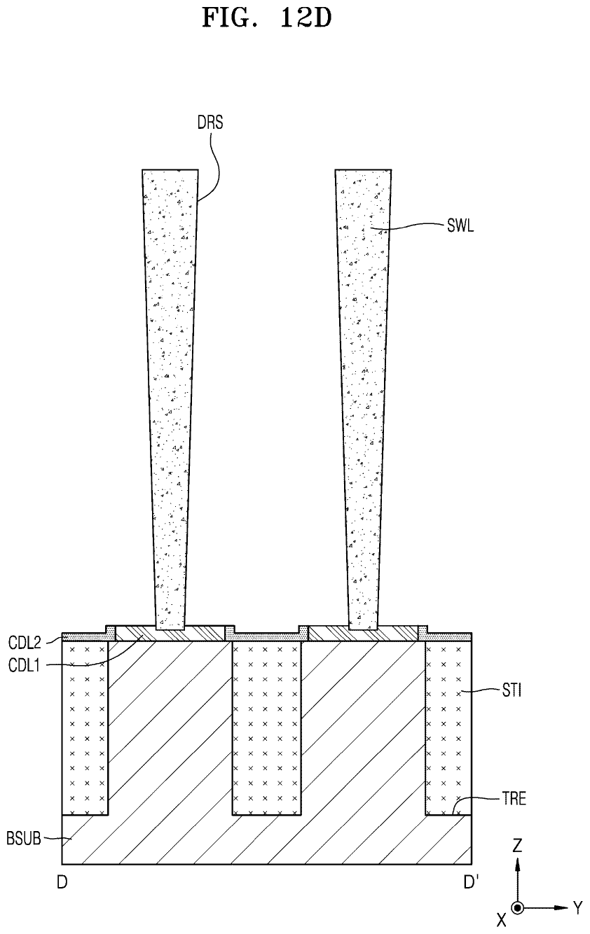

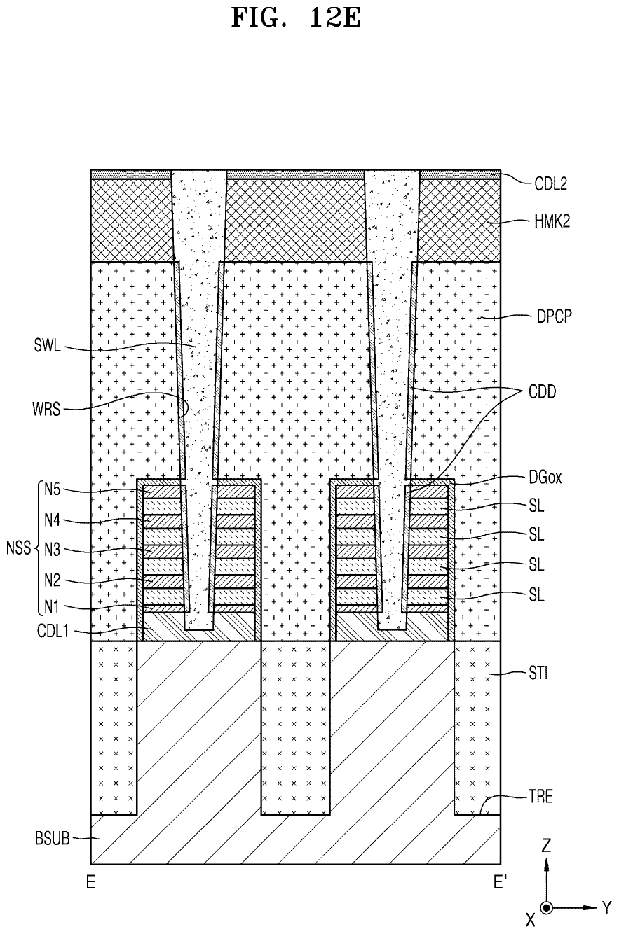

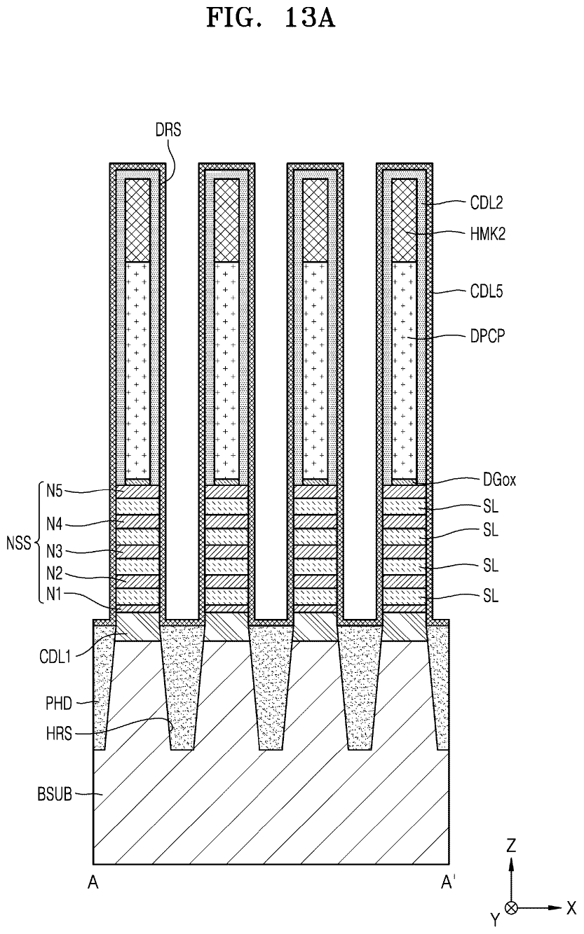

Referring to FIGS. 4A through 4C, after a device isolation layer STI filling the trench TRE is formed, a dummy gate insulating layer DGox and a dummy gate electrode DPCP may be formed on the plurality of nanosheet semiconductor layers NS and the plurality of sacrificial layers SL. Each of the dummy gate insulating layer DGox and the dummy gate electrode DPCP may be formed by using an atomic layer deposition (ALD) process, a chemical vapor deposition (CVD) process, a physical vapor deposition (PVD) process, a metal organic (MO) ALD (MOAVD) process, or an MO CVD (MOCVD) process.

In some example embodiments, the device isolation layer STI may be formed such that an upper surface of the device isolation layer STI is at a vertical level equal to or higher than the upper surface of the base substrate layer BSUB, but is at a vertical level lower than an upper surface of the base sacrificial layer MSL. After a preliminary device isolation layer filling the trench TRE is formed, the device isolation layer STI may be formed by performing a recess process for removing a certain thickness from an upper portion of the preliminary device isolation layer. For example, the device isolation layer STI may include silicon oxide, silicon nitride, silicon oxynitride, or a combination thereof. A portion of the base substrate layer BSUB limited by the device isolation layer STI may be referred to as a fin-type active region. For example, the device isolation layer STI may include a material including at least one of silicon oxide, silicon nitride, and silicon oxynitride. The device isolation layer STI may include a single layer including one type of an insulating layer, a double layer including two types of insulating layers, or a multiple layer including a combination of at least three types of insulating layers. For example, the device isolation layer STI may include two different types of insulating layers. For example, the device isolation layer STI may include a silicon oxide layer and a silicon nitride layer. For example, the device isolation layer STI may include a triple layer including a silicon oxide layer, a silicon nitride layer, and a silicon oxide layer.

In some example embodiments, the dummy gate insulating layer DGox may be selectively formed on a semiconductor material. For example, the dummy gate insulating layer DGox may be formed to conformally cover surfaces of the plurality of nanosheet semiconductor layers NS, the plurality of sacrificial layers SL, and the base sacrificial layer MSL, but may be formed not to cover the device isolation layer STI. The dummy gate insulating layer DGox may be formed by oxidizing surface portions of the plurality of nanosheet semiconductor layers NS, the plurality of sacrificial layers SL, and the base sacrificial layer MSL. In some example embodiments, the dummy gate insulating layer DGox may be formed to conformally cover surfaces of the plurality of nanosheet semiconductor layers NS, the plurality of sacrificial layers SL, the base sacrificial layer MSL, and the device isolation layer STI. The dummy gate electrode DPCP may be formed to fill all the spaces in a stacked structure of the base sacrificial layer MSL, the plurality of sacrificial layers SL, and the plurality of nanosheet semiconductor layers NS, and cover the upper surface of the dummy gate insulating layer DGox. For example, the dummy gate electrode DPCP may include polysilicon, but is not limited thereto.

Referring to FIGS. 5A through 5D together, after a plurality of second hard mask patterns HMK2 are formed on the dummy gate electrode DPCP, the dummy gate electrode DPCP and the dummy gate insulating layer DGox may be patterned by using the plurality of second hard mask patterns HMK2 as etching masks to be divided into a plurality. The plurality of second hard mask patterns HMK2 may extend in the second horizontal direction (Y direction), and may be formed apart from each other in the first horizontal direction (X direction). Each of the plurality of second hard mask patterns HMK2 may include nitride. For example, each of the plurality of second hard mask patterns HMK2 may include silicon nitride. Each of the plurality of dummy gate insulating layers DGox formed by patterning by using the plurality of second hard mask patterns HMK2, and each of the plurality of dummy gate electrodes DPCP may extend in the second horizontal direction (Y direction), and may be formed apart from each other in the first horizontal direction (X direction). On lower surfaces of spaces between stacked structures of the plurality of dummy gate insulating layers DGox and the plurality of dummy gate electrodes DPCP, the upper surface of the nanosheet semiconductor layer NS at the uppermost end among the plurality of nanosheet semiconductor layers NS and the upper surface of the device isolation layer STI may be exposed.

In some example embodiments, in the process of patterning the dummy gate insulating layer DGox, a portion of the dummy gate insulating layer DGox covering the upper surface of the base substrate layer BSUB may be removed, and thus, the device isolation layer STI and the base substrate layer BSUB may be exposed on the lower surfaces of spaces between stacked structures of the plurality of base sacrificial layers MSL, the plurality of sacrificial layers SL, and the plurality of nanosheet semiconductor layers NS.

Referring to FIGS. 5A through 5D and 6A through 6D, after the plurality of base sacrificial layers MSL are removed, a plurality of first insulating layers CDL1 filling a space, where the plurality of base sacrificial layers MSL are removed, may be formed. For example, the first insulating layer CDL1 may include silicon nitride (SiN), silicon oxynitride (SiON), silicon carbon nitride (SiCN), silicon oxycarbon nitride (SiOCN), or a combination thereof. After the plurality of first insulating layers CDL1 are formed, a second insulating layer CDL2, which covers side surfaces and the upper surface of stacked structures of the plurality of dummy gate insulating layers DGox, the plurality of dummy gate electrodes DPCP, and the plurality of second hard mask patterns HMK2, the side surfaces and the upper surface of the stacked structures of the plurality of first insulating layers CDL1, the plurality of sacrificial layers SL, and the plurality of nanosheet semiconductor layers NS, and the upper surface of the device isolation layer STI, may be formed. The second insulating layer CDL2 may be formed to conformally cover the side surfaces and the upper surface of the stacked structures of the plurality of dummy gate insulating layers DGox, the plurality of dummy gate electrodes DPCP, and the plurality of second hard mask patterns HMK2, the side surfaces and the upper surface of the stacked structures of the plurality of first insulating layers CDL1, the plurality of sacrificial layers SL, and the plurality of nanosheet semiconductor layers NS, and the upper surface of the device isolation layer STI. For example, the second insulating layer CDL2 may include SiN, SiON, SiCN, SiOCN, or a combination thereof. In some example embodiments, the first insulating layer CDL1 and the second insulating layer CDL2 may include materials having different etching selectivities from each other.

Referring to FIGS. 6A through 6D and 7A through 7D together, after the second insulating layer CDL2 is formed, by performing an anisotropic etching process, the plurality of sacrificial layers SL and the plurality of nanosheet semiconductor layers NS, which are under the spaces between the stacked structures of the plurality of dummy gate insulating layers DGox, the plurality of dummy gate electrodes DPCP, and the plurality of second hard mask patterns HMK2, may be removed to form the nanosheet stacked structure NSS including first through fifth nanosheets N1 through N5 may be formed. The nanosheet stacked structure NSS may include the first through fifth nanosheets NI through N5, which are sequentially ranged apart from each other from the lower side to the upper side, but example embodiments are illustrative, and not limited thereto. For example, the nanosheet stacked structure NSS may include three, four, or six or more nanosheets. In the inventive concepts, for convenience of descriptions, the first nanosheet N1 and the fifth nanosheet N5 are described as a lowermost end nanosheet and an uppermost end nanosheet among the first through fifth nanosheets N1 through N5 included in the nanosheet stacked structure NSS, respectively.

Portions of the plurality of sacrificial layers SL may be arranged between the first through fifth nanosheets N1 through N5 included in the nanosheet stacked structure NSS. The first insulating layer CDL1 may be exposed on the lower surfaces of spaces between the stacked structures of the plurality of dummy gate insulating layers DGox, the plurality of dummy gate electrodes DPCP, and the plurality of second hard mask patterns HMK2. It is illustrated in FIGS. 7A through 7D that the second insulating layer CDL2 covers the upper surface of the device isolation layer STI and the upper surface of the plurality of second hard mask patterns HMK2, but example embodiments are illustrative, and not limited thereto. For example, after the nanosheet stacked structure NSS including the first through fifth nanosheets N1 through N5 is formed, the second insulating layer CDL2 may cover the side surfaces of the stacked structures of the plurality of dummy gate insulating layers DGox, the plurality of dummy gate electrodes DPCP, and the plurality of second hard mask patterns HMK2, but may not cover at least a portion of the upper surface of the device isolation layer STI and the upper surface of the plurality of second hard mask patterns HMK2. Side surfaces of each of the first through fifth nanosheets N1 through N5 included in the nanosheet stacked structure NSS and outside surfaces of the second insulating layer CDL2 covering the side surfaces of the stacked structures of the plurality of dummy gate insulating layers DGox, the plurality of dummy gate electrodes DPCP, and the plurality of second hard mask patterns HMK2 may be aligned with each other in the vertical direction (Z direction).

Referring to FIGS. 8A through 8D together, a third insulating layer CDL3 covering the resultant product illustrated in FIGS. 7A through 7D and a fourth insulating layer CDL4 covering at least a portion of the third insulating layer CDL3 may be sequentially formed. For example, the third insulating layer CDL3 may be formed to conformally cover the first insulating layer CDL1 and the second insulating layer CDL2. For example, the fourth insulating layer CDL4 may cover the third insulating layer CDL3, and may be formed to fill spaces between the stacked structures of the plurality of dummy gate insulating layers DGox, the plurality of dummy gate electrodes DPCP, and the plurality of second hard mask patterns HMK2, and the second insulating layer CDL2 covering the side surfaces of the stacked structures. For example, the third insulating layer CDL3 may include SiN, SiON, SiCN, SiOCN, or a combination thereof. The fourth insulating layer CDL4 may include oxide. For example, the fourth insulating layer CDL4 may include boro-phospho-silicate glass (BPSG), phosphosilicate glass (PSG), borosilicate glass (BSG), undoped silicate glass (USG), tetraethyleortho silicate (TEOS), high density plasma (HDP), Tonen SilaZene (TOSZ), or a combination thereof.

Referring to FIGS. 9A through 9E together, by removing portions from the resultant products of FIGS. 8A through 8D, a plurality of first removed spaces WRS may be formed. The plurality of first removed spaces WRS may extend in the first horizontal direction (X direction), and may be formed apart from each other in the second horizontal direction (Y direction). The first insulating layer CDL1 may be exposed on the bottom surfaces of the plurality of first removed spaces WRS. For example, the plurality of first removed spaces WRS may be formed by removing a portion of a fourth insulating layer CD4, a portion of a third insulating layer CD3, and a portion of each of the stacked structures of the plurality of dummy gate insulating layers DGox, the plurality of dummy gate electrodes DPCP and the plurality of second hard mask patterns HMK2, and a portion of the second insulating layer CDL2 covering the side surfaces of the stacked structures.

Referring to FIGS. 10A through 10E together, a cladding layer CDD covering portions of inner sidewalls of the plurality of first removed spaces WRS. The cladding layer CDD may be selectively formed on a semiconductor material. For example, the cladding layer CDD may be formed to cover the surface of the dummy gate electrode DPCP exposed in the plurality of first removed spaces WRS, the surface of each of the first through fifth nanosheets N1 through N5 included in the nanosheet stacked structure NSS, and the surface of each of the plurality of sacrificial layers SL.

For example, the cladding layer CDD may not be formed on the surface of each of the first insulating layer CDL1, the fourth insulating layer CD4, the dummy gate insulating layer DGox, and the second hard mask pattern HMK2. Because the cladding layer CDD is not formed on the dummy gate insulating layer DGox arranged between the nanosheet stacked structure NSS and the dummy gate electrode DPCP, a portion of the cladding layer CDD covering the surface of the dummy gate electrode DPCP may be apart from portions of the cladding layer CDD covering the surfaces of the first through fifth nanosheets N1 through N5 included in the nanosheet stacked structure NSS and the plurality of sacrificial layers SL.

The cladding layer CDD may include a semiconductor material. In some example embodiments, the cladding layer CDD may include a semiconductor material that is different from those of the first through fifth nanosheets N1 through N5. For example, when each of the first through fifth nanosheets N1 through N5 includes Si, the cladding layer CDD may include SiGe.

Referring to FIGS. 11A through 11E together, the plurality of sheet separation walls SWL respectively filling the plurality of first removed spaces WRS may be formed. Each of the plurality of sheet separation walls SWL may include nitride. For example, each of the plurality of sheet separation walls SWL may include silicon nitride. The plurality of sheet separation walls SWL may extend in the first horizontal direction (X direction), and may be formed apart from each other in the second horizontal direction (Y direction).

The plurality of sheet separation walls SWL may be apart from the first through fifth nanosheets N1 through N5 included in the nanosheet stacked structure NSS. For example, the cladding layer CDD may be arranged between the plurality of sheet separation walls SWL and the first through fifth nanosheets N1 through N5 included in the nanosheet stacked structure NSS.

Referring to FIGS. 11A through 11E and 12A trough 12E together, by removing the fourth insulating layer CDL4 and the third insulating layer CDL3, a plurality of second removed spaces DRS may be formed. The plurality of second removed spaces DRSs may be limited between the stacked structures of the first through fifth nanosheets N1 through N5 included in the nanosheet stacked structure NSS and the plurality of sacrificial layers SL, between structures including the stacked structures of the plurality of dummy gate insulating layers DGox, the plurality of dummy gate electrodes DPCP, and the plurality of second hard mask patterns HMK2 and the second insulating layers CDL2 covering the stacked structures, and between the plurality of sheet separation walls SWL. Portions of the first insulating layer CDL1 and portions of the second insulating layer CDL2 may be exposed on the bottom surfaces of the plurality of second removed spaces DRS.

Referring to FIGS. 13A through 13E together, a plurality of second removed spaces HRS may be formed by removing portions of the first insulating layer CDL1 exposed on the lower surfaces of the plurality of second removed spaces DRS and portions of the base substrate layer BSUB under the first insulating layer CDL1. A plurality of place holder structures PHD filling the plurality of second removed spaces HRS may be formed. In some example embodiments, the place holder structure PHD may include a semiconductor material. For example, the plurality of place holder structures PHD may include a compound semiconductor such as SiGe.

After the plurality of place holder structures PHD are formed, a fifth insulation layer CDL5 may be formed. The fifth insulation layer CDL5 may be formed to conformally cover surfaces of a resultant product forming the plurality of place holder structures PHD. For example, the fifth insulation layer CDL5 may be formed to conformally cover the surface of each of the plurality of place holder structures PHD, the first insulating layer CDL1, the second insulating layer CDL2, the plurality of sheet separation walls SWL, the first through fifth nanosheets N1 through N5 included in the nanosheet stacked structure NSS, and the plurality of sacrificial layers SL. For example, the fifth insulating layer CDL5 may include SiN, SiON, SiCN, SiOCN, or a combination thereof.

Referring to FIGS. 14A through 14E together, after portions of the fifth insulation layer CDL5 are removed, a sixth insulation layer CDL6 and a seventh insulating layer CDL7 may be sequentially formed. For example, the remaining portions of the fifth insulation layer CDL5 except for portions of the fifth insulation layer CDL5 covering the plurality of place holder structures PHD and the first insulating layer CDL1, and portions adjacent to the portions, may be removed. All of the fifth insulation layer CDL5, the sixth insulation layer CDL6, and the seventh insulating layer CDL7, which remain, may be referred to as an insulating structure.

The uppermost end of the fifth insulation layer CDL5, which remains, may be at a vertical level equal to or higher than the upper surface of the first insulating layer CDL1. In some example embodiments, the uppermost end of the fifth insulation layer CDL5 may be higher than the upper surface of the first nanosheet N1 at the lowermost end among the first through fifth nanosheets N1 through N5 included in the nanosheet stacked structure NSS, but may be at a vertical level equal to or lower than the upper surface of the sacrificial layer SL at the lowermost end among the plurality of sacrificial layers SL. For example, the fifth insulation layer CDL5 may cover side surfaces of the first nanosheet N1. For example, the fifth insulation layer CDL5 may cover at least portions of side surfaces of the sacrificial layer SL at the lowermost end among the plurality of sacrificial layers SL and side surfaces of the first nanosheet N1. In some example embodiments, the fifth insulation layer CDL5 may cover the side surfaces of the first insulating layer CDL1, but may not cover the side surfaces of the first nanosheet N1. The fifth insulation layer CDL5 may be formed to have a U-shape on a flat surface (X-Z flat surface) that is formed by the first horizontal direction (X direction) and the vertical direction (Z direction).

The sixth insulation layer CDL6 may be formed on the fifth insulation layer CDL5. In some example embodiments, the sixth insulation layer CDL6 may be formed to fill at least portions of spaces limited by the fifth insulation layer CDL5 having a U-shape on the X-Z plane. For example, the sixth insulation layer CDL6 may include silicon oxide.

The seventh insulating layer CDL7 may be formed on the sixth insulation layer CDL6. In some example embodiments, the upper surface of the seventh insulating layer CDL7 may be at the same vertical level as the uppermost end of the fifth insulation layer CDL5. For example, the sixth insulation layer CDL6 may be formed to fill lower side portions of spaces limited by the fifth insulation layer CDL5 having a U-shape on the X-Z plane, and the seventh insulating layer CDL7 may be formed to fill the remaining portions, that is, upper side portions, of spaces limited by the fifth insulation layer CDL5. For example, the seventh insulating layer CDL7 may include SiN, SiON, SiCN, SiOCN, or a combination thereof.

After a first source/drain region SD1 and a second source/drain region SD2 are formed by using an epitaxial growth from the side surfaces of the first through fifth nanosheets N1 through N5 included in the nanosheet stacked structure NSS, which are not covered by the insulating structure including the remaining fifth insulation layer CDL5, the sixth insulation layer CDL6, and the seventh insulating layer CDL7, an eighth insulating layer CDL8 covering the surface of the resultant product, in which the first source/drain region SD1 and the second source/drain region SD2 are formed, may be formed. For example, each of the first source/drain region SD1 and the second source/drain region SD2 may include an embedded SiGe structure including a plurality of epitaxially grown SiGe layers, an epitaxially grown Si layer, or an epitaxially grown SiC layer. In some example embodiments, the eighth insulating layer CDL8 may include nitride. In some example embodiments, the first source/drain region SD1 and the second source/drain region SD2 may include impurities of different conductivity types. In some example embodiments, the first through fifth nanosheets N1 through N5 in contact with the first source/drain region SD1 and the first through fifth nanosheets N1 through N5 in contact with the second source/drain region SD2 may have impurities of different conductivity types. For example, an n-type metal-oxide-semiconductor (MOS) (NMOS) transistor may be formed in a portion, where the first source/drain region SD1 is formed, and a p-type MOS (PMOS) transistor may be formed in a portion where the second source/drain region SD2 is formed. For example, the first source/drain region SD1 may include n-type impurities, the second source/drain region SD2 may include p-type impurities, the first through fifth nanosheets N1 through N5 in contact with the first source/drain region SD1 may include p-type impurities, and the first through fifth nanosheets N1 through N5 in contact with the second source/drain region SD2 may include n-type impurities.

Referring to FIGS. 14A through 14E and 15A through 15E together, an interlayer insulating layer ILD covering the eighth insulating layer CDL8 may be formed. The interlayer insulating layer ILD may be formed to cover the eighth insulating layer CDL8, and fill spaces between the stacked structures of the plurality of dummy gate insulating layers DGox, the plurality of dummy gate electrodes DPCP, and the plurality of second hard mask patterns HMK2 and spaces between the plurality of sheet separation walls SWL. For example, the interlayer insulating layer ILD may include silicon oxide or an insulating material having a lower dielectric constant than silicon oxide. In some example embodiments, the interlayer insulating layer ILD may include a tetraethyl orthosilicate (TEOS) layer or an ultra low dielectric constant K (ULK) layer having an ULK of about or exactly 2.2 to about or exactly 2.4. The ULK layer may include a SiOC layer or a SiCOH layer.

After the interlayer insulating layer ILD is formed, after portions of upper sides of the interlayer insulating layer ILD, the eighth insulating layer CDL8, the sheet separation wall SWL, the second insulating layer CDL2, and the second hard mask pattern HMK2 are removed to expose the plurality of dummy gate electrodes DPCP, by removing the plurality of dummy gate electrodes DPCP and the plurality of dummy gate insulating layers DGox, a plurality of third removed spaces RSP may be formed. In some example embodiments, the plurality of dummy gate electrodes DPCP and the plurality of dummy gate insulating layers DGox may be removed by performing a wet etching process. An etchant, for example, HNO₃, diluted fluoric acid (DHF), NH₄OH, tetramethyl ammonium hydroxide (TMAH), potassium hydroxide (KOH), or a combination thereof may be used to perform the wet etching process.

Referring to FIGS. 15A through 15E and 16A through 16E together, by removing the plurality of sacrificial layers SL and portions of the cladding layer CDD, by using the plurality of third removed spaces RSP, a plurality of fourth removed spaces GSP may be formed. Among the plurality of fourth removed spaces GSP, portions except for spaces, from which portions of the cladding layer CDD and the plurality of sacrificial layers SL have been removed, may become the plurality of third removed spaces RSP. In other words, the plurality of third removed spaces RSP may expand to spaces, where portions of the plurality of sacrificial layers SL and the cladding layer CDD are removed, to become the plurality of fourth removed spaces GSP.

After the plurality of fourth removed spaces GSP are formed, portions, where the cladding layer CDD remains, may become a plurality of cladding patterns CDP. The plurality of cladding patterns CDP may be arranged between the plurality of sheet separation walls SWL and the first through fifth nanosheets N1 through N5 included in the plurality of nanosheet stacked structures NSS. Each of the first through fifth nanosheets N1 through N5 included in the plurality of nanosheet stacked structures NSS may include the cladding pattern CDP therebetween, and may be apart from the sheet separation wall SWL.

Referring to FIGS. 17A through 17E together, a plurality of gate insulating layers Gox covering surfaces exposed in the plurality of fourth removed spaces GSP may be formed. The plurality of gate insulating layers Gox may be formed to conformally cover the surfaces of the first through fifth nanosheets N1 through N5 included in the nanosheet stacked structure NSS. The gate insulating layer Gox may include a silicon oxide layer, a high dielectric layer, or a combination thereof. In some example embodiments, the gate insulating layer Gox may have a stacked structure including an interface layer and a high dielectric layer. The interface layer may include a low-k material having a dielectric constant of about or exactly 9 or less (for example, about or exactly 9 to about or exactly 0). For example, the interface layer may include oxide, nitride, or oxynitride. The high-k dielectric layer may include a metal oxide or a metal oxynitride. The high-k dielectric layer may include a material having a dielectric constant that is greater than that of the silicon oxide layer. For example, the high dielectric layer may have a dielectric constant of about or exactly 10 to about or exactly 25. The high dielectric layer may include hafnium oxide, hafnium oxynitride, hafnium silicon oxide, lanthanum oxide, lanthanum aluminum oxide, zirconium oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof, but the material constituting the high dielectric layer is not limited thereto. The high dielectric layer may be formed by performing an ALD process, a CVD process, or a PVD process. The high dielectric layer may have a thickness of about or exactly 10 Å to about or exactly 40 Å, but is not limited thereto. In some example embodiments, the interface layer may be omitted. For example, the gate insulating layer Gox may include HfO₂, Al₂O₃, HfAlO₃, Ta₂O₃, or TiO₂.

In some example embodiments, the gate insulating layer Gox may include a ferroelectric material layer having ferroelectric characteristics or a paraelectric material layer having paraelectric characteristics. For example, the gate insulating layer Gox may include one ferroelectric material layer. For example, the gate insulating layer Gox may include a plurality of ferroelectric material layers apart from each other. For example, the gate insulating layer Gox may have a stacked layer structure in which a plurality of ferroelectric material layers and a plurality of paraelectric material layers are alternately stacked.

The ferroelectric material layer may have a negative capacitance, and the paraelectric material layer may have a positive capacitance. For example, when two or more capacitors are connected in series, and each of capacitances of the capacitors have a positive value, the total capacitance may be decreased from each of capacitances of individual capacitors. However, when the capacitance of at least one of the two or more capacitors connected to each other in series has a negative value, the total capacitance may be positive and greater than an absolute value of each of individual capacitances.

When the ferroelectric material layer having a negative capacitance, and a paraelectric material layer having a positive capacitance are connected to each other in series, the total capacitance value of the ferroelectric material layer and the paraelectric material layer connected to each other in series may be increased. By using the fact that the total capacitance value is increased, a transistor including the ferroelectric material layer may have a subthreshold swing (SS) that is less than about or exactly 60 mV/decade at room temperature.

The ferroelectric material layer may have a ferroelectric characteristic. The ferroelectric material layer may include at least one of hafnium oxide, hafnium zirconium oxide, barium strontium titanium oxide, barium titanium oxide, and lead zirconium titanium oxide. In this case, for example, the hafnium zirconium oxide may include hafnium oxide with zirconium (Zr) doped thereon. As another example, the hafnium zirconium oxide may be a compound of hafnium (Hf), zirconium (Zr), and oxygen (O).

The ferroelectric material layer may further include doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material is included in the ferroelectric material layer, the type of dopant included in the ferroelectric material layer may vary. When the ferroelectric material layer includes a hafnium oxide, the dopant included in the ferroelectric material layer may include at least one of, for example, gadolinium (Gd), silicon (Si), zirconium (Zr), aluminum (Al), and yttrium (Y). When the dopant is Al, the ferroelectric material layer may include aluminum of about or exactly 3 at % to about or exactly 8 at %. In this case, a ratio of the dopant may be a ratio of aluminum over the sum of hafnium and aluminum. When the dopant is Si, the ferroelectric material layer may include silicon of about or exactly 2 at % to about or exactly 10 at %. When the dopant is Y, the ferroelectric material layer may include yttrium of about or exactly 2 at % to about or exactly 10 at %. When the dopant is Gd, the ferroelectric material layer may include gadolinium of about or exactly 1 at % to about or exactly 7 at %. When the dopant is Zr, the ferroelectric material layer may include zirconium of about or exactly 50 at % to about or exactly 80 at %.

The paraelectric material layer may have a paraelectric characteristic. The paraelectric material layer may include at least one of silicon oxide and a metal oxide of a high-k. The metal oxide included in the paraelectric material layer may include at least one of hafnium oxide, zirconium oxide, and aluminum oxide, but is not limited thereto.

The ferroelectric material layer and the paraelectric material layer may include the same material. The ferroelectric material layer may not have a ferroelectric characteristic, but the paraelectric material layer may not have the ferroelectric characteristic. For example, when the ferroelectric material layer and the paraelectric material layer include hafnium oxide, a crystal structure of the hafnium oxide included in the ferroelectric material layer may be different from that of the hafnium oxide included in the paraelectric material layer.

The ferroelectric material layer may have a thickness having a ferroelectric characteristic. The thickness of the ferroelectric material layer may be, for example, about or exactly 0.5 nm to about or exactly 10 nm, but is not limited thereto. Because a critical thickness of each ferroelectric material showing a ferroelectric characteristic varies, the thickness of the ferroelectric material layer may vary depending on a ferroelectric material.

Referring to FIGS. 18A through 18E together, the plurality of gate electrodes GL covering the plurality of gate insulating layers Gox and filling the plurality of fourth removed spaces GSP may be formed. The gate electrode GL may include a work function control metal-included layer and a gap-fill metal-included layer filling an upper space of the working function control metal-included layer. The work-function metal-containing layer may include at least one metal of Ti, W, Ru, Nb, Mo, Hf, Ni, Co, Pt, Yb, Tb, Dy, Er, and Pd. In some example embodiments, the gate electrode GL may have a structure in which a metal nitride layer, a metal layer, a conductive capping layer, and a gap-fill metal layer are sequentially stacked. The metal nitride layer and the metal layer may include at least one metal of Ti, Ta, W, Ru, Nb, Mo, and Hf. The gap-fill metal layer may include a W layer and/or an Al layer. In some example embodiments, the gate electrode layer GL may have a stacked structure of TiAlC/TiN/W, a stacked structure of TiN/TaN/TiAlC/TiN/W, or a stacked structure of TiN/TaN/TiN/TiAlC/TiN/W, but is not limited thereto.

In some example embodiments, among the plurality of gate electrodes GL, at least a portion of the work function metal-containing layer included in the gate electrode GL, which is formed on the nanosheet stacked structure NSS including the first through fifth nanosheets N1 through N5 in contact with the first source/drain region SD1, and at least a portion of the work function metal-containing layer included in the gate electrode GL, which is formed on the nanosheet stacked structure NSS including the first through fifth nanosheets N1 through N5 in contact with the second source/drain region SD2, may include different materials from each other.

After the plurality of gate electrodes GL are formed, and portions of the upper sides of the plurality of gate electrodes GL and portions of the upper sides of the plurality of gate insulating layers Gox are removed, a plurality of gate capping layers GC filling portions of the upper sides of the plurality of gate electrodes GL and spaces, where portions of the upper sides of the plurality of gate insulating layers Gox have been removed, may be formed. For example, the gate capping layer GC may include silicon nitride. In some example embodiments, in a process of removing portions of the upper sides of the plurality of gate electrodes GL and portions of the upper sides of the plurality of gate insulating layers Gox, a portion of the upper side of the second insulating layer CDL2 may be removed together, and the plurality of gate capping layers GC may be formed to fill spaces, where portions of the upper sides of the plurality of gate electrodes GL, portions of the upper sides of the plurality of gate insulating layers Gox, and a portion of the upper side of the second insulating layer CDL2 have been removed.

Referring to FIGS. 19A through 19F together, by cutting at least some of a plurality of gate structures including the plurality of gate insulating layers Gox, the plurality of gate electrodes GL, and the plurality of gate capping layers GC, at least one gate cut structure PCT may be formed. For example, the gate cut structure PCT may include silicon nitride. The gate cut structure PCT may penetrate the gate capping layer GC, the gate electrode GL, and the gate insulating layer Gox, and extend to the device isolation layer STI. In some example embodiments, the gate cut structure PCT may penetrate the gate capping layer GC, the gate electrode GL, and the gate insulating layer Gox, and extend into the device isolation layer STI. The gate cut structure PCT may extend in the first horizontal direction (X direction), and by cutting across at least some of the plurality of gate electrodes GL illustrated in FIGS. 18A through 18E, two separate gate electrodes GL including the gate cut structure PCT therebetween and apart from each other in the second horizontal direction (Y direction) may be formed.

Referring to FIGS. 20A through 20F together, a plurality of first contacts GCT penetrating the gate capping layer GC and connected to the plurality of gate electrodes GL, and a plurality of second contacts SCT penetrating the gate capping layer GC and the interlayer insulating layer ILD and connected to the first source/drain region SD1 and the second source/drain region SD2 may be formed. Each of the plurality of first contacts GCT and the plurality of second contacts SCT may include a metal, conductive metal nitride, or a combination thereof. For example, each of the plurality of first contacts GCT and the plurality of second contacts SCT may include a metal material, such as W, Al, Cu, Ti, Ta, Ru, Mn, and Co, a metal nitride, such as TiN, TaN, CoN, and WN, or an alloy, such as cobalt tungsten phosphide (CoWP), cobalt tungsten boron (CoWB), and cobalt tungsten boron phosphide (CoWBP). In some example embodiments, the first contact GCT may have a line shape or a bar shape in a plan view, and may have a vertical pillar shape extending in the vertical direction (Z direction). In some example embodiments, the second contact SCT may have a circular shape, an elliptical shape, or a polygonal shape in a plan view, and may have a vertical pillar shape extending in the vertical direction (Z direction).

In some example embodiments, a metal silicide layer may be arranged between the first source/drain region SD1 and the second source/drain region SD2, and between each of the plurality of second contacts SCT. For example, the metal silicide layer may include tungsten silicide (WSi), titanium silicide (TiSi), cobalt silicide (CoSi), or nickel silicide (NiSi).

A separation insulating layer SPI may be arranged between each of the plurality of first contacts GCT and the plurality of second contacts SCT. The separation insulating layer SPI may cover the gate capping layer GC, and may separate each of the plurality of first contacts GCT from each of the plurality of second contacts SCT. For example, the separation insulating layer SPI may include silicon nitride.

FIGS. 21A through 21F are vertical cross-sectional views of the integrated circuit device 1 according to some example embodiments, FIG. 22 is an enlarged cross-sectional view thereof, and FIGS. 23A and 23B are horizontal cross-sectional views thereof. FIG. 21A is a vertical cross-sectional view taken along line A-A′ in FIG. 1, FIG. 21B is a vertical cross-sectional view taken along line B-B′in FIG. 1, FIG. 21C is a vertical cross-sectional view taken along line C-C′ in FIG. 1, FIG. 21D is a vertical cross-sectional view taken along line D-D′in FIG. 1, FIG. 21E is a vertical cross-sectional view taken along line E-E′ in FIG. 1, FIG. 21F is a vertical cross-section view taken along line F-F′ in FIG. 1, FIG. 22 is an enlarged cross-sectional view of region XXII in FIG. 21E, and FIGS. 23A and 23B are horizontal cross-sectional views taken along lines Z1 and Z2 in FIG. 21E, respectively.

Referring to FIGS. 20A through 20F and 21A through 21F together, by removing a portion of the lower side of the base substrate layer BSUB and a portion of the lower side of the device isolation layer STI, the plurality of place holder structures PHD may be exposed. A portion of the lower side of the base substrate layer BSUB and a portion of the lower side of the device isolation layer STI may be removed by using a back grinding process or a back lapping process. For example, to expose the plurality of place holder structures PHD, by using a chemical mechanical polishing (CMP) process, an etch back process, or a combination thereof, a portion of the lower side of the base substrate layer BSUB and a portion of the lower side of the device isolation layer STI may be removed.

Next, the plurality of place holder structures PHD filling the plurality of second removed spaces HRS may be removed, a portion of the fifth insulation layer CDL5 exposed via the plurality of second removed spaces HRS, a portion of the sixth insulation layer CDL6, and a portion of the seventh insulating layer CDL7 may be removed, to expose the first source/drain region SD1 and the second source/drain region SD2. The plurality of second removed spaces HRS may extend from spaces, where the plurality of place holder structures PHD have been removed, into portions, where a portion of the fifth insulation layer CDL5, a portion of the sixth insulation layer CDL6, and a portion of the seventh insulating layer CDL7 have been removed, and into the first source/drain region SD1 and the second source/drain region SD2.

Thereafter, a plurality of third contacts SDCT filling the plurality of second removed spaces HRS and connected to the first source/drain region SD1 and the second source/drain region SD2 may be formed. Each of the plurality of third contacts SDCT may include a metal, conductive metal nitride, or a combination thereof. For example, each of the plurality of third contacts SDCT may include a metal material, such as W, Al, Cu, Ti, Ta, Ru, Mn, and Co, a metal nitride, such as TiN, TaN, CoN, and WN, or an alloy, such as CoWP, CoWB, and CoWBP. In some example embodiments, a metal silicide layer may be arranged between the first source/drain region SD1 and the second source/drain region SD2, and between each of the plurality of third contacts SDCT. For example, the metal silicide layer may include WSi, TiSi, CoSi, or NiSi. In some example embodiments, at least a portion of the third contact SDCT may have a circular shape, an elliptical shape, or a polygonal shape in a plan view, and may have a vertical pillar shape extending in the vertical direction (Z direction). In some other embodiment, portions of the third contact SDCT adjacent to each of the first source/drain region SD1 and the second source/drain region SD2 may have a circular shape, an elliptical shape, or a polygonal shape in a plan view, and have a vertical pillar shape extending in the vertical direction (Z direction), and a portion of the third contact SDCT adjacent to the lower surface of the base substrate layer BSUB may have a line shape or a bar shape in a plan view.

In some example embodiments, a plurality of ninth insulating layers CDL9 arranged between the plurality of third contacts SDCT and an insulating material adjacent to the plurality of third contacts SDCT may be formed. The ninth insulating layer CDL9 may be formed to cover the first insulating layer CDL1, the fifth insulation layer CDL5, the sixth insulation layer CDL6, and the seventh insulating layer CDL7, which are exposed in the second removed space HRS. For example, the ninth insulating layer CDL9 may include silicon nitride.

Referring to FIGS. 1, 21A through 21F, 22, and 23A and 23B together, the integrated circuit device 1 may include the plurality of nanosheet stacked structures NSS each including the first through fifth nanosheets N1 through N5 on the base substrate layer BSUB, the plurality of sheet separation walls SWL extending in the first horizontal direction (X direction) on the base substrate layer BSUB, the plurality of gate electrodes GL extending in the second horizontal direction (Y direction) on the plurality of nanosheet stacked structures NSS, and at least one gate cut structure PCT extending in the first horizontal direction (X direction) and cutting across at least some of the plurality of gate electrodes GL.

The plurality of nanosheet stacked structures NSS may be arranged in rows and columns in the first horizontal direction (X direction) and the second horizontal direction (Y direction), respectively. The plurality of nanosheet stacked structures NSS may be adjacent to the plurality of sheet separation walls SWL, and may be arranged in rows in the first horizontal direction (X direction). A corresponding pair of nanosheet stacked structures NSS among the plurality of nanosheet stacked structures NSS may include the sheet separation wall SWL therebetween, and may be arranged apart from each other in the second horizontal direction (Y direction).

Each of the first through fifth nanosheets N1 through N5 included in the plurality of nanosheet stacked structures NSS may extend in parallel with the upper surface of the base substrate layer BSUB. The first through fifth nanosheets N1 through N5 may be apart from each other and stacked in the vertical direction (Z direction) on the base substrate layer BSUB. One end of the first through fifth nanosheets N1 through N5 included in the plurality of nanosheet stacked structures NSS may face the plurality of sheet separation walls SWL.

The gate electrodes GL separated into two by the gate cut structure PCT may include the gate cut structure PCT therebetween, and may be apart from each other in the second horizontal direction (Y direction).

The plurality of gate electrodes GL may be arranged between the fifth nanosheet N5 at the uppermost end of the first through fifth nanosheets N1 through N5 and each of the first through fifth nanosheets N1 through N5. Portions of the plurality of gate electrodes GL arranged on the fifth nanosheet N5 at the uppermost end of the first through fifth nanosheets N1 through N5 and portions of the plurality of gate electrodes GL arranged between each of the first through fifth nanosheets N1 through N5 may be connected to each other.

The plurality of gate insulating layers Gox may be arranged between the plurality of gate electrodes GL and the plurality of nanosheet stacked structures NSS including the first through fifth nanosheets N1 through N5. Each of the plurality of first source/drain regions SD1 and the plurality of second source/drain regions SD2 may be connected to the first through fifth nanosheets N1 through N5 included in each of the plurality of nanosheet stacked structures NSS. Each of the plurality of first source/drain regions SD1 and the plurality of second source/drain regions SD2 may be connected to the other end of the first through fifth nanosheets N1 through N5 included in each of the plurality of nanosheet stacked structures NSS.

In some example embodiments, the first source/drain region SD1 and the second source/drain region SD2 may not be connected to the first nanosheet N1 at the lowermost end of the first through fifth nanosheets N1 through N5 included in the plurality of nanosheet stacked structures NSS.

The plurality of nanosheet stacked structures NSS including the first through fifth nanosheets N1 through N5, the plurality of gate electrodes GL, the plurality of first source/drain regions SD1, and the plurality of second source/drain regions SD2 may constitute a plurality of multi-gate MOSFETs.

The first insulating layer CDL1 may be arranged between the base substrate layer BSUB and the plurality of nanosheet stacked structures NSS including the first through fifth nanosheets N1 through N5. The first insulating layer CDL1 may be referred to as a base insulating layer. The device isolation layer STI may be arranged in portions of the base substrate layer BSUB, where the plurality of nanosheet stacked structures NSS including the first through fifth nanosheets N1 through N5 do not overlap the base substrate layer BSUB in the vertical direction (Z direction).

The plurality of first contacts GCT may penetrate the gate capping layer GC and be connected to an upper side portion of the plurality of gate electrodes GL. The plurality of second contacts SCT may penetrate the gate capping layer GC and the interlayer insulating layer ILD, and be connected to the upper side portions of the first source/drain region SD1 and the second source/drain region SD2. The plurality of third contacts SDCT may penetrate the base substrate layer BSUB, and be connected to the lower side portions of the first source/drain region SD1 and the second source/drain region SD2. In some example embodiments, either the plurality of second contacts SCT or the plurality of third contacts SDCT may be omitted. When either the plurality of second contacts SCT or the plurality of third contacts SDCT are omitted, the plurality of first contacts GCT may be referred to as a plurality of gate contacts, and contacts among the plurality of second contacts SCT and the plurality of third contacts SDCT, which have not been omitted, may be referred to as a plurality of source/drain contacts.

The plurality of cladding patterns CDP may be arranged between the plurality of sheet separation walls SWL and the first through fifth nanosheets N1 through N5 included in the plurality of nanosheet stacked structures NSS. Each of the plurality of cladding patterns CDP may include a different semiconductor material from those of the first through fifth nanosheets N1 through N5. For example, when each of the first through fifth nanosheets N1 through N5 includes Si, the cladding pattern CDP may include SiGe.

Each of the first through fifth nanosheets N1 through N5 included in the plurality of nanosheet stacked structures NSS may include the cladding pattern CDP therebetween, and may be apart from the sheet separation wall SWL. The sheet separation wall SWL or each of the plurality of cladding patterns CDP covering the side surfaces of the first through fifth nanosheets N1 through N5 may have a thickness of about or exactly 2 nm to about or exactly 3 nm. A thickness of each of the plurality of gate insulating layers Gox may be less than a thickness of each of the plurality of cladding patterns CDP. One end of the gate electrode GL facing the sheet separation wall SWL in the second horizontal direction (Y direction) may be closer to the sheet separation wall SWL than one end of the first through fifth nanosheets N1 through N5. The plurality of cladding patterns CDP may not be arranged between portions of the gate insulating layer Gox covering portions of the gate electrode GL filling spaces between the first through fifth nanosheets N1 through N5 included in the plurality of nanosheet stacked structures NSS and the sheet separation wall SWL. For example, the cladding patterns CDP in contact with each of both sidewalls of the sheet separation wall SWL at the both sidewalls of the sheet separation wall SWL may be arranged apart from each other in the vertical direction (Z direction). A portion of the gate electrode GL and a portion of the gate insulating layer Gox may be arranged between the cladding patterns CDP apart from each other in the vertical direction (Z direction).

With respect to the sheet separation wall SWL as a reference, each of the first through fifth nanosheets N1 through N5 included in the plurality of nanosheet stacked structures NSS arranged on one side in the second horizontal direction (Y direction) may have a first horizontal width W1, and each of the first through fifth nanosheets N1 through N5 included in the plurality of nanosheet stacked structures NSS arranged on the other side in the second horizontal direction (Y direction) may have a second horizontal width W2. For example, each of the first horizontal width W1 and the second horizontal width W2 may be about or exactly 10 nm to about or exactly 20 nm. In some example embodiments, the first horizontal width W1 and the second horizontal width W2 may have the same value. For example, among the plurality of nanosheet stacked structures NSS, horizontal widths of a corresponding pair of nanosheet stacked structures NSS including the sheet separation wall SWL therebetween and apart from each other in the second horizontal direction (Y direction) may be the same.

The sheet separation wall SWL may include a base wall portion SWB, a vertical wall portion SWV, a protrusion wall portion SWP, and a cover wall portion SWC. The base wall portion SWB, the vertical wall portion SWV, the protrusion wall portion SWP, and the cover wall portion SWC may be sequentially arranged from the lower side to the upper side in the vertical direction (Z direction). The base wall portion SWB, the vertical wall portion SWV, the protrusion wall portion SWP, and the cover wall portion SWC may be formed in one body. The base wall portion SWB may correspond to a portion at a lower vertical level than a vertical level lower than the plurality of nanosheet stacked structures NSS including the first through fifth nanosheets N1 through N5 among the sheet separation wall SWL, that is, the lower surface of the first nanosheet N1 at the lowermost end. In some example embodiments, the base wall portion SWB may include a portion of the first insulating layer CDL1, that is, the sheet separation wall SWL extending into the base insulating layer and buried therein. In other words, the base wall portion SWB may extend into the first insulating layer CDL1, that is, the base insulating layer. The vertical wall portion SWV May, among the sheet separation wall SWL, correspond to a portion extending in the vertical direction (Z direction) from the same level as the plurality of nanosheet stacked structures NSS including the first through fifth nanosheets N1 through N5, that is, a vertical level, at which the lower surface of the first nanosheet N1 at the lowermost end is arranged, to a vertical level at which the upper surface of the fifth nanosheet N5 at the uppermost end. The protrusion wall portion SWP may be arranged between the vertical wall portion SWV and the cover wall portion SWC, and may include a portion having a greater horizontal width than a horizontal width of the upper end of the vertical wall portion SWV and a horizontal width of the lower end of the cover wall portion SWC. The protrusion wall portion SWP may extend upwardly from a vertical level, at which the upper surface of the fifth nanosheet N5 at the uppermost end is arranged. The cover wall portion SWC may include an uppermost side portion of the sheet separation wall SWL on the protrusion wall portion SWP. The upper end of the cover wall portion SWC and the uppermost end of the gate electrode GL may be on the same vertical level.

In the second horizontal direction (Y direction), the protrusion wall portion SWP may have a third horizontal width W3, the upper side portion of the vertical wall portion SWV may have a fourth horizontal width W4, the lower side portion of the vertical wall portion SWV may have a fifth horizontal width W5, and the base wall portion SWB may have a sixth horizontal width W6. In some example embodiments, the third horizontal width W3 may be greater than the fourth horizontal width W4 and the fifth horizontal width W5. The fourth horizontal width W4 may be equal to or greater than the fifth horizontal width W5. The sixth horizontal width W6 may be greater than the fifth horizontal width W5. In some example embodiments, the vertical wall portion SWV may extend from the lower side to the upper side thereof in the vertical direction (Z direction), and may have a tapered shape, in which a horizontal width thereof increases in the second horizontal direction (Y direction). For example, the fourth horizontal width W4 may be greater than the fifth horizontal width W5. In some example embodiments, each of the base wall portion SWB, the protrusion wall portion SWP, and the cover wall portion SWC may extend from the lower side to the upper side in the vertical direction (Z direction), and may have a tapered shape, in which a horizontal width thereof increases in the second horizontal direction (Y direction).

Each of the plurality of sheet separation walls SWL may extend in the first horizontal direction (X direction), and a horizontal width thereof may change in the second horizontal direction (Y direction). For example, the sheet separation wall SWL may have a seventh horizontal width W7 between a pair of the first source/drain regions SD1 or a pair of the second source/drain regions SD2 in the second horizontal direction (Y direction), and may have an eighth horizontal width W8 between a pair of gate insulating layers Gox covering a pair of gate electrodes GL, or a pair of cladding patterns CDP in the second horizontal direction (Y direction). The eighth horizontal width W8 may be less than the seventh horizontal width W7. Compared to a portion between a pair of first source/drain regions SD1 or between a pair of second source/drain regions SD2, the sheet separation wall SWL may have a horizontal cross-section, in which the remaining portion, that is, a portion between a pair of gate insulating layers Gox covering a pair of gate electrodes GL, or a portion between a pair of cladding patterns CDP, is concave. For example, the sheet separation wall SWL may include a pair of concave portions SWR recessed inwardly at portions adjacent to a pair of gate insulating layers Gox covering a pair of gate electrodes GL or a pair of cladding patterns CDP.

The cladding patterns CDP arranged between the first through fifth nanosheets N1 through N5 included in a pair of nanosheet stacked structures NSS corresponding to each other among the plurality of nanosheet stacked structures NSS and the sheet separation wall SWL may be arranged in a pair of concave portions SWR. All of a plurality of concave portions SWR of the sheet separation wall SWL may be filled by the cladding pattern CDP in the second horizontal direction (Y direction), between the first through fifth nanosheets N1 through N5 included in the plurality of nanosheet stacked structures NSS.

The plurality of concave portions SWR of the sheet separation wall SWL may be filled by a portion of a pair of gate electrodes GL and portions of a pair of gate insulating layers Gox covering a pair of gate electrodes GL, in spaces between the first through fifth nanosheets N1 through N5 included in the plurality of nanosheet stacked structures NSS in the vertical direction (Z direction). In other words, the gate electrode GL may extend into a portion of each of the plurality of concave portions SWR.

In the integrated circuit device 1 according to the inventive concepts, because the cladding pattern CDP is arranged between the first through fifth nanosheets N1 through N5 included in the plurality of nanosheet stacked structures NSS and the sheet separation wall SWL, an occurrence of charge trap in the sheet separation wall SWL may be prevented or reduced, a channel leakage current (Isoff) may be improved, and operation characteristics may be improved. In addition, in the integrated circuit device 1 according to the inventive concepts, because the gate electrode GL extends into a concave portion of the sheet separation wall SWL, an effective channel length (Weff) of the multi-gate MOSFET may be secured, and thus, operation characteristics may be improved.

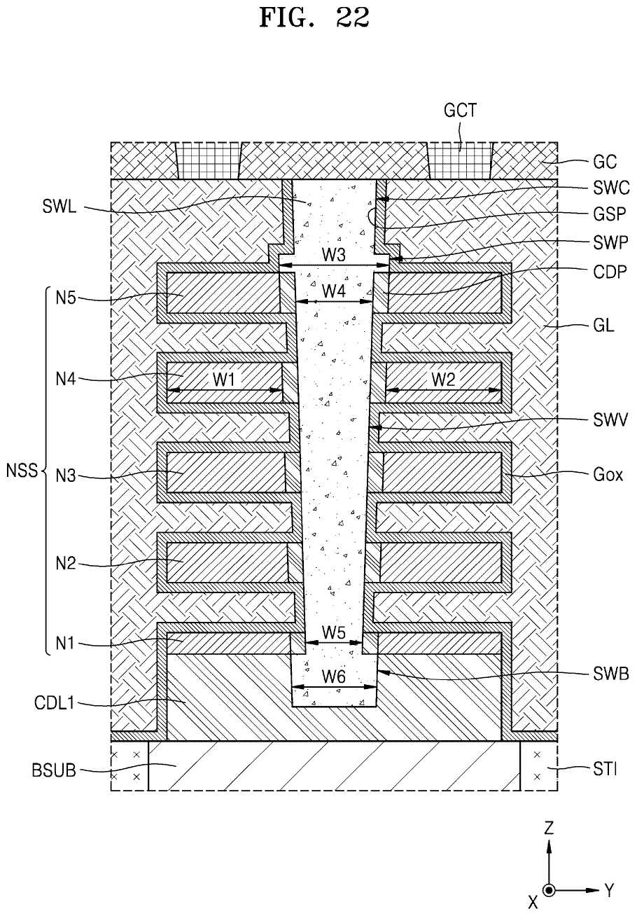

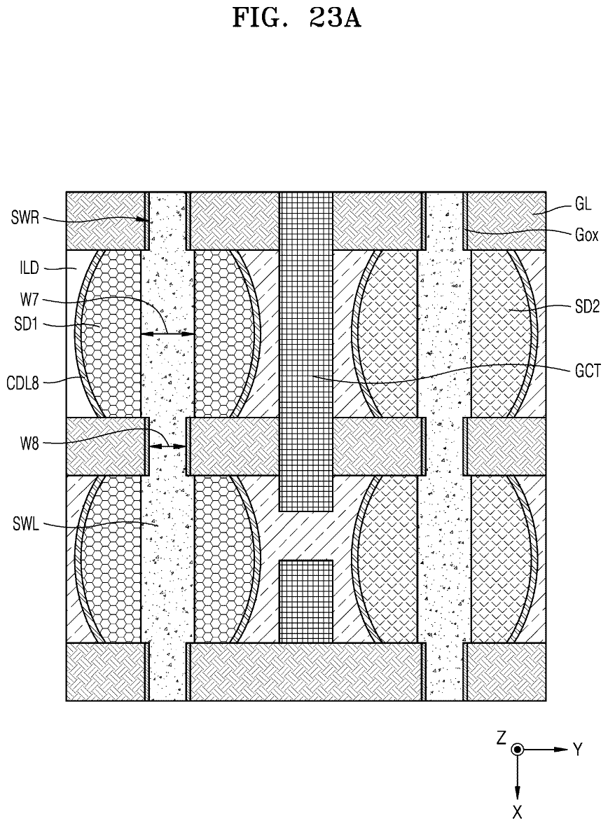

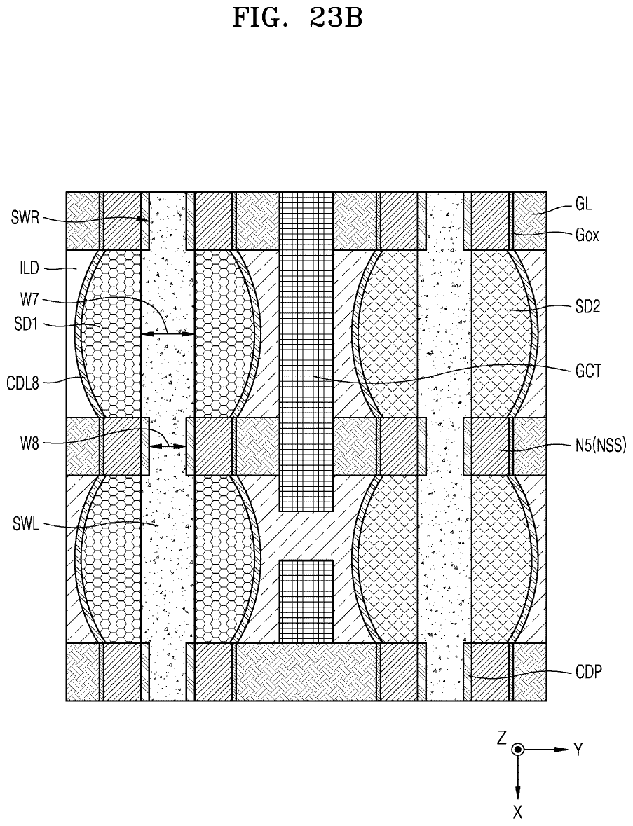

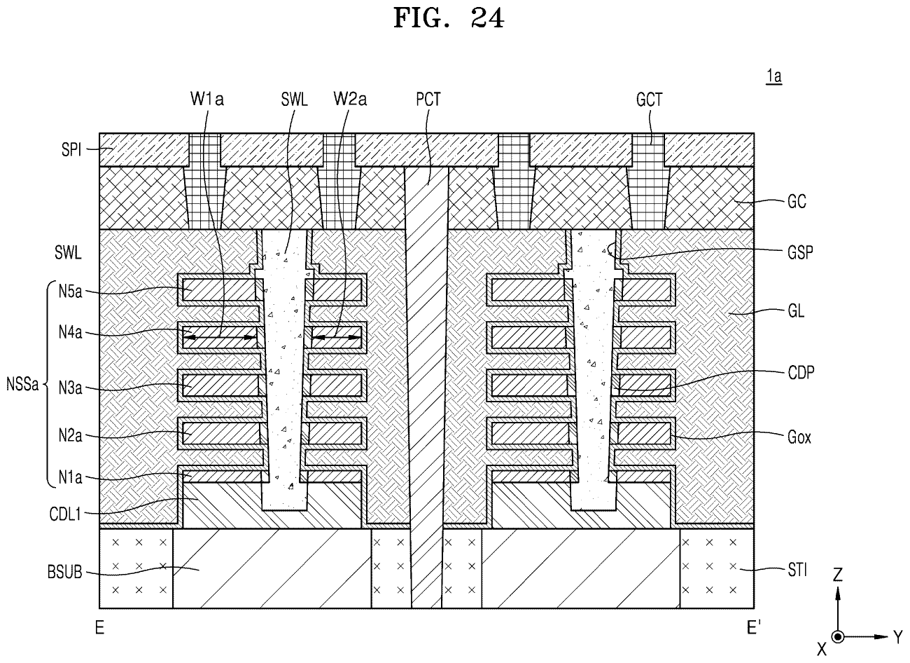

FIG. 24 is a vertical cross-sectional view of an integrated circuit device la according to some example embodiments. FIG. 24 is a vertical cross-sectional view taken along a region corresponding to line E-E′ in FIG. 1. In descriptions of FIG. 24, duplicate descriptions given with respect to FIGS. 1 through 23B are omitted.

Referring to FIG. 24, instead of the plurality of nanosheet stacked structures NSS including the first through fifth nanosheets N1 through N5 included in the integrated circuit device 1 illustrated in FIGS. 1, 21 through 21F, 22, 23A, and 23B, the integrated circuit device 1a may include a plurality of nanosheet stacked structures NSSa including first through fifth nanosheets N1a through N5a.

The integrated circuit device la may include the plurality of nanosheet stacked structures NSSa including the first through fifth nanosheets N1a through N5a apart from each other and stacked in the vertical direction (Z direction), the plurality of sheet separation walls SWL extending in the first horizontal direction (X direction), the plurality of gate electrodes GL extending on the plurality of nanosheet stacked structures NSSa in the second horizontal direction (Y direction), and at least one gate cut structure PCT extending in the first horizontal direction (X direction) and cutting across at least some of the plurality of gate electrodes GL.

The plurality of nanosheet stacked structures NSSa may be arranged in rows and columns in the first horizontal direction (X direction) and the second horizontal direction (Y direction), respectively. The plurality of nanosheet stacked structures NSSa may be adjacent to the plurality of sheet separation walls SWL, and may be arranged in rows in the first horizontal direction (X direction). A corresponding pair of nanosheet stacked structures NSSa among the plurality of nanosheet stacked structures NSSa may include the sheet separation wall SWL therebetween, and may be arranged apart from each other in the second horizontal direction (Y direction).

The gate electrodes GL separated into two by the gate cut structure PCT may include the gate cut structure PCT therebetween, and may be apart from each other in the second horizontal direction (Y direction).

The plurality of gate electrodes GL may be arranged between the fifth nanosheet N5a at the uppermost end of the first through fifth nanosheets N1a through N5a and each of the first through fifth nanosheets N1a through N5a. Portions of the plurality of gate electrodes GL arranged on the fifth nanosheet N5a at the uppermost end of the first through fifth nanosheets N1a through N5a and portions of the plurality of gate electrodes GL arranged between each of the first through fifth nanosheets N1a through N5a may be connected to each other.

The plurality of gate insulating layers Gox may be arranged between the plurality of gate electrodes GL and the plurality of nanosheet stacked structures NSSa including the first through fifth nanosheets N1a through N5a.

The first insulating layer CDL1 may be arranged between the base substrate layer BSUB and the plurality of nanosheet stacked structures NSSa including the first through fifth nanosheets N1a through N5a. The device isolation layer STI may be arranged in portions of the base substrate layer BSUB, where the plurality of nanosheet stacked structures NSSa including the first through fifth nanosheets N1a through N5a do not overlap the base substrate layer BSUB in the vertical direction (Z direction).

The plurality of first contacts GCT may penetrate the gate capping layer GC and be connected to an upper side portion of the plurality of gate electrodes GL.

The plurality of cladding patterns CDP may be arranged between the plurality of sheet separation walls SWL and the first through fifth nanosheets N1a through N5a included in the plurality of nanosheet stacked structures NSSa. Each of the first through fifth nanosheets N1a through N5a included in the plurality of nanosheet stacked structures NSSa may include the cladding pattern CDP therebetween, and may be apart from the sheet separation wall SWL. The sheet separation wall SWL or each of the plurality of cladding patterns CDP covering the side surfaces of the first through fifth nanosheets N1a through Na may have a thickness of about or exactly 2 nm to about or exactly 3 nm. A thickness of each of the plurality of gate insulating layers Gox may be less than a thickness of each of the plurality of cladding patterns CDP. One end of the gate electrode GL facing the sheet separation wall SWL in the second horizontal direction (Y direction) may be closer to a sheet separation wall SWL than one end of the first through fifth nanosheets N1a through N5a.

With respect to the sheet separation wall SWL as a reference, each of the first through fifth nanosheets N1a through N5a included in the plurality of nanosheet stacked structures NSSa arranged on one side in the second horizontal direction (Y direction) may have a first horizontal width W1a, and each of the first through fifth nanosheets N1a through N5a included in the plurality of nanosheet stacked structures NSSa arranged on the other side in the second horizontal direction (Y direction) may have a second horizontal width W2a. The first horizontal width W1a and the second horizontal width W2a may have the same value. For example, among the plurality of nanosheet stacked structures NSSa, horizontal widths of each of the first through nanosheets N1a through N5a included in a corresponding pair of nanosheet stacked structures NSSa, which include the sheet separation wall SWL therebetween and apart from each other in the second horizontal direction (Y direction), may be different from each other.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

While the inventive concept has been particularly shown and described with reference to some example embodiments thereof, it will be understood that various changes in form and details may be made therein without departing from the spirit and scope of the following claims.

What is claimed is:

1. An integrated circuit device comprising:
a base substrate layer;
a sheet separation wall extending on the base substrate layer in a first horizontal direction;
a pair of nanosheet stacked structures including the sheet separation wall therebetween and apart from each other in a second horizontal direction, the second horizontal direction different from the first horizontal direction, the pair of nanosheet stacked structures each including a plurality of nanosheets;
a plurality of cladding patterns between a first end of each of the plurality of nanosheets included in each of the pair of nanosheet stacked structures and the sheet separation wall; and
a pair of gate electrodes extending on the pair of nanosheet stacked structures in the second horizontal direction.

2. The integrated circuit device of claim 1, wherein the plurality of cladding patterns are apart from each other in a vertical direction, on each of both sidewalls of the sheet separation wall.

3. The integrated circuit device of claim 2,
further comprising a pair of gate insulating layers between the plurality of nanosheets included in the pair of nanosheet stacked structures and the pair of gate electrodes,
wherein, among the plurality of cladding patterns, portions of the pair of gate electrodes and portions of the pair of gate insulating layers are between two cladding patterns apart from each other in the vertical direction.

4. The integrated circuit device of claim 1,
further comprising a base insulating layer between the pair of nanosheet stacked structures and the base substrate layer,
wherein the sheet separation wall extends into the base insulating layer.

5. The integrated circuit device of claim 4, wherein
the sheet separation wall comprises a base wall portion, a vertical wall portion, a protrusion wall portion, and a cover wall portion, which are sequentially arranged in a vertical direction and constitute one body,
the base wall portion extends into the base insulating layer and is buried therein,
the vertical wall portion extends in the vertical direction from a vertical level, at which a lower surface of a nanosheet at a lowermost end among the plurality of nanosheets included in each of the pair of nanosheet stacked structures is arranged, to a vertical level at which an upper surface of a nanosheet at an uppermost end, and
the protrusion wall portion has a horizontal width greater than a horizontal width of an upper end of the vertical wall portion and a horizontal width of a lower end of the cover wall portion.

6. The integrated circuit device of claim 5, wherein the vertical wall portion extends from a lower side to an upper side in the vertical direction, and has a tapered shape, in which a horizontal width of the vertical wall portion increases in the second horizontal direction.

7. The integrated circuit device of claim 1,
further comprising a pair of source/drain regions connected to a second end opposite to the first end of each of the plurality of nanosheets included in each of the pair of nanosheet stacked structures,
wherein the sheet separation wall has a horizontal width between the pair of nanosheet stacked structures that is less than a horizontal width between the pair of source/drain regions.

8. The integrated circuit device of claim 7, wherein
the sheet separation wall has a horizontal cross-section having a pair of concave portions between the pair of nanosheet stacked structures, and
the plurality of cladding patterns are in the pair of concave portions.

9. The integrated circuit device of claim 1, wherein a first end of the pair of gate electrodes facing the sheet separation wall is closer to the sheet separation wall than the first end of each of the plurality of nanosheets comprised in the pair of nanosheet stacked structures.

10. The integrated circuit device of claim 1, wherein the plurality of cladding patterns comprise different types of semiconductor materials from the plurality of nanosheets.

11. An integrated circuit device comprising:
a base insulating layer on a base substrate layer;
a sheet separation wall extending on the base insulating layer in a first horizontal direction;
a pair of nanosheet stacked structures including the sheet separation wall therebetween and apart from each other in a second horizontal direction, the second horizontal direction different from the first horizontal direction, the pair of nanosheet stacked structures each including a plurality of nanosheets;
a plurality of cladding patterns between a first end of each of the plurality of nanosheets included in each of the pair of nanosheet stacked structures and the sheet separation wall;
a pair of gate electrodes extending on the pair of nanosheet stacked structures in the second horizontal direction;
a pair of gate insulating layers between the plurality of nanosheets included in each of the pair of nanosheet stacked structures and the pair of gate electrodes, the pair of gate insulating layers each having a thickness less than a thickness of each of the plurality of cladding patterns; and
a pair of source/drain regions connected to a second end opposite to the first end of each of the plurality of nanosheets included in each of the pair of nanosheet stacked structures.

12. The integrated circuit device of claim 11, wherein the sheet separation wall has a first horizontal width between the pair of source/drain regions, and a second horizontal width less than the first horizontal width between the pair of nanosheet stacked structures.

13. The integrated circuit device of claim 12, wherein
the sheet separation wall has a horizontal cross-section having a pair of concave portions between the pair of nanosheet stacked structures, and
in a vertical direction, in spaces between the plurality of nanosheets comprised in each of the pair of nanosheet stacked structures, the pair of gate electrodes extend into the pair of concave portions.

14. The integrated circuit device of claim 13, wherein
the plurality of cladding patterns are in the pair of concave portions, and
portions of the pair of gate electrodes extending into the pair of concave portions are between the plurality of cladding patterns apart from each other in the vertical direction.

15. The integrated circuit device of claim 11, wherein
wherein the sheet separation wall comprises
a base wall portion buried in the base insulating layer,
a vertical wall portion extending in a vertical direction from a vertical level, at which a lower surface of a nanosheet at a lowest end among the plurality of nanosheets included in each of the pair of nanosheet stacked structures is arranged, to a vertical level, at which an upper surface of a nanosheet at an uppermost end is arranged, and having a horizontal width increasing in the second horizontal direction,
a protrusion wall portion upwardly extending from a vertical level, at which the upper surface of the nanosheet at the uppermost end is arranged, and a cover wall portion on the protrusion wall portion and including an upper end at an identical vertical level to an uppermost end of the pair of gate electrodes, and
the protrusion wall portion has in the second horizontal direction, a horizontal width greater than a horizontal width of an upper end of the vertical wall portion and a horizontal width of a lower end of the cover wall portion.

16. The integrated circuit device of claim 11,
wherein, among the pair of nanosheet stacked structures, the plurality of nanosheets comprised in one nanosheet stacked structure and the plurality of nanosheets comprised in another nanosheet stacked structure have an identical horizontal width in the second horizontal direction.

17. The integrated circuit device of claim 11,
wherein, among the pair of nanosheet stacked structures, each of the plurality of nanosheets comprised in one nanosheet stacked structure has a first horizontal width in the second horizontal direction, and each of the plurality of nanosheets comprised in another nanosheet stacked structure has a second horizontal width less than the first horizontal width in the second horizontal direction.

18. An integrated circuit device comprising:
a base insulating layer on a base substrate layer;
a sheet separation wall extending on the base insulating layer in a first horizontal direction;
a pair of nanosheet stacked structures including the sheet separation wall therebetween and apart from each other in a second horizontal direction, the second horizontal direction different from the first horizontal direction, the pair of nanosheet stacked structures each including a plurality of nanosheets;
a plurality of cladding patterns between a first end of each of the plurality of nanosheets included in each of the pair of nanosheet stacked structures and the sheet separation wall;
a plurality of gate electrodes between a nanosheet at an uppermost end among the plurality of nanosheets included in the pair of nanosheet stacked structures and each of the plurality of nanosheets, the plurality of gate electrodes extending in the second horizontal direction;
a pair of gate insulating layers between the plurality of nanosheets included in each of the pair of nanosheet stacked structures and the plurality of gate electrodes, the pair of gate insulating layers each having a thickness less than a thickness of each of the plurality of cladding patterns;
a gate capping layer covering the plurality of gate electrodes;
a pair of source/drain regions connected to a second end opposite to the first end of each of the plurality of nanosheets included in each of the pair of nanosheet stacked structures;
a gate contact configured to penetrate the gate capping layer and connected to each of the plurality of gate electrodes; and
a source/drain contact configured to penetrate the base substrate layer and connected to each of the pair of source/drain regions,
the sheet separation wall having a horizontal cross-section having a pair of concave portions between the pair of nanosheet stacked structures,
the plurality of cladding patterns being in the pair of concave portions, and
the plurality of gate electrodes extending into the pair of concave portions.

19. The integrated circuit device of claim 18, wherein
the plurality of cladding patterns comprise a semiconductor material, and
the sheet separation wall comprises nitride.

20. The integrated circuit device of claim 18, wherein each of the plurality of cladding patterns has a thickness greater than a thickness of each of the pair of gate insulating layers, and has a thickness of 2 nm to 3 nm.
